(19) United States
(12) Patent Application Publication
(10) Pub. No.: US 2025/0287777 A1
(43) Pub. Date: Sep. 11, 2025

(54) LIGHT-EMITTING DEVICE AND DISPLAY DEVICE

(71) Applicant: SEMICONDUCTOR ENERGY LABORATORY CO., LTD., Atsugi-shi (JP)

(72) Inventors: Satoshi SEO, Sagamihara (JP); Nobuharu OHSAWA, Zama (JP); Hiromi SEO, Sagamihara (JP); Hiromitsu KIDO, Atsugi (JP); Yuki HAYASHI, Atsugi (JP)

(21) Appl. No.: 19/068,294

(22) Filed: Mar. 3, 2025

(30) Foreign Application Priority Data
Mar. 8, 2024 (JP) 2024-036313

(51) Int. Cl. H10K 50/19; H10K 50/13; H10K 59/35; H10K 85/60; H10K 101/25; H10K 101/40

(52) U.S. Cl. CPC H10K 50/19; H10K 50/131; H10K 85/654; H10K 85/6572; H10K 59/35; H10K 2101/25; H10K 2101/40

(57) ABSTRACT

To provide a light-emitting device having favorable characteristics. The light-emitting device includes first and second electrodes, an intermediate layer therebetween, first and second light-emitting layers, and first and second electron-transport layers. The first light-emitting layer is between the first electrode and the intermediate layer, the second light-emitting layer is between the intermediate layer and the second electrode, the first electron-transport layer is between the first light-emitting layer and the intermediate layer, the second electron-transport layer is between the second light-emitting layer and the second electrode, the second electron-transport layer includes a first organic compound having a triazine skeleton, the intermediate layer includes a second organic compound having a phenanthroline skeleton, the first and second light-emitting layers include the same emission center substance and the same two kinds of organic compounds forming an exciplex, the first light-emitting layer is different from a light-emitting layer of at least one of a plurality of light-emitting devices adjacent to the light-emitting device, and the second light-emitting layer is different from a light-emitting layer of the at least one of the plurality of light-emitting devices adjacent to the light-emitting device.

### BACKGROUND OF THE INVENTION

### 1. Field of the Invention

One embodiment of the present invention relates to an organic compound, an organic semiconductor element, a light-emitting device, a photodiode sensor, a display module, a lighting module, a display device, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a liquid crystal display device, a lighting device, a power storage device, a memory device, an image capturing device, a driving method thereof, and a manufacturing method thereof.

### 2. Description of the Related Art

A light-emitting device (also referred to as organic EL element) including an organic compound and utilizing electroluminescence (EL) has been put into practical use. In the basic structure of such a light-emitting device, an organic compound layer including an emission center substance is sandwiched between a pair of electrodes. Carriers are injected by application of a voltage to the device, and recombination energy of the carriers is used to obtain light emission from the emission center substance.

Since such a light-emitting device is of self-luminous type, a display device in which the light-emitting device is used for a pixel has higher visibility than a liquid crystal display device and does not need a backlight. A display device including such a light-emitting device is also highly advantageous in that it can be thin and lightweight. Another feature of such a light-emitting device is that it has an extremely high response speed.

Since a continuous planar light-emitting layer can be formed for such light-emitting devices, planar light emission can be achieved. This feature is difficult to realize with a point light source typified by an incandescent lamp and an LED or a linear light source typified by a fluorescent lamp; thus, the light-emitting device also has great potential as a planar light source, which can be used for a lighting device and the like.

Display devices or lighting devices that include light-emitting devices are suitable for a variety of electronic appliances as described above, and research and development of light-emitting devices have progressed for better characteristics.

In particular, tandem light-emitting devices have attracted attention because of their high current efficiency.

Patent Documents 1 and 2 disclose tandem light-emitting devices fabricated by a side-by-side patterning method.

### REFERENCES

[Patent Document 1] Japanese Published Patent Application No. 2005-317548
[Patent Document 2] Japanese Published Patent Application No. 2023-161850

### SUMMARY OF THE INVENTION

An object of one embodiment of the present invention is to provide a light-emitting device having favorable characteristics. Another object of one embodiment of the present invention is to provide a light-emitting device having high emission efficiency. Another object of one embodiment of the present invention is to provide a light-emitting device having high reliability. Another object of one embodiment of the present invention is to provide a light-emitting device having a low driving voltage. Another object of one embodiment of the present invention is to provide a light-emitting device having high reliability and a low driving voltage.

Another object of one embodiment of the present invention is to provide a light-emitting device that enables a display device to have favorable characteristics. Another object of one embodiment of the present invention is to provide a light-emitting device that enables a display device to have high emission efficiency. Another object of one embodiment of the present invention is to provide a light-emitting device that enables a display device to have high reliability. Another object of one embodiment of the present invention is to provide a light-emitting device that enables a display device to have a low driving voltage. Another object of one embodiment of the present invention is to provide a light-emitting device that enables a display device to have high reliability and a low driving voltage.

Another object of one embodiment of the present invention is to provide any of an organic semiconductor device, a light-emitting device, a light-receiving device, a display device, an electronic appliance, and a lighting device each having low power consumption. Another object of one embodiment of the present invention is to provide an electronic appliance having high reliability or a lighting device having high reliability. Another object of one embodiment of the present invention is to provide any of a novel organic semiconductor device, a novel light-emitting device, a novel light-receiving device, a novel display device, a novel electronic appliance, and a novel lighting device.

It is only necessary that the present invention achieve at least one of the above-described objects. Note that the description of these objects does not preclude the existence of other objects. One embodiment of the present invention does not need to achieve all these objects. Other objects will be apparent from and can be derived from the description of the specification, the drawings, the claims, and the like.

One embodiment of the present invention is a light-emitting device which includes a first electrode, a second electrode, an intermediate layer, a first light-emitting layer, a second light-emitting layer, a first electron-transport layer, and a second electron-transport layer and in which the intermediate layer is between the first electrode and the second electrode, the first light-emitting layer is between the first electrode and the intermediate layer, the second light-emitting layer is between the intermediate layer and the second electrode, the first electron-transport layer is between the first light-emitting layer and the intermediate layer, the second electron-transport layer is between the second light-emitting layer and the second electrode, the first light-emitting layer includes a first emission center substance, a third organic compound, and a fourth organic compound, the second light-emitting layer includes a second emission center substance, a fifth organic compound, and a sixth organic compound, the third organic compound and the fourth organic compound form a first exciplex in combination, the fifth organic compound and the sixth organic compound form a second exciplex in combination, a difference between a maximum peak wavelength of an emission spectrum of the first emission center substance and a maximum peak wavelength of an emission spectrum of the second emission center substance is less than or equal to 30 nm, the first light-emitting layer emits light of a hue different from a hue of light emitted by a light-emitting layer of at least one of a plurality of light-emitting devices adjacent to the light-emitting device, and the second light-emitting layer emits light of a hue different from a hue of light emitted by a light-emitting layer of the at least one of the plurality of light-emitting devices adjacent to the light-emitting device.

Another embodiment of the present invention is a light-emitting device which includes a first electrode, a second electrode, an intermediate layer, a first light-emitting layer, a second light-emitting layer, a first electron-transport layer, and a second electron-transport layer and in which the intermediate layer is between the first electrode and the second electrode, the first light-emitting layer is between the first electrode and the intermediate layer, the second light-emitting layer is between the intermediate layer and the second electrode, the first electron-transport layer is between the first light-emitting layer and the intermediate layer, the second electron-transport layer is between the second light-emitting layer and the second electrode, the second electron-transport layer includes a first organic compound having a triazine skeleton, the intermediate layer includes a mixed layer of lithium or a lithium compound and a second organic compound having a phenanthroline skeleton, the first light-emitting layer includes a first emission center substance, a third organic compound, and a fourth organic compound, the second light-emitting layer includes a second emission center substance, a fifth organic compound, and a sixth organic compound, the third organic compound and the fourth organic compound form a first exciplex in combination, the fifth organic compound and the sixth organic compound form a second exciplex in combination, a difference between a maximum peak wavelength of an emission spectrum of the first emission center substance and a maximum peak wavelength of an emission spectrum of the second emission center substance is less than or equal to 30 nm, the first light-emitting layer emits light of a hue different from a hue of light emitted by a light-emitting layer of at least one of a plurality of light-emitting devices adjacent to the light-emitting device, and the second light-emitting layer emits light of a hue different from a hue of light emitted by a light-emitting layer of the at least one of the plurality of light-emitting devices adjacent to the light-emitting device.

Another embodiment of the present invention is the light-emitting device having the above-described structure where the first electron-transport layer includes a seventh organic compound having a triazine skeleton.

Another embodiment of the present invention is the light-emitting device having the above-described structure where the first organic compound and the seventh organic compound are the same organic compound.

Another embodiment of the present invention is the light-emitting device having the above-described structure where the intermediate layer includes lithium or a lithium compound.

Another embodiment of the present invention is the light-emitting device having the above-described structure where the intermediate layer includes a mixed layer of the lithium or the lithium compound and the second organic compound.

Another embodiment of the present invention is the light-emitting device having the above structure where an emission edge on a shorter wavelength side of the first exciplex is at a shorter wavelength than an absorption edge on a longer wavelength side of the first emission center substance.

Another embodiment of the present invention is the light-emitting device having the above structure where an emission edge on a shorter wavelength side of the second exciplex is at a shorter wavelength than an absorption edge on a longer wavelength side of the second emission center substance.

Another embodiment of the present invention is the light-emitting device having the above structure where the emission edge on a shorter wavelength side of the first exciplex is at a shorter wavelength than the absorption edge on a longer wavelength side of the first emission center substance, and the emission edge on a shorter wavelength side of the second exciplex is at a shorter wavelength than the absorption edge on a longer wavelength side of the second emission center substance.

Another embodiment of the present invention is the light-emitting device having the above structure where a peak wavelength of an emission spectrum of the first exciplex is on a shorter wavelength side than a peak wavelength of the emission spectrum of the first emission center substance, and a difference between the peak wavelength of the emission spectrum of the first exciplex and the peak wavelength of the emission spectrum of the first emission center substance is less than or equal to 30 nm.

Another embodiment of the present invention is the light-emitting device having the above structure where a peak wavelength of an emission spectrum of the second exciplex is on a shorter wavelength side than a peak wavelength of the emission spectrum of the second emission center substance, and a difference between the peak wavelength of the emission spectrum of the second exciplex and the peak wavelength of the emission spectrum of the second emission center substance is less than or equal to 30 nm.

Another embodiment of the present invention is the light-emitting device having the above structure where the peak wavelength of the emission spectrum of the first exciplex is on a shorter wavelength side than the peak wavelength of the emission spectrum of the first emission center substance, the difference between the peak wavelength of the emission spectrum of the first exciplex and the peak wavelength of the emission spectrum of the first emission center substance is less than or equal to 30 nm, the peak wavelength of the emission spectrum of the second exciplex is on a shorter wavelength side than the peak wavelength of the emission spectrum of the second emission center substance, and the difference between the peak wavelength of the emission spectrum of the second exciplex and the peak wavelength of the emission spectrum of the second emission center substance is less than or equal to 30 nm.

Another embodiment of the present invention is the light-emitting device having the above structure where an energy difference between a HOMO level and a LUMO level of the first emission center substance is larger than an energy difference between a HOMO level and a LUMO level of the first exciplex.

Another embodiment of the present invention is the light-emitting device having the above structure where an energy difference between a HOMO level and a LUMO level of the second emission center substance is larger than an energy difference between a HOMO level and a LUMO level of the second exciplex.

Another embodiment of the present invention is the light-emitting device having the above structure where the energy difference between the HOMO level and the LUMO level of the first emission center substance is larger than the energy difference between the HOMO level and the LUMO level of the first exciplex, and the energy difference between the HOMO level and the LUMO level of the second emission center substance is larger than the energy difference between the HOMO level and the LUMO level of the second exciplex.

Another embodiment of the present invention is the light-emitting device having the above-described structure where the second electron-transport layer includes lithium or a lithium compound.

Another embodiment of the present invention is the light-emitting device having the above-described structure where the first emission center substance and the second emission center substance are the same substance.

Another embodiment of the present invention is the light-emitting device having the above-described structure where the intermediate layer includes a first layer including the second organic compound.

Another embodiment of the present invention is the light-emitting device having the above-described structure where the first layer includes lithium or a lithium compound.

Another embodiment of the present invention is the light-emitting device having the above-described structure where the intermediate layer further includes a second layer and the second layer is between the first layer and the second light-emitting layer.

Another embodiment of the present invention is the light-emitting device having the above-described structure where the second layer includes a ninth organic compound having a hole-transport property.

Another embodiment of the present invention is the light-emitting device having the above-described structure where the second layer includes an organic compound having at least one of a halogen group and a cyano group.

Another embodiment of the present invention is the light-emitting device having the above-described structure where the second layer includes an organic compound having at least one of fluorine and a cyano group.

Another embodiment of the present invention is the light-emitting device having the above-described structure where the second layer includes an organic compound having four or more halogen groups, four or more cyano groups, or a combination of a halogen group(s) and a cyano group(s) the number of which is four or more.

Another embodiment of the present invention is the light-emitting device having the above-described structure where the second layer includes an organic compound having four or more fluorines, four or more cyano groups, or a combination of a fluorine(s) and a cyano group(s) the number of which is four or more.

Another embodiment of the present invention is the light-emitting device having the above-described structure where the first electron-transport layer includes the seventh organic compound having a triazine skeleton.

Another embodiment of the present invention is the light-emitting device having the above-described structure where the first organic compound and the seventh organic compound are the same organic compound.

Another embodiment of the present invention is the light-emitting device having the above-described structure where the first electron-transport layer includes an eighth organic compound not having triazine skeleton.

Another embodiment of the present invention is the light-emitting device having the above-described structure where the first electron-transport layer includes the eighth organic compound having at least one of a pyrimidine skeleton, an imidazole skeleton, and an anthracene skeleton.

Another embodiment of the present invention is a display device including any of the above-described light-emitting devices.

Another embodiment of the present invention is a display device which includes a light-emitting device A and a light-emitting device B and in which the light-emitting device A and the light-emitting device B are adjacent to each other, the light-emitting device A includes a first electrode A, a second electrode A, an intermediate layer A, a first light-emitting layer A, a second light-emitting layer A, a first electron-transport layer A, and a second electron-transport layer A, the intermediate layer A is between the first electrode A and the second electrode A, the first light-emitting layer A is between the first electrode A and the intermediate layer A, the second light-emitting layer A is between the intermediate layer A and the second electrode A, the first electron-transport layer A is between the first light-emitting layer A and the intermediate layer A, the second electron-transport layer A is between the second light-emitting layer A and the second electrode A, the light-emitting device B includes a first electrode B, a second electrode B, an intermediate layer B, a first light-emitting layer B, a second light-emitting layer B, a first electron-transport layer B, and a second electron-transport layer B, the intermediate layer B is between the first electrode B and the second electrode B, the first light-emitting layer B is between the first electrode B and the intermediate layer B, the second light-emitting layer B is between the intermediate layer B and the second electrode B, the first electron-transport layer B is between the first light-emitting layer B and the intermediate layer B, the second electron-transport layer B is between the second light-emitting layer B and the second electrode B, the second electron-transport layer A and the second electron-transport layer B each include a first organic compound having a triazine skeleton, the second electron-transport layer A and the second electron-transport layer B are made of the same material, the intermediate layer A and the intermediate layer B each include lithium or a lithium compound and a second organic compound having a phenanthroline skeleton, the first light-emitting layer A includes a first emission center substance, a third organic compound, and a fourth organic compound, the second light-emitting layer A includes a second emission center substance, a fifth organic compound, and a sixth organic compound, the third organic compound and the fourth organic compound form a first exciplex in combination, the fifth organic compound and the sixth organic compound form a second exciplex in combination, the first light-emitting layer B includes a third emission center substance, the second light-emitting layer B includes a fourth emission center substance, a difference between a maximum peak wavelength of an emission spectrum of the first emission center substance and a maximum peak wavelength of an emission spectrum of the second emission center substance is less than or equal to 30 nm, a difference between a maximum peak wavelength of an emission spectrum of the third emission center substance and a maximum peak wavelength of an emission spectrum of the fourth emission center substance is less than or equal to 30 nm, the first light-emitting layer A emits light of a hue different from a hue of light emitted by the first light-emitting layer B, and the second light-emitting layer A emits light of a hue different from a hue of light emitted by the second light-emitting layer B.

Another embodiment of the present invention is a display device which includes a light-emitting device A and a light-emitting device B and in which the light-emitting device A and the light-emitting device B are adjacent to each other, the light-emitting device A includes a first electrode A, a second electrode A, an intermediate layer A, a first light-emitting layer A, a second light-emitting layer A, a first electron-transport layer A, and a second electron-transport layer A, the intermediate layer A is between the first electrode A and the second electrode A, the first light-emitting layer A is between the first electrode A and the intermediate layer A, the second light-emitting layer A is between the intermediate layer A and the second electrode A, the first electron-transport layer A is between the first light-emitting layer A and the intermediate layer A, the second electron-transport layer A is between the second light-emitting layer A and the second electrode A, the light-emitting device B includes a first electrode B, a second electrode B, an intermediate layer B, a first light-emitting layer B, a second light-emitting layer B, a first electron-transport layer B, and a second electron-transport layer B, the intermediate layer B is between the first electrode B and the second electrode B, the first light-emitting layer B is between the first electrode B and the intermediate layer B, the second light-emitting layer B is between the intermediate layer B and the second electrode B, the first electron-transport layer B is between the first light-emitting layer B and the intermediate layer B, the second electron-transport layer B is between the second light-emitting layer B and the second electrode B, the second electron-transport layer A and the second electron-transport layer B each include a first organic compound having a triazine skeleton, the second electron-transport layer A and the second electron-transport layer B are one continuous layer, the intermediate layer A and the intermediate layer B each include lithium or a lithium compound and a second organic compound having a phenanthroline skeleton, the first light-emitting layer A includes a first emission center substance, a third organic compound, and a fourth organic compound, the second light-emitting layer A includes a second emission center substance, a fifth organic compound, and a sixth organic compound, the third organic compound and the fourth organic compound form a first exciplex in combination, the fifth organic compound and the sixth organic compound form a second exciplex in combination, the first light-emitting layer B includes a third emission center substance, the second light-emitting layer B includes a fourth emission center substance, a difference between a maximum peak wavelength of an emission spectrum of the first emission center substance and a maximum peak wavelength of an emission spectrum of the second emission center substance is less than or equal to 30 nm, a difference between a maximum peak wavelength of an emission spectrum of the third emission center substance and a maximum peak wavelength of an emission spectrum of the fourth emission center substance is less than or equal to 30 nm, the first light-emitting layer A and the first light-emitting layer B are different from each other, and the second light-emitting layer A and the second light-emitting layer B are different from each other.

Another embodiment of the present invention is the display device having the above structure where an emission edge on a shorter wavelength side of the first exciplex is at a shorter wavelength than an absorption edge on a longer wavelength side of the first emission center substance.

Another embodiment of the present invention is the display device having the above structure where an emission edge on a shorter wavelength side of the second exciplex is at a shorter wavelength than an absorption edge on a longer wavelength side of the second emission center substance.

Another embodiment of the present invention is the display device having the above structure where the emission edge on a shorter wavelength side of the first exciplex is at a shorter wavelength than the absorption edge on a longer wavelength side of the first emission center substance, and the emission edge on a shorter wavelength side of the second exciplex is at a shorter wavelength than the absorption edge on a longer wavelength side of the second emission center substance.

Another embodiment of the present invention is the display device having the above structure where a peak wavelength of an emission spectrum of the first exciplex is on a shorter wavelength side than a peak wavelength of the emission spectrum of the first emission center substance, and a difference between the peak wavelength of the emission spectrum of the first exciplex and the peak wavelength of the emission spectrum of the first emission center substance is less than or equal to 30 nm.

Another embodiment of the present invention is the display device having the above structure where a peak wavelength of an emission spectrum of the second exciplex is on a shorter wavelength side than a peak wavelength of the emission spectrum of the second emission center substance, and a difference between the peak wavelength of the emission spectrum of the second exciplex and the peak wavelength of the emission spectrum of the second emission center substance is less than or equal to 30 nm.

Another embodiment of the present invention is the display device having the above structure where the peak wavelength of the emission spectrum of the first exciplex is on a shorter wavelength side than the peak wavelength of the emission spectrum of the first emission center substance, the difference between the peak wavelength of the emission spectrum of the first exciplex and the peak wavelength of the emission spectrum of the first emission center substance is less than or equal to 30 nm, the peak wavelength of the emission spectrum of the second exciplex is on a shorter wavelength side than the peak wavelength of the emission spectrum of the second emission center substance, and the difference between the peak wavelength of the emission spectrum of the second exciplex and the peak wavelength of the emission spectrum of the second emission center substance is less than or equal to 30 nm.

Another embodiment of the present invention is the display device having the above structure where an energy difference between a HOMO level and a LUMO level of the first emission center substance is larger than an energy difference between a HOMO level and a LUMO level of the first exciplex.

Another embodiment of the present invention is the display device having the above structure where an energy difference between a HOMO level and a LUMO level of the second emission center substance is larger than an energy difference between a HOMO level and a LUMO level of the second exciplex.

Another embodiment of the present invention is the display device having the above structure where the energy difference between the HOMO level and the LUMO level of the first emission center substance is larger than the energy difference between the HOMO level and the LUMO level of the first exciplex, and the energy difference between the HOMO level and the LUMO level of the second emission center substance is larger than the energy difference between the HOMO level and the LUMO level of the second exciplex.

Another embodiment of the present invention is an electronic appliance including the above-described light-emitting device and a sensor, an operation button, a speaker, or a microphone.

Another embodiment of the present invention is a lighting device including the above-described light-emitting device and a housing.

The structures described above are embodiments of the present invention, and the present invention is not limited to the above-described structures.

One embodiment of the present invention can provide a light-emitting device having favorable characteristics. Another embodiment of the present invention can provide a light-emitting device having high emission efficiency. Another embodiment of the present invention can provide a light-emitting device having high reliability. Another embodiment of the present invention can provide a light-emitting device having a low driving voltage. Another embodiment of the present invention can provide a light-emitting device having high reliability and a low driving voltage.

Another embodiment of the present invention can provide a light-emitting device that enables a display device to have favorable characteristics. Another embodiment of the present invention can provide a light-emitting device that enables a display device to have high emission efficiency. Another embodiment of the present invention can provide a light-emitting device that enables a display device to have high reliability. Another embodiment of the present invention can provide a light-emitting device that enables a display device to have a low driving voltage. Another embodiment of the present invention can provide a light-emitting device that enables a display device to have high reliability and a low driving voltage.

Another embodiment of the present invention can provide any of an organic semiconductor device, a light-emitting device, a light-receiving device, a display device, an electronic appliance, and a lighting device each having low power consumption. Another embodiment of the present invention can provide an electronic appliance having high reliability or a lighting device having high reliability.

### BRIEF DESCRIPTION OF THE DRAWINGS

In the accompanying drawings:

FIGS. 1A to 1C are schematic views of light-emitting devices of embodiments of the present invention;

FIGS. 2A and 2B are schematic views of light-emitting devices of embodiments of the present invention;

FIGS. 3A and 3B illustrate a display device of one embodiment of the present invention;

FIGS. 4A and 4B illustrate a display device of one embodiment of the present invention;

FIGS. 5A to 5E are cross-sectional views illustrating an example of a method for manufacturing a display device;

FIGS. 6A and 6B are cross-sectional views illustrating an example of a method for manufacturing a display device;

FIGS. 7A to 7D are cross-sectional views illustrating an example of a method for manufacturing a display device;

FIGS. 8A to 8C are cross-sectional views illustrating an example of a method for manufacturing a display device;

FIGS. 9A to 9C are cross-sectional views illustrating an example of a method for manufacturing a display device;

FIGS. 10A to 10C are cross-sectional views illustrating an example of a method for manufacturing a display device;

FIGS. 11A and 11B are perspective views illustrating a structure example of a display module;

FIGS. 12A and 12B are cross-sectional views illustrating structure examples of a display device;

FIG. 13 is a perspective view illustrating a structure example of a display device;

FIG. 14 is a cross-sectional view illustrating a structure example of a display device;

FIG. 15 is a cross-sectional view illustrating a structure example of a display device;

FIGS. 16A to 16C illustrate a structure example of a display device;

FIG. 17 is a cross-sectional view illustrating a structure example of a display device;

FIGS. 18A to 18C illustrate a structure example of a display device;

FIGS. 19A to 19D illustrate examples of wearable devices;

FIGS. 20A to 20F illustrate examples of electronic appliances;

FIGS. 21A to 21G illustrate examples of electronic appliances;

FIG. 22 is a graph showing luminance-current density characteristics of a light-emitting device R1 and a comparative light-emitting device R1;

FIG. 23 is a graph showing current efficiency-luminance characteristics of the light-emitting device R1 and the comparative light-emitting device R1;

FIG. 24 is a graph showing current density-voltage characteristics of the light-emitting device R1 and the comparative light-emitting device R1;

FIG. 25 is a graph showing power efficiency-luminance characteristics of the light-emitting device R1 and the comparative light-emitting device R1;

FIG. 26 is a graph showing electroluminescence spectra of the light-emitting device R1 and the comparative light-emitting device R1;

FIG. 27 is a graph showing luminance-current density characteristics of a light-emitting device G1 and a comparative light-emitting device G1;

FIG. 28 is a graph showing current efficiency-luminance characteristics of the light-emitting device G1 and the comparative light-emitting device G1;

FIG. 29 is a graph showing current density-voltage characteristics of the light-emitting device G1 and the comparative light-emitting device G1;

FIG. 30 is a graph showing power efficiency-luminance characteristics of the light-emitting device G1 and the comparative light-emitting device G1;

FIG. 31 is a graph showing electroluminescence spectra of the light-emitting device G1 and the comparative light-emitting device G1;

FIG. 32 is a graph showing time dependence of normalized luminance of the light-emitting device G1 and the comparative light-emitting device G1;

FIG. 33 is a graph showing PL spectra of 8mpTP-4mDBtPBfpm, βNCCP, and an exciplex of 8mpTP-4mDBtPBfpm and βNCCP;

FIG. 34 is a graph showing a PL spectrum of an exciplex of 8mpTP-4mDBtPBfpm and βNCCP and an absorption spectrum and a PL spectrum of Ir(5mppy-d₃)₂(mbfpypy-d₃);

FIG. 35 is a graph showing an example of determining an emission edge and an absorption edge;

FIG. 36 is a graph showing luminance-current density characteristics of a light-emitting device B1 and a comparative light-emitting device B1;

FIG. 37 is a graph showing current efficiency-luminance characteristics of the light-emitting device B1 and the comparative light-emitting device B1;

FIG. 38 is a graph showing current density-voltage characteristics of the light-emitting device B1 and the comparative light-emitting device B1;

FIG. 39 is a graph showing power efficiency-luminance characteristics of the light-emitting device B1 and the comparative light-emitting device B1;

FIG. 40 is a graph showing blue index-luminance characteristics of the light-emitting device B1 and the comparative light-emitting device B1;

FIG. 41 is a graph showing electroluminescence spectra of the light-emitting device B1 and the comparative light-emitting device B1;

FIG. 42 is a graph showing luminance-current density characteristics of a light-emitting device R2 and a comparative light-emitting device R2;

FIG. 43 is a graph showing current efficiency-luminance characteristics of the light-emitting device R2 and the comparative light-emitting device R2;

FIG. 44 is a graph showing current density-voltage characteristics of the light-emitting device R2 and the comparative light-emitting device R2;

FIG. 45 is a graph showing power efficiency-luminance characteristics of the light-emitting device R2 and the comparative light-emitting device R2;

FIG. 46 is a graph showing electroluminescence spectra of the light-emitting device R2 and the comparative light-emitting device R2;

FIG. 47 is a graph showing luminance-current density characteristics of a light-emitting device G2 and a comparative light-emitting device G2;

FIG. 48 is a graph showing current efficiency-luminance characteristics of the light-emitting device G2 and the comparative light-emitting device G2;

FIG. 49 is a graph showing current density-voltage characteristics of the light-emitting device G2 and the comparative light-emitting device G2;

FIG. 50 is a graph showing power efficiency-luminance characteristics of the light-emitting device G2 and the comparative light-emitting device G2;

FIG. 51 is a graph showing electroluminescence spectra of the light-emitting device G2 and the comparative light-emitting device G2;

FIG. 52 is a graph showing time dependence of normalized luminance of the light-emitting device G2 and the comparative light-emitting device G2;

FIG. 53 is a graph showing luminance-current density characteristics of a light-emitting device B2 and a comparative light-emitting device B2;

FIG. 54 is a graph showing current efficiency-luminance characteristics of the light-emitting device B2 and the comparative light-emitting device B2;

FIG. 55 is a graph showing current density-voltage characteristics of the light-emitting device B2 and the comparative light-emitting device B2;

FIG. 56 is a graph showing power efficiency-luminance characteristics of the light-emitting device B2 and the comparative light-emitting device B2;

FIG. 57 is a graph showing blue index-luminance characteristics of the light-emitting device B2 and the comparative light-emitting device B2;

FIG. 58 is a graph showing electroluminescence spectra of the light-emitting device B2 and the comparative light-emitting device B2;

FIG. 59 is a graph showing luminance-current density characteristics of a light-emitting device R3, a light-emitting device G3, and a light-emitting device B3;

FIG. 60 is a graph showing current efficiency-luminance characteristics of the light-emitting device R3, the light-emitting device G3, and the light-emitting device B3;

FIG. 61 is a graph showing current density-voltage characteristics of the light-emitting device R3, the light-emitting device G3, and the light-emitting device B3;

FIG. 62 is a graph showing power efficiency-luminance characteristics of the light-emitting device R3, the light-emitting device G3, and the light-emitting device B3;

FIG. 63 is a graph showing blue index-current density characteristics of the light-emitting device B3;

FIG. 64 is a graph showing electroluminescence spectra of the light-emitting device R3, the light-emitting device G3, and the light-emitting device B3;

FIG. 65 is a graph showing a PL spectrum of an exciplex of 8mpTP-4mDBtPBfpm and βNCCP and an absorption spectrum and a PL spectrum of Pt(tBudppymmtBubiz-tBubp);

FIG. 66 is a graph showing an example of determining an absorption edge of Pt(tBudppymmtBubiz-tBubp);

FIG. 67 is a graph showing PL spectra of 11mDBtBPPnfpr, PCBBiF, and an exciplex of 11mDBtBPPnfpr and PCBBiF;

FIG. 68 is a graph showing a PL spectrum of an exciplex of 11mDBtBPPnfpr and PCBBiF and an absorption spectrum and a PL spectrum of OCPG-006; and

FIG. 69 is a graph showing an example of determining an absorption edge of OCPG-006.

### DETAILED DESCRIPTION OF THE INVENTION

Embodiments of the present invention will be described in detail below with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

In this specification and the like, a device formed using a metal mask or a fine metal mask (FMM, a high-resolution metal mask) is sometimes referred to as a device having a metal mask (MM) structure. In this specification and the like, a device formed without using a metal mask or an FMM is sometimes referred to as a device having a metal maskless (MML) structure.

### Embodiment 1

A tandem light-emitting device has a structure in which a plurality of light-emitting units are stacked between a pair of electrodes with an intermediate layer (a charge-generation layer) between the plurality of light-emitting units. The plurality of light-emitting units include their respective light-emitting layers, and each of the light-emitting layers can emit light with a flow of current therethrough. The tandem light-emitting device having such a structure has much higher current efficiency than a non-tandem light-emitting device, and can thus be suitably used for a display device that is required to perform high-luminance display or that needs to have high reliability.

Since the tandem light-emitting device includes a plurality of light-emitting layers and can thus easily provide white light emission, many full-color display devices including the tandem light-emitting device employ a “white+color filter” method. A color conversion method is also in practical use in which light-emitting layers that emit blue light are stacked and a color conversion layer typified by quantum dots is used.

Meanwhile, some full-color display devices employing a side-by-side patterning method and the tandem light-emitting device have also been put into practical use. A light-emitting device fabricated by the side-by-side patterning method has little or no energy loss due to a color filter or a color conversion layer and can thus have higher emission efficiency than light-emitting devices fabricated by the above-described two methods.

At least one of light-emitting layers included in a tandem light-emitting device of one embodiment of the present invention includes an emission center substance, a first host material, and a second host material. The emission center substance is preferably a phosphorescent substance. The first host material and the second host material are organic compounds and form an exciplex in combination. The tandem light-emitting device of one embodiment of the present invention has a structure in which energy is transferred from the exciplex formed by the first host material and the second host material to the emission center substance to make the emission center substance emit light. Thus, the transfer efficiency of excitation energy to the emission center substance is improved, so that the light-emitting device can have high efficiency and high reliability. In addition, the driving voltage can also be reduced.

It is preferable that in the tandem light-emitting device, an electron-transport layer included in a light-emitting unit on a cathode side include a first organic compound having a triazine skeleton, and an intermediate layer include a second organic compound having a phenanthroline skeleton.

It is only required that at least one of the light-emitting layers included in the tandem light-emitting device of one embodiment of the present invention have the above structure of the light-emitting layer; however, it is preferable that two or more, or all of the light-emitting layers have the structure. For example, in the case of a tandem light-emitting device including two light-emitting layers, a first light-emitting layer and a second light-emitting layer, it is preferable that the first light-emitting layer include a first emission center substance, a third organic compound, and a fourth organic compound, the third organic compound and the fourth organic compound form an exciplex in combination, the second light-emitting layer include a second emission center substance, a fifth organic compound, and a sixth organic compound, and the fifth organic compound and the sixth organic compound form an exciplex in combination.

It is preferable that for efficient formation of an exciplex, one of the first host material and the second host material be an organic compound having a hole-transport property and the other be an organic compound having an electron-transport property. In addition, the HOMO level of the organic compound having a hole-transport property is preferably higher than or equal to that of the organic compound having an electron-transport property. The LUMO level of the organic compound having a hole-transport property is preferably higher than or equal to that of the organic compound having an electron-transport property, in which case an exciplex can be formed more efficiently.

The values of the HOMO and LUMO levels can be obtained through a cyclic voltammetry (CV) measurement.

In the cyclic voltammetry (CV) measurement, the values (E) of HOMO and LUMO levels can be calculated on the basis of an oxidation peak potential (Eₚₐ) and a reduction peak potential (E_{pc}), which are obtained by changing the potential of a working electrode with respect to a reference electrode. In the measurement, a HOMO level and a LUMO level can be obtained by potential scanning in the positive direction and potential scanning in the negative direction, respectively. The scanning speed in the measurement is 0.1 V/s.

Specifically, a standard oxidation-reduction potential (Eₒ) (=Eₚₐ+E_{pc})/2) is calculated from an oxidation peak potential (Eₚₐ) and a reduction peak potential (E_{pc}), which are obtained by the cyclic voltammogram of a material. Then, the standard oxidation-reduction potential (Eₒ) is subtracted from the potential energy (Eₓ) of the reference electrode with respect to a vacuum level, whereby each of the values (E)(=Eₓ−Eₒ) of HOMO and LUMO levels can be obtained.

Note that the reversible oxidation-reduction wave is obtained in the above case; in the case where an irreversible oxidation-reduction wave is obtained, the HOMO level is calculated as follows: a value obtained by subtracting a predetermined value (0.1 eV) from an oxidation peak potential (Eₚₐ) is assumed to be a reduction peak potential (E_{pc}), and a standard oxidation-reduction potential (Eₒ) is calculated to one decimal place. To calculate the LUMO level, a value obtained by adding a predetermined value (0.1 eV) to a reduction peak potential (E_{pc}) is assumed to be an oxidation peak potential (Eₚₐ), and a standard oxidation-reduction potential (Eₒ) is calculated to one decimal place.

The formation of an exciplex can be confirmed by, for example, comparing the emission spectra of the organic compound having a hole-transport property, the organic compound having an electron-transport property, and the mixed film of these organic compounds, and observing the phenomenon in which the emission spectrum of the mixed film is on a longer wavelength side than the emission spectrum of each of the organic compounds (or has another peak on a longer wavelength side). Alternatively, the formation of an exciplex can be confirmed by comparing the transient photoluminescence (PL) of the organic compound having a hole-transport property, the transient PL of the organic compound having an electron-transport property, and the transient PL of the mixed film of the organic compounds, and observing a difference in transient response, such as a phenomenon in which the transient PL lifetime of the mixed film has a longer lifetime component or has a larger proportion of delayed components than that of each of the organic compounds. The transient PL can be rephrased as transient electroluminescence (EL). That is, the formation of an exciplex can also be confirmed by comparing the transient EL of the organic compound having a hole-transport property, the organic compound having an electron-transport property, and the mixed film of the organic compounds, and observing a difference in transient response.

Here, an emission edge on a shorter wavelength side of a photoluminescence (PL) spectrum of the exciplex formed by the first host material and the second host material is preferably positioned at a shorter wavelength than an absorption edge on a longer wavelength side of an absorption spectrum of the emission center substance. Such a positional relationship between the PL spectrum of the exciplex and the absorption edge of the emission center substance enables efficient energy transfer.

Alternatively, a peak wavelength of the PL spectrum of the exciplex formed by the first host material and the second host material is preferably shorter than a peak wavelength of the PL spectrum of the emission center substance. The difference between the peak wavelength of the PL spectrum of the exciplex and the peak wavelength of the PL spectrum of the emission center substance is preferably less than or equal to 30 nm. Such a relationship between the peak wavelength of the PL spectrum of the exciplex and the peak wavelength of the PL spectrum of the emission center substance enables efficient energy transfer.

Alternatively, the difference between the peak wavelength of the PL spectrum of the exciplex formed by the first host material and the second host material and the wavelength of the absorption edge on a longer wavelength side of the absorption spectrum of the emission center substance is preferably less than or equal to 30 nm. Such a relationship between the peak wavelength of the PL spectrum of the exciplex and the wavelength of the absorption edge on a longer wavelength side of the absorption spectrum of the emission center substance enables efficient energy transfer.

The PL spectrum of the exciplex is preferably measured using a film formed by co-evaporation of the first host material and the second host material. Meanwhile, the PL spectrum or the absorption spectrum of the emission center substance may be measured using a sample in the form of a thin film or a solution; however, a sample in the form of a solution is preferably used for examination of the state of an isolated molecule. As a solvent of the solution, a solvent with relatively low polarity, such as toluene or chloroform, is preferably used.

The absorption edge of the absorption spectrum can be determined as the intersection between a tangent and the horizontal axis or the baseline. The tangent is drawn at a point at which the slope on a longer wavelength side of the longest-wavelength peak (or the longest-wavelength shoulder peak) of the absorption spectrum has the maximum absolute value. The emission edge on a shorter wavelength side of the PL spectrum can be determined as the intersection between a tangent and the horizontal axis or the baseline. The tangent is drawn at a point at which the slope on a shorter wavelength side of the shortest-wavelength peak (or the shortest-wavelength shoulder peak) of the PL spectrum has the maximum absolute value.

As described above, one of the first host material and the second host material is preferably an organic compound having an electron-transport property and the other is preferably an organic compound having a hole-transport property.

The organic compound having an electron-transport property preferably has an electron mobility higher than or equal to 1×10⁻⁷ cm²/Vs, further preferably higher than or equal to 1×10⁻⁶ cm²/Vs when the square root of the electric field strength [V/cm] is 600.

The organic compound having an electron-transport property is preferably an organic compound having a π-electron deficient heteroaromatic ring. Examples of the organic compound having a π-electron deficient heteroaromatic ring include an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above organic compounds, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

Preferable examples of the organic compound that has a π-electron deficient heteroaromatic ring and can be used as the organic compound having an electron-transport property include the following organic compounds: organic compounds having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl) stilbene (abbreviation: BzOS); organic compounds that have a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), and 2-[4-(2-triphenylenyl)phenyl]-1,10-phenanthroline (abbreviation: pTpPPhen); organic compounds having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl) (biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6 (P-Bqn) 2Py), 2,2′-(pyridine-2,6-diyl)bis{4-[4-(2-naphthyl)phenyl]-6-phenylpyrimidine} (abbreviation: 2,6 (NP-PPm) 2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 7-[4-(9-phenyl-9H-carbazol-2-yl) quinazolin-2-yl]-7H-dibenzo[c,g]carbazole (abbreviation: PC-cgDBCzQz), 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), and 2,2′-(2,2′-bipyridine-6,6′-diyl)bis(4-phenylbenzo[h]quinazoline) (abbreviation: 6,6′(P-Bqn) 2BPy); and organic compounds that have a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-[4-(2-naphthalenyl)phenyl]-4-phenyl-6-spiro[9H-fluorene-9,9′-[9H]xanthen]-4-yl-1,3,5-triazine (abbreviation: βNP-SFx(4)Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl) indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 3-phenyl-9-[4-phenyl-6-(9-phenyl-3-dibenzofuranyl)-1,3,5-triazin-2-yl]-9H-carbazole (abbreviation: PDBf-PCzTzn), 9-[4-(4,6-diphenyl-1,3,5-triazin-2-yl)-2-dibenzothienyl]-2-phenyl-9H-carbazole (abbreviation: PCzDBtTzn), and 2,4,6-tris(2-pyridyl)-1,3,5-triazine (abbreviation: 2Py3Tzn).

The organic compound having a hole-transport property is preferably an organic compound having an amine skeleton or a π-electron rich heteroaromatic ring, for example. As the π-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of the amine through an arylene group may be used. Note that the substance having a hole-transport property is preferably an organic compound having an N,N-bis(4-biphenyl)amino group to enable fabricating a light-emitting device having a long lifetime.

Preferable examples of such organic compounds include the following organic compounds: compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 3,9-bis(9-phenyl-9H-carbazol-3-yl)-9H-carbazole (abbreviation: PCCzPC), 9-(biphenyl-4-yl)-9′-phenyl-3,3′-bi-9H-carbazole (abbreviation: PCCzBP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-[3-(triphenylsilyl)phenyl]-9′H-9,3′:6′,9″-tercarbazole (abbreviation: PSiCzGI); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage.

As described above, one of the first host material and the second host material is preferably an organic compound having an electron-transport property and the other is preferably an organic compound having a hole-transport property. For a higher carrier-transport property and more efficient exciplex formation, it is preferable that one of the first host material and the second host material be an organic compound having a π-electron deficient heteroaromatic ring and the other be an organic compound having an amine skeleton or a π-electron rich heteroaromatic ring. Alternatively, for higher triplet excitation energy, it is further preferable that one of the first host material and the second host material be an organic compound having a heteroaromatic ring with a diazine (pyrimidine or pyrazine) skeleton or an organic compound having a heteroaromatic ring with a triazine skeleton and the other be an organic compound having any of a carbazole skeleton, a dibenzofuran skeleton, and a dibenzothiophene skeleton. For higher stability and reliability, it is preferable that one of the first host material and the second host material be an organic compound having a triazine skeleton or a pyrimidine skeleton and the other be an organic compound having a carbazole skeleton. As the organic compound having a carbazole skeleton, it is particularly preferable to use an organic compound having a 3,3′-bicarbazole skeleton because the organic compound has a high donor property and high heat resistance. It is very preferable that one of the first host material and the second host material be an organic compound having a 3,3′-bicarbazole skeleton and the other be an organic compound having a triazine skeleton, in which case high triplet excitation energy, stability, and reliability are achieved.

By mixing the organic compound having an electron-transport property with the organic compound having a hole-transport property, the transport property of the light-emitting layer can be easily adjusted and a recombination region can be easily controlled. The weight ratio of the content of the organic compound having a hole-transport property to the content of the organic compound having an electron-transport property is 1:19 to 19:1, or preferably 3:7 to 7:3.

The light-emitting layer included in the tandem light-emitting device is preferably separated from a light-emitting layer included in at least one adjacent light-emitting device. Alternatively, the light-emitting layer included in the tandem light-emitting device is preferably different from a light-emitting layer included in at least one adjacent light-emitting device. Alternatively, the emission color of the tandem light-emitting device or a pixel including the tandem light-emitting device is preferably different from the emission color of at least one adjacent light-emitting device or pixel. Alternatively, the emission center substance included in the light-emitting layer of the tandem light-emitting device preferably has a structure different from that of an emission center substance included in a light-emitting layer of at least one adjacent light-emitting device.

It is preferable that in the tandem light-emitting device, the electron-transport layer included in the light-emitting unit on the cathode side include the first organic compound having a triazine skeleton, and the intermediate layer include the second organic compound having a phenanthroline skeleton. When the electron-transport layer of the light-emitting unit on the cathode side includes the first organic compound and the intermediate layer includes the second organic compound, the tandem light-emitting device can achieve a low driving voltage. When the electron-transport layer of the light-emitting unit on the cathode side includes the first organic compound, the intermediate layer includes the second organic compound, and any of the light-emitting layers includes the emission center substance and two kinds of organic compounds that form an exciplex, the tandem light-emitting device can achieve higher emission efficiency as well as a lower driving voltage to have high power efficiency and high energy efficiency.

Moreover, when the light-emitting layer included in the tandem light-emitting device is separated from a light-emitting layer included in at least one adjacent light-emitting device or is different from a light-emitting layer included in at least one adjacent light-emitting device, the emission color of the tandem light-emitting device is different from the emission color of at least one adjacent light-emitting device, or the emission center substance included in the light-emitting layer of the tandem light-emitting device has a structure different from that of an emission center substance included in a light-emitting layer of at least one adjacent light-emitting device, the tandem light-emitting device can have extremely high current efficiency and can thus have higher power efficiency and higher energy efficiency.

Consequently, a display device of one embodiment of the present invention that includes such a light-emitting device can achieve low power consumption, high reliability, high-luminance display, and high visibility. In addition, the display device can have high display quality.

The above-described first organic compound having a triazine skeleton preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has a property of transporting more electrons than holes.

The first organic compound having a triazine skeleton preferably has the triazine skeleton and an aromatic ring. The aromatic ring is preferably a monocyclic aromatic ring, a polycyclic aromatic ring, an aromatic ring having an alkyl group as a substituent, an aromatic ring having a fluoro group as a substituent, an aromatic ring having a cyano group as a substituent, or the like. The triazine skeleton may have a substituent other than the above-described aromatic ring, and the aromatic ring may have a substituent other than the above-described triazine skeleton. Note that the triazine skeleton is also referred to as a triazine ring, and other skeletons can also be rephrased as rings.

Examples of the monocyclic aromatic ring include aromatic hydrocarbon rings such as a benzene ring and heteroaromatic rings such as a pyrrole ring, a pyridine ring, a pyrimidine ring, and a triazine ring. Having the aromatic ring as a substituent has the effect of improving heat resistance, specifically, a glass transition temperature (Tg), and the effect of improving an electron-transport property, for example.

Examples of the polycyclic aromatic ring include aromatic hydrocarbon rings such as a naphthalene ring, a phenanthrene ring, a chrysene ring, a triphenylene ring, a fluorene ring, and a spirobifluorene ring and heteroaromatic rings such as a carbazole ring, a dibenzofuran ring, a dibenzothiophene ring, a xanthene ring, an indolocarbazole ring, and an indenocarbazole ring. A compound having the polycyclic aromatic ring as a substituent can improve heat resistance more than a compound having the monocyclic aromatic ring such as a benzene ring and is thus preferable. A compound having as a substituent a ring in which an aromatic ring (e.g., a benzene ring, a naphthalene ring, or a pyridine ring) is further condensed to any of the above polycyclic aromatic rings can further improve heat resistance. Examples of the ring in which an aromatic ring is further condensed to the polycyclic aromatic ring include a benzofluorene ring, a benzonaphthofuran ring, a benzoxanthene ring, and a benzonaphthothiophene ring. Providing a layer including a compound having high heat resistance in the vicinity of the cathode can inhibit heat damage to the device when high-temperature treatment in a patterning step or the like is performed after the layer or the cathode is formed.

Examples of the alkyl group include a methyl group, an ethyl group, a propyl group, a tertiary butyl group, a cyclohexyl group, and an adamantyl group. The first organic compound having the alkyl group as a substituent can have a low refractive index, and a layer including the first organic compound can have a low refractive index. This can inhibit total reflection at the interface between the layer and another layer and improve the light extraction efficiency of the light-emitting device including the layer. When such a compound having an alkyl group is used also for the hole-transport layer, the refractive index of the hole-transport layer can be lowered. In particular, when a compound having a triazine skeleton and an alkyl group is used for the electron-transport layer and a compound having an aromatic amine skeleton and an alkyl group is used for the hole-transport layer, the effect of improving the light extraction efficiency can be synergistically enhanced. An organic compound having an alkyl group having a plurality of carbon atoms, preferably three or more carbon atoms, further preferably four or more carbon atoms, still further preferably five or more carbon atoms, can enhance the effect of lowering the refractive index. A layer including a compound having a fluoro group as a substituent is also preferable because it can lower the refractive index. In particular, an organic compound having a plurality of fluoro groups can enhance the effect of lowering the refractive index. It is also effective to use a compound having a fluoro group for both the electron-transport layer and the hole-transport layer. A compound having a structure in which a plurality of alkyl groups or fluoro groups are bonded to one aromatic ring can further lower the refractive index of the layer. In one example, two or three or more tertiary butyl groups are bonded as substituents to one benzene ring. Without limitation to the benzene ring, the plurality of alkyl groups or fluoro groups may be bonded to another monocyclic aromatic ring such as a pyridine ring or a polycyclic aromatic ring such as a fluorene ring. In addition, the plurality of alkyl groups or fluoro groups are suitably bonded to one or more rings included in a polycyclic aromatic ring (e.g., a naphthalene ring, a fluorene ring, a carbazole ring, a quinoline ring, or a xanthene ring). In one example, a plurality of tertiary butyl groups are bonded to one benzene ring included in a fluorene ring.

The first organic compound having a cyano group as a substituent is preferable because it can improve the electron-transport property.

A combination of some of polycyclic aromatic rings, alkyl groups, fluoro groups, and cyano groups is also suitable for substituents of the first organic compound. Having a polycyclic aromatic ring and a cyano group as substituents, for example, can improve both the heat resistance and the electron-transport property. In addition, having a polycyclic aromatic ring and an alkyl group can improve both the heat resistance and the light extraction efficiency. In this manner, substituents can be combined in accordance with the required function.

The first organic compound having a plurality of polycyclic aromatic rings as substituents can further improve the heat resistance. In that case, the first organic compound preferably has the aromatic hydrocarbon ring and the heteroaromatic ring.

The first organic compound having a triazine skeleton can be specifically, for example, an organic compound that has a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-[4-(2-naphthalenyl)phenyl]-4-phenyl-6-spiro[9H-fluoren-9,9′-[9H]xanthen]-4-yl-1,3,5-triazine abbreviation: βNP-SFx(4)Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl) indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 3-pheny-9-[4-phenyl-6-(9-phenyl-3-dibenzofuranyl-1,3,5-triazin-2-yl]-9H-carbazole (abbreviation: PDBf-PCzTzn), 9-[4-(4,6-diphenyl-1,3,5-triazin-2-yl)-2-dibenzothienyl]-2-phenyl-9H-carbazole (abbreviation: PCzDBtTzn), 2,4-diphenyl-6-[3′-(spiro[7H-benzo[c]fluorene-7,9′-[9H]xanthen]-2′-yl)biphenyl-3-yl]-1,3,5-triazine (abbreviation: mSbfxBPTzn), 3′-[4-phenyl-6-(spiro[9H-fluorene-9,9′-[9H]xanthen]-2′-yl)-1,3,5-triazin-2-yl]biphenyl-4-carbonitrile (abbreviation: mpCNBP-SFxTzn), or 2,2′-[1,2-naphthalenediyldi(4,1-phenylene)]bis(4,6-diphenyl-1,3,5-triazine) (abbreviation: TznP2N), and is particularly preferably TznP2N represented by Structural Formula (100) below, mSbfxBPTzn represented by Structural Formula (101) below, mpCNBP-SFxTzn represented by Structural Formula (102) below, CNBPNPTzn represented by Structural Formula (103) below, βNP-SFx(4)Tzn represented by Structural Formula (104) below, mmtBuBP-mDMePyPTzn represented by Structural Formula (105) below, mBnfBPTzn represented by Structural Formula (106) below, or the like.

### [Chemical Formula 1]

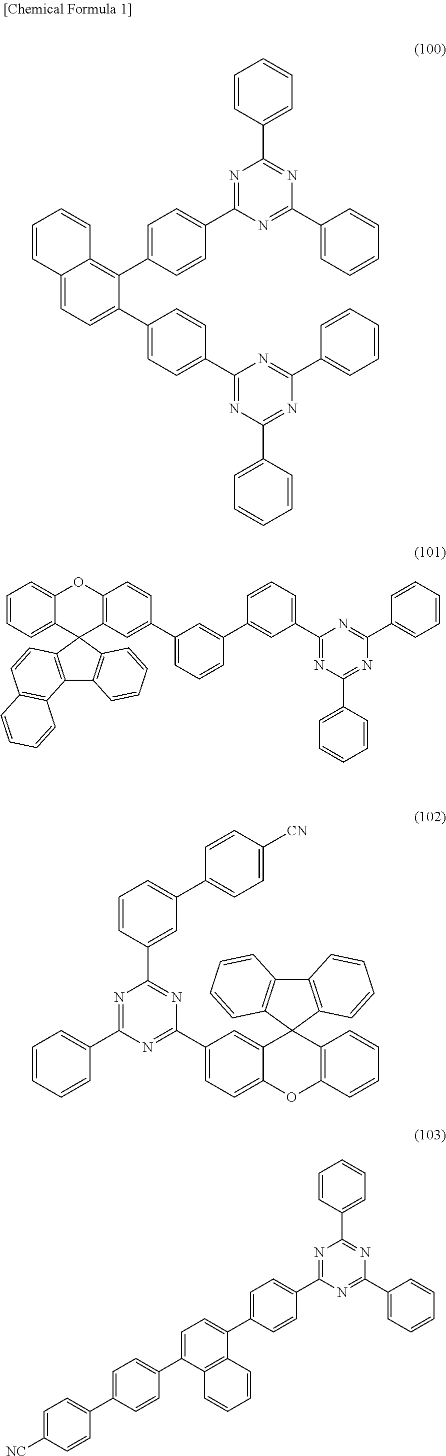 [SMILES: c1ccc(-c2nc(-c3ccccc3)nc(-c3ccc(-c4ccc5ccccc5c4-c4ccc(-c5nc(-c6ccccc6)nc(-c6ccccc6)n5)cc4)cc3)n2)cc1 ; c1ccc(-c2nc(-c3ccccc3)nc(-c3cccc(-c4cccc(-c5ccc6c(c5)C5(c7ccccc7O6)c6ccccc6-c6c5ccc5ccccc65)c4)c3)n2)cc1 ; N#Cc1ccc(-c2cccc(-c3nc(-c4ccccc4)nc(-c4ccc5c(c4)C4(c6ccccc6O5)c5ccccc5-c5ccccc54)n3)c2)cc1 ; N#Cc1ccc(-c2ccc(-c3ccc(-c4ccc(-c5nc(-c6ccccc6)nc(-c6ccccc6)n5)cc4)c4ccccc34)cc2)cc1]

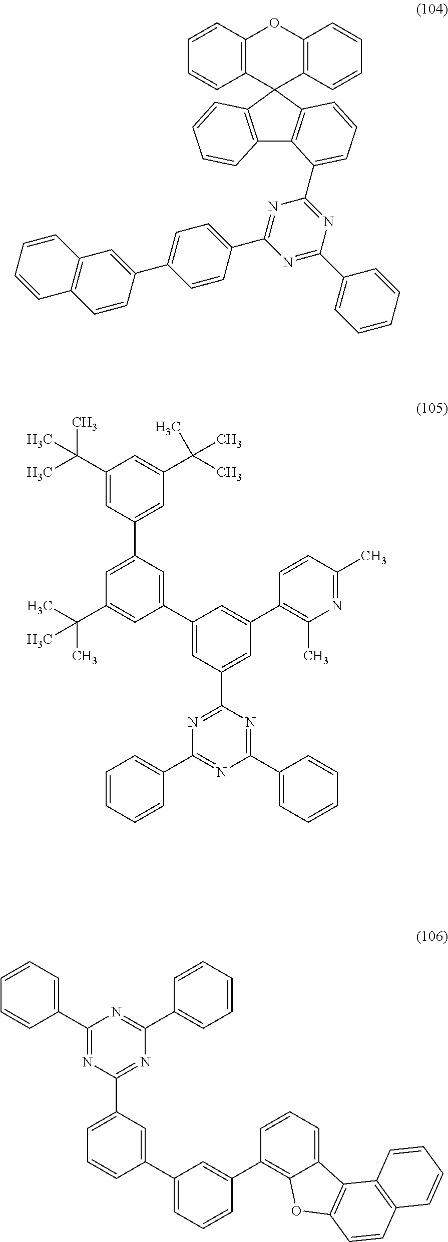 [SMILES: c1ccc(-c2nc(-c3ccc(-c4ccc5ccccc5c4)cc3)nc(-c3cccc4c3-c3ccccc3C43c4ccccc4Oc4ccccc43)n2)cc1 ; Cc1ccc(-c2cc(-c3cc(-c4cc(C(C)(C)C)cc(C(C)(C)C)c4)cc(C(C)(C)C)c3)cc(-c3nc(-c4ccccc4)nc(-c4ccccc4)n3)c2)c(C)n1 ; c1ccc(-c2nc(-c3ccccc3)nc(-c3cccc(-c4cccc(-c5cccc6c5oc5ccc7ccccc7c56)c4)c3)n2)cc1]

Note that an electron-transport layer included in a light-emitting unit on the anode side may include a seventh organic compound having a triazine skeleton, like the electron-transport layer included in the light-emitting unit on the cathode side, or may include an eighth organic compound not having a triazine skeleton.

The electron-transport layer included in the light-emitting unit on the anode side preferably includes the seventh organic compound having a triazine skeleton in order to reduce power consumption. It is particularly preferable that the seventh organic compound included in the electron-transport layer be the same as the first organic compound in order to inhibit a manufacturing apparatus from becoming complex and offer a cost advantage in raw material procurement.

When the electron-transport layer included in the light-emitting unit on the anode side includes the eighth organic compound not having a triazine skeleton, the carrier-transport property can be easily controlled to provide a light-emitting device with better characteristics. The organic compound not having a triazine skeleton is preferably an organic compound that has a heteroaromatic ring having a pyridine skeleton or an organic compound that has a heteroaromatic ring having a diazine (pyrimidine or pyrazine) skeleton. Note that any of the above organic compounds deuterated as appropriate can also be used.

The above-described second organic compound having a phenanthroline skeleton and included in the intermediate layer preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has a property of transporting more electrons than holes.

The second organic compound having a phenanthroline skeleton preferably has the phenanthroline skeleton and an aromatic ring. The aromatic ring is preferably a monocyclic aromatic ring, a polycyclic aromatic ring, or the like.

Examples of the monocyclic aromatic ring include a benzene ring, a pyrrole ring, a pyridine ring, and a pyrimidine ring. Preferable examples of the polycyclic aromatic ring include heteroaromatic rings such as a phenanthroline ring and a pyrrole ring, as well as aromatic hydrocarbon rings such as a naphthalene ring, a phenanthrene ring, a chrysene ring, a triphenylene ring, and a fluorene ring. It is particularly preferable that the second organic compound have a plurality of such polycyclic aromatic rings to improve its heat resistance or electron-transport property.

The second organic compound having a phenanthroline skeleton can be, for example, an organic compound that has a heteroaromatic ring having a phenanthroline skeleton, such as bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen), and is preferably PnNPhen represented by Structural Formula (200) below, mPPhen2P represented by (201) below, or the like.

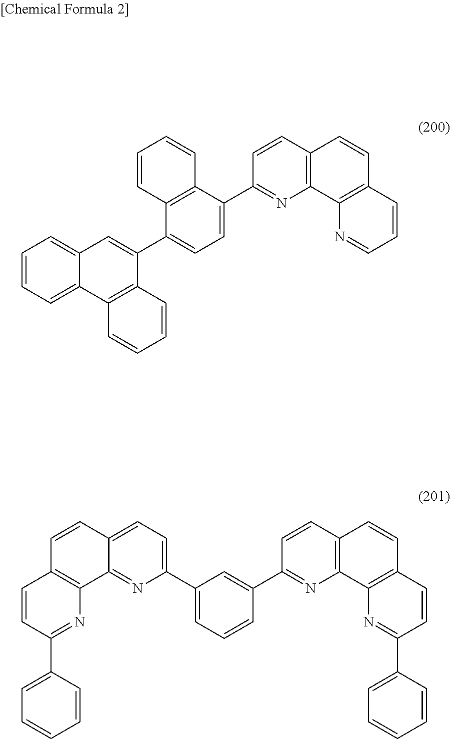 [SMILES: c1ccc2c(c1)cc(-c1ccc(-c3ccc4ccc5cccnc5c4n3)c3ccccc13)c1ccccc12 ; c1ccc(-c2ccc3ccc4ccc(-c5cccc(-c6ccc7ccc8ccc(-c9ccccc9)nc8c7n6)c5)nc4c3n2)cc1]

In the light-emitting device of one embodiment of the present invention, the intermediate layer can have any structure as long as it includes the second organic compound having a phenanthroline skeleton and can inject electrons and holes respectively into the light-emitting unit on the anode side and the light-emitting unit on the cathode side, which are in contact with the intermediate layer, by voltage application between the anode and the cathode. Note that the intermediate layer preferably has a stacked-layer structure of a first layer including the second organic compound and a second layer positioned closer to the cathode than the first layer is.

The first layer preferably includes a metal or a metal compound in addition to the second organic compound. The metal or a metal of the metal compound is preferably an alkali metal (Group 1 element) such as Li, an alkaline earth metal (Group 2 element) such as Mg or Ca, a Group 3 element including Y and lanthanoids such as Eu and Yb, a Group 11 element such as Cu, Ag, or Au, a Group 12 element such as Zn, an earth metal (Group 13 element) such as Al or In.

Note that the first layer may have a stacked-layer structure of a layer including an organic compound and a layer including a metal or a metal compound and positioned closer to the cathode than the layer including an organic compound is, or may be a mixed layer of an organic compound and a metal or a metal compound. The first layer is preferably the mixed layer, in which case it requires a smaller number of film formation chambers and a lower manufacturing cost and contributes to an improvement in the stability of the light-emitting device.

In the case where the organic compound and the metal or the metal compound are mixed, the organic compound and the metal or the metal compound tend to show substantially the same distribution when the first layer is analyzed in the thickness direction. That is, when the organic compound is uniformly distributed, the metal or the metal compound is also substantially uniformly distributed. In the case of the stacked-layer structure of the layer including the organic compound and the layer including the metal or the metal compound, the metal or the metal compound is sometimes diffused from the layer including the metal or the metal compound and detected also in a region other than the layer but shows a distribution different from that of the organic compound; thus, the analysis results of diffusion and mixing can be distinguished from each other.

In the case where the metal or the metal compound is detected over a region having a thickness greater than or equal to 10 nm, preferably greater than or equal to 15 nm, further preferably greater than or equal to 20 nm when the first layer is analyzed in the thickness direction, the first layer can be regarded as including a mixed layer in which the organic compound and the metal or the metal compound are mixed.

The metal or a metal of the metal compound is preferably, among others, a substance exhibiting a donor property with respect to the second organic compound. Examples of the substance exhibiting a donor property with respect to the second organic compound include metals belonging to Groups 1 and 2; lithium or a lithium compound is particularly preferable. Specifically, Li, lithium fluoride (LiF), lithium oxide (Li₂O), 8-hydroxyquinolinato-lithium (abbreviation: Liq), or the like is preferable. In the case where the first layer includes the second organic compound and the substance exhibiting a donor property with respect to the second organic compound, electrons are generated by charge separation, and the electrons are injected into the light-emitting unit on the anode side through the second organic compound when voltage is applied between the anode and the cathode. Thus, the light-emitting device of one embodiment of the present invention can have a low driving voltage.

The second organic compound is preferably an organic compound having a phenanthroline skeleton having an electron-donating substituent, as well as the above-described organic compound. A phenanthroline skeleton is likely to interact with a metal or the like, and when the second organic compound having such a phenanthroline skeleton further has an electron-donating group, the phenanthroline skeleton can have a higher electron density and become more likely to interact with the metal or the metal compound. In particular, the use of a metal belonging to Group 3, 11, 12, or 13 as the metal or a metal of the metal compound makes it possible to provide a tandem light-emitting device which is inhibited from having an increase in driving voltage and which has favorable characteristics.

Specific examples of the electron-donating group include an alkyl group, an alkoxy group, an aryloxy group, an alkylamino group, an arylamino group, and a heterocyclic amino group. Note that examples of the electron-donating group that is preferably introduced to the phenanthroline ring are not limited to the above examples. The electron-donating group may be any group that can increase the electron density of the phenanthroline ring by being introduced to the phenanthroline ring. The electron-donating group may be introduced to the phenanthroline ring via an arylene group such as a phenylene group, and the arylene group is preferably a p-phenylene group.

Specific examples of the organic compound that can be used as the second organic compound are shown in Structural Formulae (300) to (311).

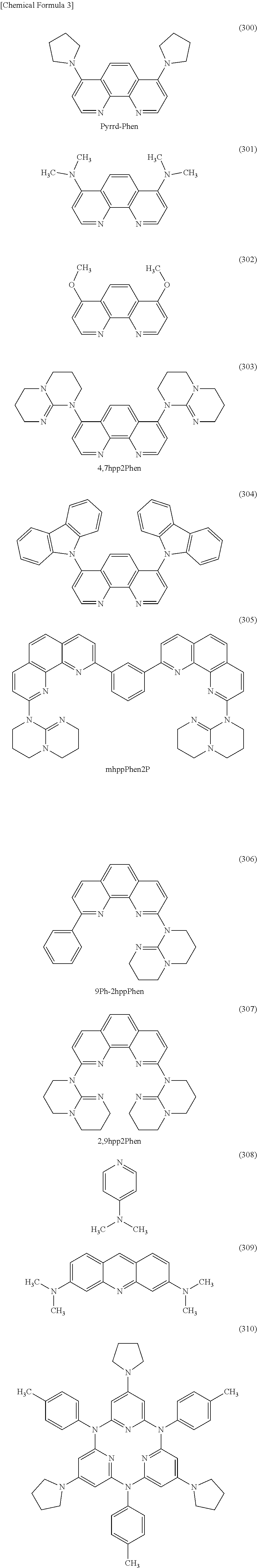

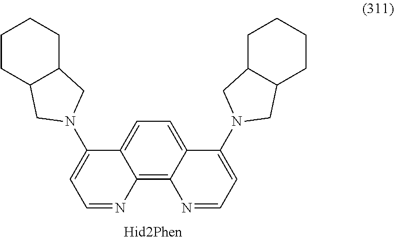 [SMILES: c1cc(N2CC3CCCCC3C2)c2ccc3c(N4CC5CCCCC5C4)ccnc3c2n1]

Note that the first layer preferably includes a Group 1 or Group 2 element, especially lithium or a lithium compound, and the second organic compound having a phenanthroline skeleton having an electron-donating substituent, in which case the tandem light-emitting device can have a lower driving voltage and higher reliability. Moreover, the first layer preferably includes a Group 1 or Group 2 element, especially lithium or a lithium compound, and the second organic compound having a phenanthroline skeleton having an electron-donating substituent, in which case it is possible to inhibit an increase in driving voltage due to processing of an organic compound layer of the light-emitting device by a photolithography method.

Among organic compounds having a phenanthroline ring, an organic compound having a 1,10-phenanthroline ring, the two nitrogen atoms of which can be coordinated to a metal, is particularly preferably used as the second organic compound in the intermediate layer having the above-described structure to facilitate interaction with the metal or the metal compound.

In the case where an electron-donating group is introduced to a 1,10-phenanthroline skeleton, the electron-donating group is preferably substituted at the 4- and 7-positions of the 1,10-phenanthroline skeleton. Introducing electron-donating groups to the 4- and 7-positions of the 1,10-phenanthroline skeleton can increase the electron density of the nitrogen atoms at the 1- and 10-positions, thereby facilitating the interaction with the metal or the metal compound.

The first layer may further include an organic compound different from the second organic compound. Note that the different organic compound preferably has an electron-transport property. It is particularly preferable that the organic compound have two or more heteroaromatic rings bonded or condensed to each other and the two or more heteroaromatic rings have three or more heteroatoms in total. The first layer including such an organic compound can improve the heat resistance, the electron-transport property, and the like.

The second layer preferably includes a ninth organic compound having a hole-transport property. The second layer preferably further includes a substance exhibiting an acceptor property, and the substance exhibiting an acceptor property is preferably an organic compound exhibiting an acceptor property with respect to the ninth organic compound. The substance having an acceptor property is particularly preferably an organic compound having at least one of a halogen group and a cyano group, further preferably an organic compound having at least one of fluorine and a cyano group. Note that it is further preferable that the total number of halogen groups (fluorines) and cyano groups of the organic compound be four or more.

In the case where the second layer includes the ninth organic compound and the substance exhibiting an acceptor property with respect to the ninth organic compound, holes are generated by charge separation, and the holes are injected into the light-emitting unit on the cathode side through the ninth organic compound when voltage is applied between the anode and the cathode. Thus, the light-emitting device of one embodiment of the present invention can have a low driving voltage.

The intermediate layer may include a third layer between the first layer and the second layer.

The third layer includes a substance having an electron-transport property and has functions of smoothly transferring and receiving electrons between the first layer and the second layer to reduce the driving voltage, and reducing the interaction between the first layer and the second layer to improve the reliability, for example.

The thickness of the third layer is preferably greater than or equal to 1 nm and less than or equal to 10 nm, further preferably greater than or equal to 2 nm and less than or equal to 5 nm, in which case an increase in driving voltage can be inhibited.

The light-emitting device of one embodiment of the present invention that has the above structure can have high current efficiency, low energy loss, and favorable characteristics. A display device of one embodiment of the present invention that includes such a light-emitting device can achieve low power consumption, high reliability, high-luminance display, and high visibility.

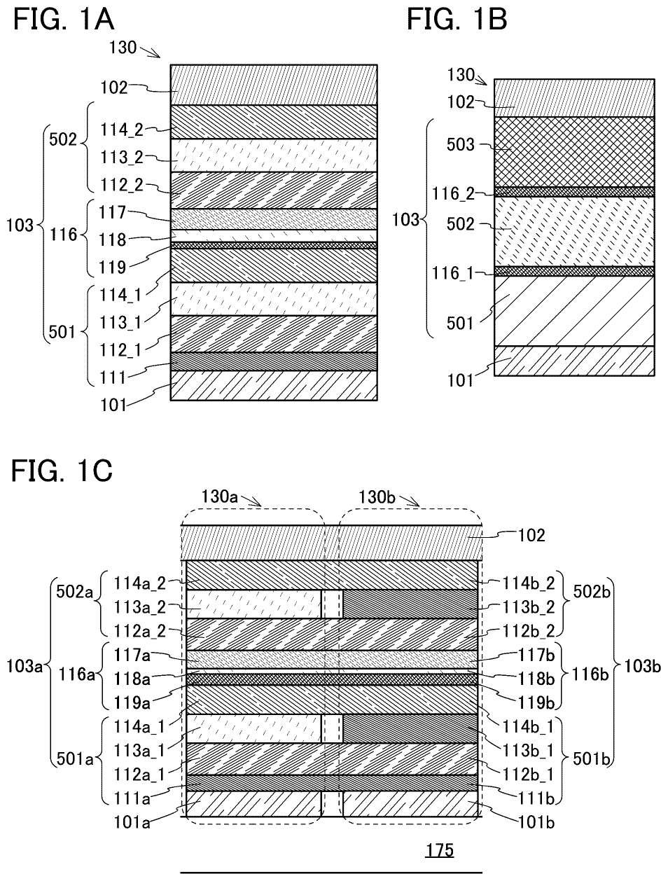

Next, light-emitting devices of embodiments of the present invention will be described in detail with reference to drawings. FIG. 1A illustrates a light-emitting device 130 of one embodiment of the present invention. The light-emitting device of one embodiment of the present invention is a tandem light-emitting device and includes an organic compound layer 103 (also referred to as an EL layer) that includes a first light-emitting unit 501 including a first light-emitting layer 113_1, a second light-emitting unit 502 including a second light-emitting layer 113_2 and a second electron-transport layer 114_2, and an intermediate layer 116, between a first electrode 101 including an anode and a second electrode 102 including a cathode. Note that the first light-emitting unit may include a first electron-transport layer 114_1 between the first light-emitting layer 113_1 and the intermediate layer 116.

In the light-emitting device 130, the second electron-transport layer 114_2 includes the first organic compound having a triazine skeleton, and the intermediate layer 116 includes the second organic compound having a phenanthroline skeleton. The second electron-transport layer 114_2 including the first organic compound having a triazine skeleton is preferably in contact with the second electrode 102 in order to reduce power consumption.

Although light-emitting devices each including one intermediate layer 116 and two light-emitting units are described as examples in this embodiment, a light-emitting device including n intermediate layer(s) (n is an integer greater than or equal to 1) and n+1 light-emitting units may be employed. For example, the light-emitting device 130 illustrated in FIG. 1B is an example of a tandem light-emitting device in which n is 2 and which includes the first light-emitting unit 501, a first intermediate layer 116_1, the second light-emitting unit 502, a second intermediate layer 116_2, and a third light-emitting unit 503.

The first light-emitting unit 501 and the second light-emitting unit 502 may include a functional layer in addition to the light-emitting layers and the electron-transport layers described above. Although FIG. 1A illustrates the structure in which the first light-emitting unit 501 is provided with a hole-injection layer 111 and a first hole-transport layer 112_1 in addition to the first light-emitting layer 113_1 and the first electron-transport layer 114_1 and the second light-emitting unit 502 is provided with a second hole-transport layer 112_2 in addition to the second light-emitting layer 113_2 and the second electron-transport layer 114_2, the structure of the organic compound layer 103 in one embodiment of the present invention is not limited thereto and any of the layers may be omitted or other layers may be added. Typical examples of the other layers include a carrier-blocking layer and an exciton-blocking layer.

The first electrode 101 includes the anode. The first electrode 101 may have a stacked-layer structure, in which case a layer in contact with the organic compound layer 103 functions as the anode. The anode is preferably formed using a metal, an alloy, a conductive compound, or a mixture thereof each having a high work function (specifically, higher than or equal to 4.0 eV), for example. Specific examples include indium oxide-tin oxide (ITO: indium tin oxide), indium oxide-tin oxide containing silicon or silicon oxide, indium oxide-zinc oxide, and indium oxide containing tungsten oxide and zinc oxide (IWZO). Films of such conductive metal oxides are usually formed by a sputtering method, but may be formed by a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used for the anode. Graphene can also be used for the anode. Note that an electrode material can be selected regardless of the work function when the composite material forming a second layer 117 in the above intermediate layer 116 is used for the layer (typically the hole-injection layer) in contact with the anode.

The hole-injection layer 111 is provided in contact with the anode and has a function of facilitating injection of holes into the organic compound layer 103 (the first light-emitting unit 501). The hole-injection layer 111 can be formed using a phthalocyanine-based compound or a complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example.

The hole-injection layer 111 may be formed using a substance having an electron-acceptor property. Examples of the substance having an acceptor property include organic compounds having an electron-withdrawing group (e.g., a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene) malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds. Alternatively, the hole-injection layer 111 can be formed using a phthalocyanine-based compound or a complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example. The substance having an acceptor property can extract electrons from an adjacent hole-transport layer (or hole-transport material) by application of an electric field.

The hole-injection layer 111 is preferably formed using a composite material containing any of the aforementioned materials having an acceptor property and a substance having a hole-transport property.

As the substance having a hole-transport property and used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the substance having a hole-transport property and used in the composite material preferably has a hole mobility higher than or equal to 1×10⁻⁶ cm²/Vs. The substance having a hole-transport property and used in the composite material is preferably a compound having a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least any one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such a substance having a hole-transport property further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of the amine through an arylene group may be used. Note that the substance having a hole-transport property preferably has an N,N-bis(4-biphenyl)amino group to enable fabricating a light-emitting device having a long lifetime.

Specific examples of the substance having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF (4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBAIBP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-[3-(triphenylsilyl)phenyl]-9′H-9,3′:6′,9″-tercarbazole (abbreviation: PSiCzGI).

Examples of the aromatic amine compounds that can be used as the substance having a hole-transport property include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances having an acceptor property, an organic compound having an acceptor property is easy to use because the organic compound is easily deposited by evaporation as a film.

The hole-transport layer (the first hole-transport layer 112_1 or the second hole-transport layer 112_2) includes an organic compound having a hole-transport property. The organic compound having a hole-transport property preferably has a hole mobility higher than or equal to 1× 10⁻⁶ cm²/Vs.

Examples of the above organic compound having a hole-transport property include the following compounds: compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-9-(4-biphenyl)-9′-(triphenylen-2-yl)-3,3′-9H,9′H-bicarbazole, 9-3,3′-9H,9′H-bicarbazole, (triphenylen-2-yl)-9′-[1,1′:3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, and 9-[3-(triphenylsilyl)phenyl]-3,9′-bi-9H-carbazole (abbreviation: PSiCzCz); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. Any of the organic compounds given as examples of the substance having a hole-transport property and used in the composite material in the hole-injection layer 111 can also be suitably used as the material included in the hole-transport layer 112. Note that any of the above organic compounds deuterated as appropriate can also be used.

Note that the first hole-transport layer 112_1 and the second hole-transport layer 112_2 preferably include organic compounds having the same skeleton, and further preferably include the same compound. One or both of the first hole-transport layer 112_1 and the second hole-transport layer 112_2 may have a stacked-layer structure. When the hole-transport layer 112 has a stacked-layer structure and its layer closer to the light-emitting layer 113 includes an organic compound having high electron tolerance and/or an organic compound having an electron-blocking property, the light-emitting device can have high reliability. In the case where the hole-transport layer 112 has a stacked-layer structure, its layer closer to the light-emitting layer 113 preferably includes a material having a high hole-transport property, a low electron-transport property, and a high LUMO level. The LUMO level of the material is preferably higher than that of a material having the highest constituent ratio among the materials included in the light-emitting layer or a material having the highest LUMO level among the materials included in the light-emitting layer, further preferably by 0.30 eV or more. The material is preferably an organic compound having an amine skeleton and a polycyclic heteroaromatic ring, further preferably an organic compound having an amine skeleton and a furan skeleton or a dibenzofuran skeleton. In the case where the hole-transport layer 112 has a stacked-layer structure and its layer closer to the light-emitting layer 113 includes the above-described material, electrons can be prevented from passing from the light-emitting layer 113 to the first electrode 101 side, which enables manufacturing a display device with high efficiency and a long lifetime. Note that in the hole-transport layer 112 having a stacked-layer structure, its layer closer to the first electrode 101 preferably includes an organic compound having an amine skeleton and a polycyclic hydrocarbon, further preferably an organic compound having an amine skeleton and a fluorene skeleton. An organic compound having an amine skeleton and a fluorene skeleton has high reliability and a high hole-transport property and is thus preferably used to reduce the power consumption of the light-emitting device.

The light-emitting layers (the first light-emitting layer 113_1 and the second light-emitting layer 113_2) each preferably include an emission center substance and a host material. At least one of the light-emitting layers has a structure in which the emission center substance, the first host material, and the second host material are included and the first host material and the second host material are organic compounds forming an exciplex in combination; it is preferable that both the first light-emitting layer 113_1 and the second light-emitting layer 113_2 have this structure. The light-emitting layers may additionally include another material.

The first light-emitting layer 113_1 and the second light-emitting layer 113_2 preferably emit light of similar colors. For example, red, green, and blue pixels are often used in a full-color display device. In a light-emitting device used in a red pixel, both the first light-emitting layer 113_1 and the second light-emitting layer 113_2 emit red light. In a green pixel, both of the two light-emitting layers emit green light. In a blue pixel, both of the two light-emitting layers emit blue light. In that case, the difference in maximum peak wavelength between the emission spectrum of the compound as the emission center substance of the first light-emitting layer 113_1 and the emission spectrum of the compound as the emission center substance of the second light-emitting layer 113_2 is preferably less than or equal to 30 nm, further preferably less than or equal to 20 nm, still further preferably less than or equal to 10 nm. Note that it is further preferable that the first light-emitting layer 113_1 and the second light-emitting layer 113_2 include the same emission center substance. It is still further preferable that the first light-emitting layer 113_1 and the second light-emitting layer 113_2 be made of the same material.

The emission center substance may be a fluorescent substance, a phosphorescent substance, a substance exhibiting thermally activated delayed fluorescence (TADF), or any other light-emitting substance.

Examples of the fluorescent substance that can be used as the emission center substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene) propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl) acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene) propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine] (abbreviation: 1,6BnfAPrn-03), N,N′-diphenyl-N,N′-bis(9-phenyl-9H-carbazol-2-yl) naphtho[2,3-b;6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties and high emission efficiency or high reliability.

A preferable phosphorescent substance that can be used as the emission center substance in the light-emitting layer is a metal complex, or specifically, an iridium complex or a platinum complex, examples of which are as follows.

The examples include organometallic iridium complexes having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]) and tris(5-methyl-3,4-diphenyl-4H-1,2,4-triazolato)iridium(III) (abbreviation: [Ir(Mptz)₃]); organometallic iridium complexes having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic iridium complexes having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC)iridium(III) (abbreviation: CNImIr); organometallic complexes having a benzimizazolidene skeleton, such as tris[(6-tert-butyl-3-phenyl-2H-imidazo[4,5-b]pyrazin-1-yl-κC²)phenyl-κC²]iridium(III) (abbreviation: [Ir(cb)₃]); organometallic iridium complexes in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N, C^{2′}]iridium(III) acetylacetonate (abbreviation: FIracac); and platinum complexes such as (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC(II)platinum(II) (abbreviation: PtON-TBBI). These compounds emit blue-hued phosphorescent light and have an emission peak in the wavelength range from 450 nm to 520 nm. Alternatively, a compound obtained by substituting deuterium for part of hydrogen in any of these compounds can also be used.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C^{2′})iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridineκC]bis[2-(5-d₃-methyl-2-pyridinyl-κN²)phenyl-κC]iridium(III) (abbreviation: Ir(5mppy-d₃)₂(mbfpypy-d₃)), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d6)₂(mbfpypy-iPr-d₄)), [2-d₃-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d₃)), [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), [2-(4-methyl-5-phenyl-2-pyridinyl-κN)phenyl-κC]bis[2-(2-pyridinyl-κN)phenyl-κC]iridium (abbreviation: [Ir(ppy)₂(mdppy)]), and tris{2-[5-(methyl-d₃)-4-phenyl-2-pyridinyl-κN]phenyl-κC}iridium(III) (abbreviation: Ir(5m4dppy-d₃)₃); organometallic platinum complexes such as (2-{1-(5-tert-butylbiphenyl-2-yl)-4-[3-tert-butyl-5-(4-phenyl-2-pyridinyl-κN)phenyl-κC⁶]-2-benzimidazolyl-κN³}-4,6-di-tert-butylphenolato-κO)platinum(II) (abbreviation: Pt(tBudppymmtBubiz-tBubp)) and [2-(4-(3,5-di-tert-butylphenyl)-6-{3-[4-(5′-tert-butyl[1,1′:3′,1″-terphenyl]-2′-yl)-2-pyridinyl-κN]phenyl-κC²}-2-pyridinyl-κN)phenolato-κO]platinum(II) (abbreviation: Pt(4tButpppypyp-mmtBup)); and rare earth metal complexes such as tris(acetylacetonato)(monophenanthroline)terbium(III) (abbreviation: [Tb(acac)₃(Phen)]). These compounds mainly emit green-hued phosphorescent light and have an emission peak in the wavelength range from 500 nm to 600 nm. Note that organometallic iridium complexes having a pyrimidine skeleton have distinctively high reliability or emission efficiency and thus are particularly preferable. Alternatively, a compound obtained by substituting deuterium for part of hydrogen in any of these compounds can also be used.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(dlnpm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato) (dipivaloylmethanato)iridium(III) (abbreviation: [Ir(tppr)₂(dpm)]), and (acetylacetonato)bis[2,3-bis(4-fluorophenyl) quinoxalinato]iridium(III) (abbreviation: [Ir(Fdpq)₂(acac)]); organometallic iridium complexes having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-κN]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato) (monophenanthroline) europium (III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit red-hued phosphorescent light and have an emission peak in the wavelength range from 600 nm to 700 nm. Furthermore, the organometallic iridium complexes having a pyrazine skeleton can provide red light emission with favorable chromaticity. Alternatively, a compound obtained by substituting deuterium for part of hydrogen in any of these compounds can also be used.

Note that in one embodiment of the present invention, the use of a deuterated compound as the emission center substance improves the emission efficiency. Thus, the emission center substance is preferably a deuterated material.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

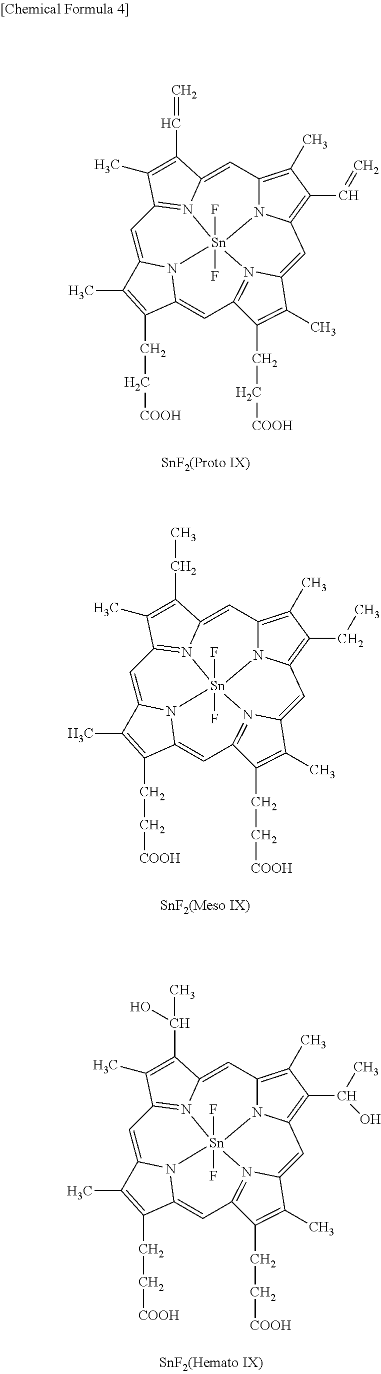

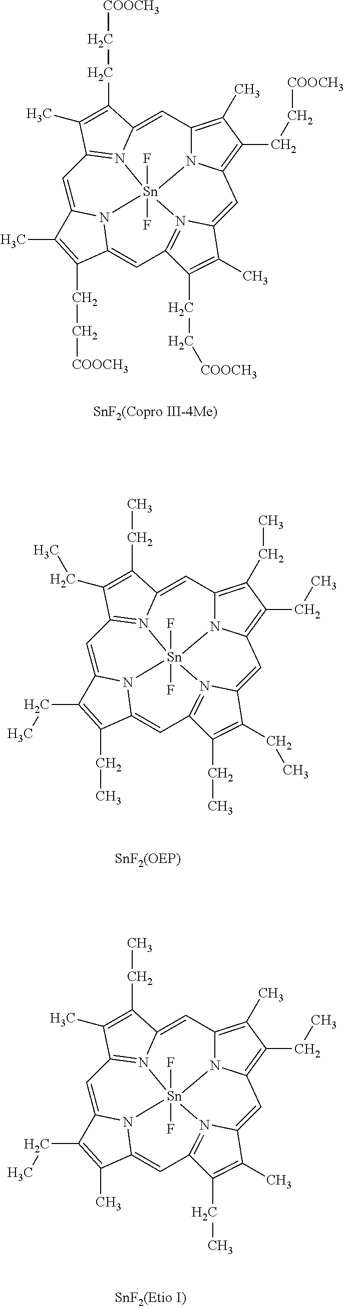

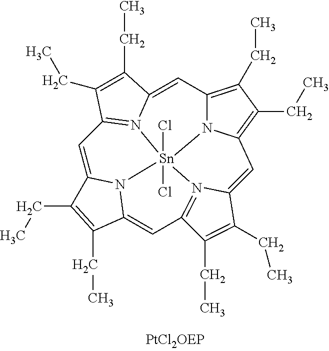

Alternatively, it is possible to use a heterocyclic compound with one or both of a π-electron rich heteroaromatic ring and a π-electron deficient heteroaromatic ring that is represented by any of the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). These heterocyclic compounds are preferable because of having high electron-transport and hole-transport properties owing to the π-electron rich heteroaromatic ring and the π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which a π-electron rich heteroaromatic ring is directly bonded to a T-electron deficient heteroaromatic ring is particularly preferable because the electron-donating property of the π-electron rich heteroaromatic ring and the electron-accepting property of the π-electron deficient heteroaromatic ring are both enhanced, the energy difference between the lowest singlet excited level (S₁ level) and the lowest triplet excited level (T₁ level) becomes small, and thus thermally activated delayed fluorescence can be obtained with high efficiency. Note that an aromatic ring to which an electron-withdrawing group such as a cyano group is bonded may be used instead of a π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton including boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of a π-electron deficient heteroaromatic ring and a π-electron rich heteroaromatic ring.

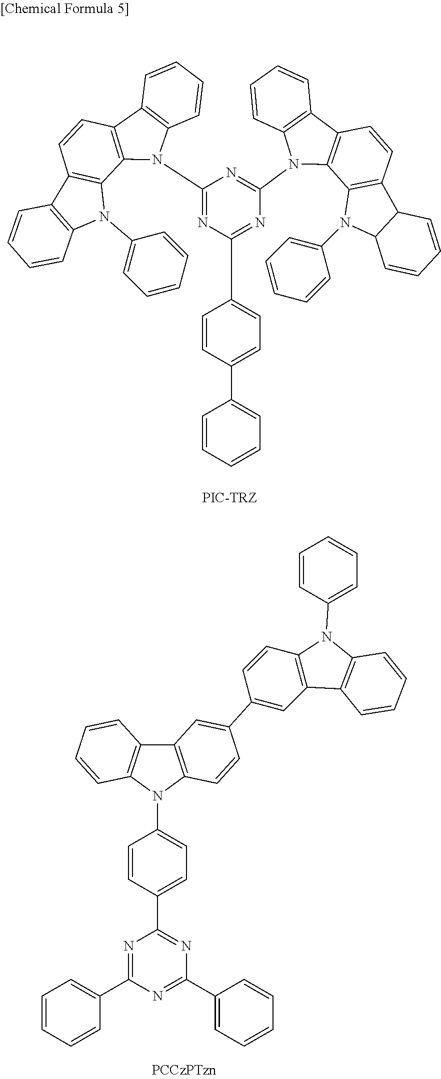 [SMILES: C1=CC2c3ccc4c5ccccc5n(-c5nc(-c6ccc(-c7ccccc7)cc6)nc(-n6c7ccccc7c7ccc8c9ccccc9n(-c9ccccc9)c8c76)n5)c4c3N(c3ccccc3)C2C=C1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

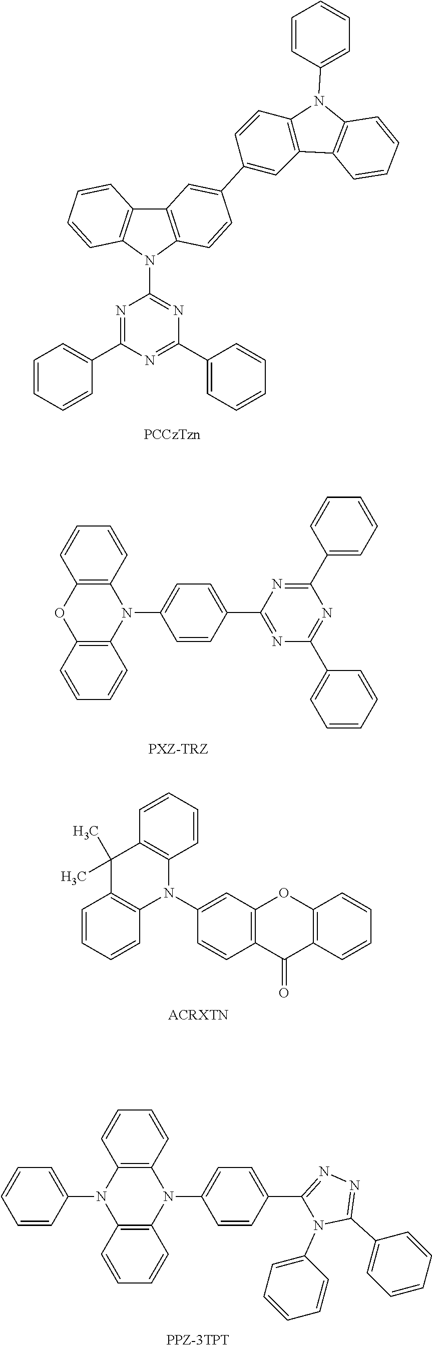 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; CC1(C)c2ccccc2N(c2ccc3c(=O)c4ccccc4oc3c2)c2ccccc21 ; c1ccc(-c2nnc(-c3ccc(N4c5ccccc5N(c5ccccc5)c5ccccc54)cc3)n2-c2ccccc2)cc1]

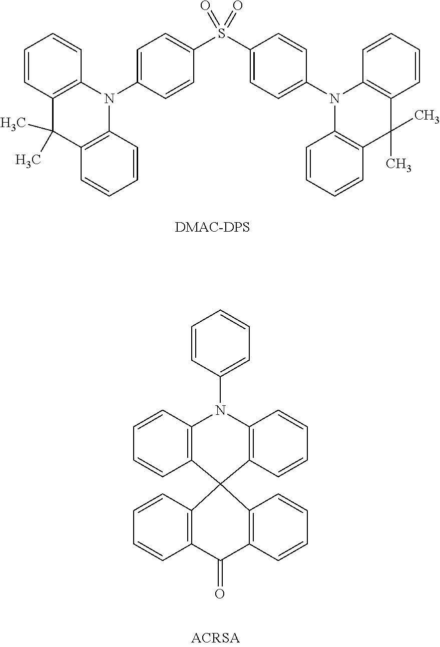

Alternatively, a TADF material whose singlet excited state and triplet excited state are in a thermal equilibrium state may be used. Since such a TADF material enables a short emission lifetime (excitation lifetime), the efficiency of a light-emitting device in a high-luminance region can be less likely to decrease. Specifically, a material having the following molecular structure can be used.

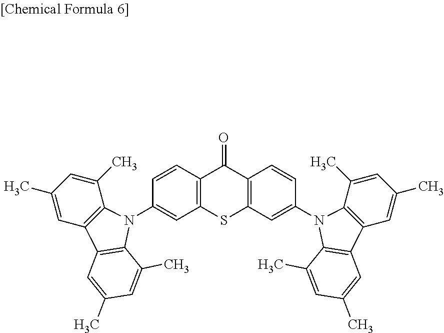

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at a low temperature (e.g., 77 K to 10 K) is used for an index of the T₁ level. When the level of energy with a wavelength of the line obtained by extrapolating a tangent to the fluorescent spectrum at a tail on the shorter wavelength side is the S₁ level and the level of energy with a wavelength of the line obtained by extrapolating a tangent to the phosphorescent spectrum at a tail on the shorter wavelength side is the T₁ level, the difference between the S₁ level and the T₁ level of the TADF material is preferably smaller than or equal to 0.3 eV, further preferably smaller than or equal to 0.2 eV.

When a TADF material is used as a light-emitting substance, the S₁ level of a host material is preferably higher than that of the TADF material. In addition, the T₁ level of the host material is preferably higher than that of the TADF material.

The structure in which the first host material and the second host material are used as the host materials in the light-emitting layer and the two materials form an exciplex has been already described in detail above, and the description is not repeated. In the case of a light-emitting layer not having this structure, any of a variety of carrier-transport materials such as an organic compound having an electron-transport property and/or an organic compound having a hole-transport property can be used as host material(s).

The organic compound having a hole-transport property is preferably an organic compound having an amine skeleton, a π-electron rich heteroaromatic ring, or the like. As the π-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such a substance having a hole-transport property further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of the amine through an arylene group may be used. Note that the substance having a hole-transport property is preferably an organic compound having an N,N-bis(4-biphenyl)amino group to enable fabricating a light-emitting device having a long lifetime.

Preferable examples of such organic compounds include the following organic compounds: compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBAIBP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 3,9-bis(9-phenyl-9H-carbazol-3-yl)-9H-carbazole (abbreviation: PCCzPC), 9-(biphenyl-4-yl)-9′-phenyl-3,3′-bi-9H-carbazole (abbreviation: PCCzBP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-[3-(triphenylsilyl)phenyl]-9′H-9,3′:6′,9″-tercarbazole (abbreviation: PSiCzGI); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. In addition, the organic compounds given as examples of the material with a hole-transport property that can be used for the hole-transport layer can also be used.

The organic compound having an electron-transport property is preferably an organic compound having a π-electron deficient heteroaromatic ring. Examples of the organic compound having a π-electron deficient heteroaromatic ring include an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above organic compounds, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

Preferable examples of the organic compound having a π-electron deficient heteroaromatic ring include the following organic compounds: organic compounds having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-ter-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl) stilbene (abbreviation: BzOS); organic compounds that have a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), and 2-[4-(2-triphenylenyl)phenyl]-1,10-phenanthroline (abbreviation: pTpPPhen); organic compounds having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl) (biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8 (βN2)-4mDBtPBfpm), 2,2′-(pyridine-2,6-diyl)bis(4-phenylbenzo[h]quinazoline) (abbreviation: 2,6 (P-Bqn) 2Py), 2,2′-(pyridine-2,6-diyl)bis{4-[4-(2-naphthyl)phenyl]-6-phenylpyrimidine} (abbreviation: 2,6 (NP-PPm) 2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 7-[4-(9-phenyl-9H-carbazol-2-yl) quinazolin-2-yl]-7H-dibenzo[c,g]carbazole (abbreviation: PC-cgDBCzQz), 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), and 2,2′-(2,2′-bipyridine-6,6′-diyl)bis(4-phenylbenzo[h]quinazoline) (abbreviation: 6,6′(P-Bqn) 2BPy); and organic compounds that have a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-[4-(2-naphthalenyl)phenyl]-4-phenyl-6-spiro[9H-fluorene-9,9′-[9H]xanthen]-4-yl-1,3,5-triazine (abbreviation: βNP-SFx(4)Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl) indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 3-phenyl-9-[4-phenyl-6-(9-phenyl-3-dibenzofuranyl)-1,3,5-triazin-2-yl]-9H-carbazole (abbreviation: PDBf-PCzTzn), 9-[4-(4,6-diphenyl-1,3,5-triazin-2-yl)-2-dibenzothienyl]-2-phenyl-9H-carbazole (abbreviation: PCzDBtTzn), and 2,4,6-tris(2-pyridyl)-1,3,5-triazine (abbreviation: 2Py3Tzn). The organic compound that has a heteroaromatic ring having a diazine skeleton, the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage.

In the case where a fluorescent substance is used as the emission center substance, a material having an anthracene skeleton is suitably used as the host material. The use of a substance having an anthracene skeleton as the host material for the fluorescent substance makes it possible to obtain a light-emitting layer with high emission efficiency and high durability. Among the substances having an anthracene skeleton, a substance having a diphenylanthracene skeleton, in particular, a substance having a 9,10-diphenylanthracene skeleton, is chemically stable and thus is preferably used as the host material. The host material preferably has a carbazole skeleton to have higher hole-injection and hole-transport properties; further preferably, the host material has a benzocarbazole skeleton in which a benzene ring is further condensed to a carbazole skeleton, because the HOMO level of the host material having a benzocarbazole skeleton is higher than that of the host material having a carbazole skeleton by approximately 0.1 eV and the host material having a benzocarbazole skeleton is thus easier for holes to enter than the host material having a carbazole skeleton. In particular, the host material preferably has a dibenzocarbazole skeleton, because the HOMO level of the host material having a dibenzocarbazole skeleton is higher than that of the host material having a carbazole skeleton by approximately 0.1 eV, the host material having a dibenzocarbazole skeleton is thus easier for holes to enter than the host material having a carbazole skeleton, and the host material having a dibenzocarbazole skeleton has a higher hole-transport property and higher heat resistance than the host material having a carbazole skeleton. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl) anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as a light-emitting substance, a phosphorescent substance can be used as an energy donor for supplying excitation energy to the fluorescent substance.

The first electron-transport layer 114_1 includes a substance having an electron-transport property. The substance having an electron-transport property preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has a property of transporting more electrons than holes. The above substance is preferably an organic compound that has a π-electron deficient heteroaromatic ring. The organic compound that has a π-electron deficient heteroaromatic ring is preferably one or more of an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton, and is particularly preferably an organic compound that has a heteroaromatic ring having a triazine skeleton.

As the organic compound that has an electron-transport property and that can be used in the first electron-transport layer 114_1, any of the aforementioned organic compounds that can be used as the organic compound with an electron-transport property serving as the host material in the first light-emitting layer 113_1 and the second light-emitting layer 113_2 can be used. Among the above organic compounds, the organic compound that has a heteroaromatic ring having a diazine skeleton, the organic compound that has a heteroaromatic ring having a pyridine skeleton, and the organic compound that has a heteroaromatic ring having a triazine skeleton are preferable because of having high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage.

The second electron-transport layer 114_2 is, as described above, a layer including the first organic compound having a triazine skeleton. Since the details have already been described, the description is omitted here.

Note that the first electron-transport layer 114_1 preferably includes the organic compound having a triazine skeleton to reduce power consumption. In particular, the organic compound having a triazine skeleton and included in the first electron-transport layer 114_1 and the first organic compound having a triazine skeleton and included in the second electron-transport layer 114_2 are preferably the same organic compound, which inhibits the complication of a manufacturing apparatus and is advantageous also in terms of raw material procurement cost.

Alternatively, when the first electron-transport layer 114_1 includes an organic compound not having a triazine skeleton, the carrier-transport property can be easily controlled to provide a light-emitting device with better characteristics. The organic compound not having a triazine skeleton is preferably an organic compound that has a heteroaromatic ring having a pyridine skeleton or an organic compound that has a heteroaromatic ring having a diazine (pyrimidine or pyrazine) skeleton.

The intermediate layer 116 includes the second organic compound having a phenanthroline skeleton. As illustrated in FIG. 1A, the intermediate layer 116 preferably includes a first layer 119 including the second organic compound having a phenanthroline skeleton. The intermediate layer 116 preferably includes the second layer 117 including the ninth organic compound having a hole-transport property and the substance having an acceptor property. The second layer 117 is positioned closer to the second electrode 102 than the first layer 119 is. The intermediate layer 116 may include a third layer 118 between the first layer 119 and the second layer 117.

The details of the first layer are described above and not repeated here.

The first layer 119 may further include an organic compound having an electron-transport property. As the organic compound having an electron-transport property, any of the aforementioned organic compounds that can be used as the organic compound with an electron-transport property serving as the host material in the first light-emitting layer 113_1 and the second light-emitting layer 113_2 can be used. The organic compound with an electron-transport property is preferably an organic compound having two or more heteroaromatic rings that are bonded or condensed to each other and that have three or more heteroatoms in total, in which case the resistance to a photolithography method can be improved and an increase in driving voltage can be inhibited.

Note that the first layer 119 may have a stacked-layer structure of a layer including an organic compound and a layer including a metal or a metal compound and positioned closer to the cathode than the layer including an organic compound is, or may be a mixed layer of an organic compound and a metal or a metal compound. The first layer 119 is preferably the mixed layer, in which case it requires a smaller number of film formation chambers and a lower manufacturing cost and contributes to an improvement in the stability of the light-emitting device.

In the case where the organic compound and the metal or the metal compound are mixed, the organic compound and the metal or the metal compound tend to show substantially the same distribution when the first layer 119 is analyzed in the thickness direction. That is, when the organic compound is uniformly distributed, the metal or the metal compound is also substantially uniformly distributed. In the case of the stacked-layer structure of the layer including the organic compound and the layer including the metal or the metal compound, the metal or the metal compound is sometimes diffused from the layer including the metal or the metal compound and detected also in a region other than the layer but shows a distribution different from that of the organic compound; thus, the analysis results of diffusion and mixing can be distinguished from each other.

The second layer 117 preferably includes the ninth organic compound having a hole-transport property. The second layer 117 preferably further includes a substance exhibiting an acceptor property, and the substance exhibiting an acceptor property is preferably an organic compound exhibiting an acceptor property with respect to the ninth organic compound.

In the case where the second layer 117 includes the ninth organic compound and the substance exhibiting an acceptor property with respect to the ninth organic compound, holes are generated by charge separation, and the holes are injected into the second light-emitting unit 502 on the cathode side through the ninth organic compound when voltage is applied between the first electrode 101 and the second electrode 102. Thus, the light-emitting device 130 of one embodiment of the present invention can have a low driving voltage.

As the ninth organic compound having a hole-transport property, any of a variety of organic compounds such as aromatic amine compounds, heteroaromatic compounds, aromatic hydrocarbons, and high molecular compounds (e.g., oligomers, dendrimers, and polymers) can be used. Note that the ninth organic compound preferably has a hole mobility higher than or equal to 1×10⁻⁶ cm²/Vs. The ninth organic compound preferably has a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least any one of a pyrrole skeleton, a furan skeleton, and a thiophene skeleton is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of the amine through an arylene group may be used. Note that the organic compound having a hole-transport property preferably has an N,N-bis(4-biphenyl)amino group to enable fabricating a light-emitting device having a long lifetime.

The above-described organic compound having a hole-transport property can specifically be any of the organic compounds given as examples of the organic compound with a hole-transport property that can be used in the hole-injection layer 111.

The substance with an acceptor property can be, for example, any of the substances given as examples of the organic compound with an acceptor property that can be used in the hole-injection layer 111. An organic compound having at least one of a halogen group and a cyano group is particularly preferable, and an organic compound having at least one of fluorine and a cyano group is further preferable. Note that it is further preferable that the total number of halogen groups (fluorines) and cyano groups of the organic compound be four or more. Examples of the organic compound having at least one of a halogen group and a cyano group include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile].

Note that the substance with an acceptor property preferably has an electron-accepting property with respect to the ninth organic compound having a hole-transport property. When the substance with an acceptor property has an electron-accepting property with respect to the ninth organic compound, charge separation occurs and the second layer 117 can function as a charge-generation layer and functions as an intermediate layer of the tandem light-emitting device. A signal is preferably observed by electron spin resonance in the second layer 117. For example, the density of spins attributed to a signal observed at a g-factor of approximately 2.00 is preferably higher than or equal to 1×10¹⁷ spins/cm³, further preferably higher than or equal to 1×10¹⁸ spins/cm³, still further preferably higher than or equal to 1×10¹⁹ spins/cm³.

The third layer 118 includes a substance with an electron-transport property and has functions of preventing the interaction between the first layer 119 and the second layer 117 and smoothly transferring and receiving electrons therebetween to reduce the driving voltage, and reducing the interaction between the first layer 119 and the second layer 117 to improve the reliability, for example.

The LUMO level of the substance with an electron-transport property that is included in the third layer 118 is preferably between the LUMO level of the substance with an acceptor property in the second layer 117 and the LUMO level of the organic compound included in a layer (e.g., the first electron-transport layer 114_1 in the first light-emitting unit 501 in FIG. 1A) that is in contact with the first layer 119 in the light-emitting unit on the anode side.

A specific energy level of the LUMO level of the substance with an electron-transport property that is used in the third layer 118 is preferably higher than or equal to −5.0 eV, further preferably higher than or equal to −5.0 eV and lower than or equal to −3.0 eV, still further preferably higher than or equal to −4.30 eV and lower than or equal to −3.00 eV, yet still further preferably higher than or equal to −4.30 eV and lower than or equal to −3.30 eV, in which case an increase in driving voltage can be inhibited. Note that the substance with an electron-transport property that is used in the third layer 118 is preferably a phthalocyanine-based material or a metal complex having a metal-oxygen bond and an aromatic ligand.

Specific examples of the substance with an electron-transport property that is used in the third layer 118 include perylenetetracarboxylic acid derivatives such as diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F6), 3,4,9,10-perylenetetracarboxylic diimide (abbreviation: PTCDI), and 3,4,9,10-perylenetetracarboxyl-bis-benzimidazole (abbreviation: PTCBI), (C₆₀—Iₕ) [5,6]fullerene (abbreviation: C₆₀), and (C₇₀-D₅ₕ)[5,6]fullerene (abbreviation: C₇₀). It is also possible to use a compound having a heterophane skeleton, which is a cyclophane skeleton having a hetero ring; for example, a phthalocyanine compound such as phthalocyanine (abbreviation: H₂Pc) can be used as the compound. Alternatively, it is possible to use a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use a phthalocyanine-based metal complex such as copper phthalocyanine or zinc phthalocyanine or 2,3,8,9,14,15-hexafluorodiquinoxalino[2,3-a:2′,3′-c]phenazine.

The thickness of the third layer 118 is preferably greater than or equal to 1 nm and less than or equal to 10 nm, further preferably greater than or equal to 2 nm and less than or equal to 5 nm.

Note that the second light-emitting unit 502 includes no hole-injection layer because the second layer 117 in the intermediate layer 116 functions as a hole-injection layer; however, the second light-emitting unit 502 may include a hole-injection layer.

The second electrode 102 includes the cathode. The second electrode 102 may have a stacked-layer structure, in which case a layer in contact with the organic compound layer 103 functions as the cathode. The cathode is preferably formed using a metal, an alloy, an electrically conductive compound, or a mixture thereof each having a low work function (specifically, lower than or equal to 3.8 eV), for example. Specific examples of such a cathode material include elements belonging to Group 1 and Group 2 of the periodic table, such as alkali metals (e.g., lithium (Li) or cesium (Cs)), magnesium (Mg), calcium (Ca), and strontium (Sr), alloys containing any of these elements (e.g., MgAg and AlLi), rare earth metals such as europium (Eu) and ytterbium (Yb), and alloys containing any of these rare earth metals. Specific examples thereof include alkali metals, alkaline earth metals, rare earth metals, compounds thereof, and complexes thereof, such as lithium fluoride (LiF), cesium fluoride (CsF), calcium fluoride (CaF₂), 8-hydroxyquinolinato-lithium (abbreviation: Liq), and ytterbium (Yb), and electrides. Examples of an electride include substances in which electrons are added at high concentration to calcium oxide-aluminum oxide. Note that a mixture of two or more of these materials may be used as a cathode material. In the case where the second electrode 102 has a stacked-layer structure, a material having high conductivity can be used for the layer(s) other than the cathode, regardless of the work function.

Note that the second electron-transport layer 114_2 is preferably in contact with the second electrode 102. When the second electron-transport layer 114_2 is in contact with the second electrode 102, the light-emitting device can have excellent electron-injection and electron-transport properties, a low driving voltage, and low power consumption.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

The organic compound layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different film formation methods may be used to form the electrodes or the layers described above.

FIG. 1C illustrates two adjacent light-emitting devices (a light-emitting device 130a and a light-emitting device 130b) included in a display device of one embodiment of the present invention.

The light-emitting device 130a includes an organic compound layer 103a between a first electrode 101a and the second electrode 102 over an insulating layer 175. The organic compound layer 103a has a structure in which a first light-emitting unit 501a and a second light-emitting unit 502a are stacked with an intermediate layer 116a therebetween. Although FIG. 1C illustrates an example in which the two light-emitting units are stacked, three or more light-emitting units may be stacked. The first light-emitting unit 501a includes a hole-injection layer 111a, a first hole-transport layer 112a_1, a first light-emitting layer 113a_1, and a first electron-transport layer 114a_1. The intermediate layer 116a includes a second layer 117a, a third layer 118a, and a first layer 119a. The third layer 118a may be present or absent. The second light-emitting unit 502a includes a second hole-transport layer 112a_2, a second light-emitting layer 113a_2, and a second electron-transport layer 114a_2.

The light-emitting device 130b includes an organic compound layer 103b between a first electrode 101b and the second electrode 102 over the insulating layer 175. The organic compound layer 103b has a structure in which a first light-emitting unit 501b and a second light-emitting unit 502b are stacked with an intermediate layer 116b therebetween. Although FIG. 1C illustrates an example in which the two light-emitting units are stacked, three or more light-emitting units may be stacked. The first light-emitting unit 501b includes a hole-injection layer 111b, a first hole-transport layer 112b_1, a first light-emitting layer 113b_1, and a first electron-transport layer 114b_1. The intermediate layer 116b includes a second layer 117b, a third layer 118b, and a first layer 119b. The third layer 118b may be present or absent. The second light-emitting unit 502b includes a second hole-transport layer 112b_2, a second light-emitting layer 113b_2, and a second electron-transport layer 114b_2.

The second electron-transport layer 114a_2 and the second electron-transport layer 114b_2 preferably include the first organic compound having a triazine skeleton. The first layer 119a and the first layer 119b each include the second organic compound having a phenanthroline skeleton.

The first light-emitting layer 113a_1 and the second light-emitting layer 113a_2 preferably emit light of similar colors. The difference in maximum peak wavelength between the emission spectrum of the compound as the emission center substance of the first light-emitting layer 113a_1 and the emission spectrum of the compound as the emission center substance of the second light-emitting layer 113a_2 is preferably less than or equal to 30 nm, further preferably less than or equal to 20 nm, still further preferably less than or equal to 10 nm. It is further preferable that the first light-emitting layer 113a_1 and the second light-emitting layer 113a_2 include the same emission center substance. The first light-emitting layer 113b_1 and the second light-emitting layer 113b_2 preferably emit light of similar colors. The difference in maximum peak wavelength between the emission spectrum of the compound as the emission center substance of the first light-emitting layer 113b_1 and the emission spectrum of the compound as the emission center substance of the second light-emitting layer 113b_2 is preferably less than or equal to 30 nm, further preferably less than or equal to 20 nm, still further preferably less than or equal to 10 nm. It is further preferable that the first light-emitting layer 113b_1 and the second light-emitting layer 113b_2 include the same emission center substance. Furthermore, it is preferable that the first light-emitting layer 113a_1 and the second light-emitting layer 113a_2 be made of the same material. It is preferable that one, further preferably both, of the first light-emitting layer 113a_1 and the second light-emitting layer 113a_2 have the above-described structure of the light-emitting layer of one embodiment of the present invention.

It is preferable that the first light-emitting layer 113a_1 and the first light-emitting layer 113b_1 be separated from each other and the second light-emitting layer 113a_2 and the second light-emitting layer 113b_2 be separated from each other. It is preferable that the emission color(s) of the first light-emitting layer 113a_1 and the second light-emitting layer 113a_2 be different from the emission color(s) of the first light-emitting layer 113b_1 and the second light-emitting layer 113b_2. It is preferable that the emission center substance included in the first light-emitting layer 113a_1 and the emission center substance included in the first light-emitting layer 113b_1 be different from each other and the emission center substance included in the second light-emitting layer 113a_2 and the emission center substance included in the second light-emitting layer 113b_2 be different from each other. Furthermore, it is preferable that the first light-emitting layer 113b_1 and the second light-emitting layer 113b_2 be made of the same material. It is preferable that one, further preferably both, of the first light-emitting layer 113b_1 and the second light-emitting layer 113b_2 have the above-described structure of the light-emitting layer of one embodiment of the present invention.

Note that each of the pairs of the hole-injection layers 111a and 111b, the first hole-transport layers 112a_1 and 112b_1, the first electron-transport layers 114a_1 and 114b_1, the intermediate layers 116a and 116b (the second layers 117a and 117b, the third layers 118a and 118b, and the first layers 119a and 119b), the second hole-transport layers 112a_2 and 112b_2, and the second electron-transport layers 114a_2 and 114b_2 may be one continuous layer or may be separate layers independent of each other between the light-emitting device 130a and the light-emitting device 130b. When these layers are continuous layers, the light-emitting devices can be fabricated with high productivity at low cost. When the layers are separate layers between the light-emitting devices, the layers can be formed using materials suitable for their emission colors, thereby enabling the light-emitting devices or a display device to have favorable characteristics. In particular, the second electron-transport layer 114a_2 and the second electron-transport layer 114b_2 are preferably one continuous layer, in which case both the light-emitting device 130a and the light-emitting device 130b can have favorable characteristics.

The second electron-transport layer 114a_2 and the second electron-transport layer 114b_2 being one continuous layer means that the second electron-transport layer 114a_2 and the second electron-transport layer 114b_2 are made of the same material. That is, when the second electron-transport layer 114a_2 and the second electron-transport layer 114b_2 are made of the same material, both the light-emitting device 130a and the light-emitting device 130b can have favorable characteristics. It is further preferable that the second electron-transport layer 114a_2 and the second electron-transport layer 114b_2 have similar structures, and it is still further preferable that the second electron-transport layer 114a_2 and the second electron-transport layer 114b_2 have the same structure.

Furthermore, in the case where the emission center substances included in the first light-emitting layers 113a_1 and 113b_1 are different from each other and the emission center substances included in the second light-emitting layers 113a_2 and 113b_2 are different from each other (e.g., in the case where the first light-emitting layer 113a_1 and the second light-emitting layer 113a_2 are blue fluorescent layers and the first light-emitting layer 113b_1 and the second light-emitting layer 113b_2 are green phosphorescent layers, in the case where the first light-emitting layers 113a_1 and 113a_2 are blue fluorescent layers and the first light-emitting layers 113b_1 and 113b_2 are red phosphorescent layers, or in the case where the first light-emitting layers 113a_1 and 113a_2 are green phosphorescent layers and the first light-emitting layers 113b_1 and 113b_2 are red phosphorescent layers), the light-emitting layers of the light-emitting devices 130a and 130b have different carrier balances. Therefore, in order to improve the performance of each of the light-emitting devices 130a and 130b, it is usually necessary to select and use an appropriate intermediate layer and an appropriate electron-transport layer for each light-emitting device. However, even when the second electron-transport layers 114a_2 and 114b_2 have the same structure, the use of the first organic compound having a triazine skeleton in the second electron-transport layers 114a_2 and 114b_2 and the use of the second organic compound having a phenanthroline skeleton in the first layers 119a and 119b can improve the performance of each of the light-emitting devices 130a and 130b. That is, both the productivity and the performance can be improved. Note that the first layers 119a and 119b may have the same structure.

Note that one continuous layer is what is called a common layer formed across the light-emitting devices 130a and 130b.

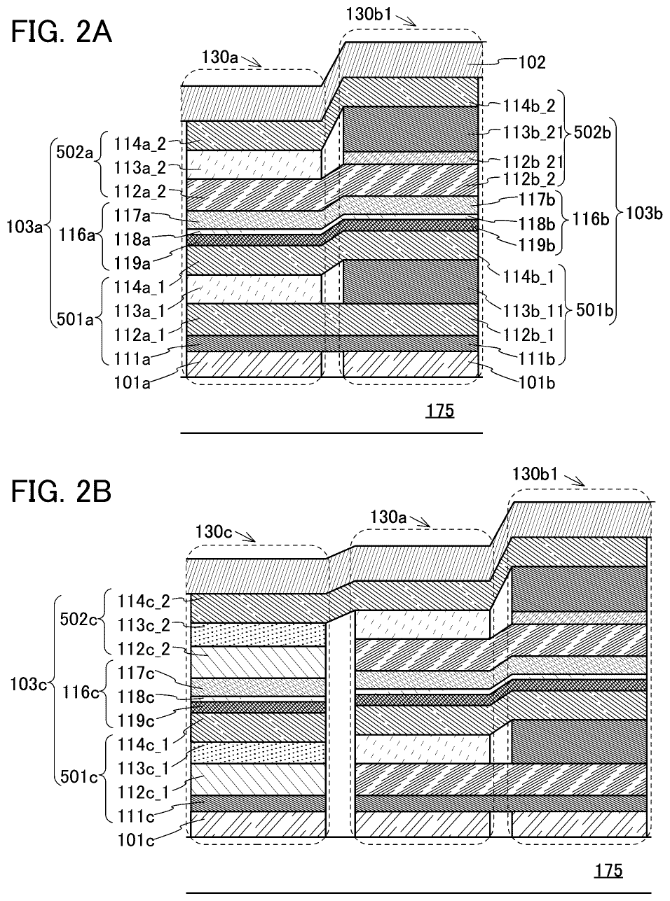

FIG. 2A is a modification example of FIG. 1C. The light-emitting device 130a and a light-emitting device 130b1 emit light of different colors and thus have different optical path lengths between the electrodes for amplification of emitted light using microcavity. In the light-emitting device 130b1, the distance between the electrodes can be adjusted by thickening light-emitting layers such as a light-emitting layer 113b_11 and a light-emitting layer 113b_21. Alternatively, the optical path length may be changed by thickening or adding a functional layer such as a hole-transport layer 112b_21.

FIG. 2B illustrates three adjacent light-emitting devices (the light-emitting device 130a, the light-emitting device 130b1, and a light-emitting device 130c) included in a display device of one embodiment of the present invention.

The light-emitting device 130c includes an organic compound layer 103c between a first electrode 101c and the second electrode 102 over the insulating layer 175. The organic compound layer 103c has a structure where a first light-emitting unit 501c and a second light-emitting unit 502c are stacked with an intermediate layer 116c therebetween. Although FIG. 2B illustrates an example in which the two light-emitting units are stacked, three or more light-emitting units may be stacked. The first light-emitting unit 501c includes a hole-injection layer 111c, a first hole-transport layer 112c_1, a first light-emitting layer 113c_1, and a first electron-transport layer 114c_1. The intermediate layer 116c includes a second layer 117c, a third layer 118c, and a first layer 119c. The third layer 118c may be present or absent. The second light-emitting unit 502c includes a second hole-transport layer 112c_2, a second light-emitting layer 113c_2, and a second electron-transport layer 114c_2.

It is assumed here that the light-emitting device 130c emits light whose wavelength is shorter than those of light from the light-emitting devices 130a and 130b1. The distance between the electrodes in the light-emitting device 130c is adjusted by the thicknesses of the first light-emitting layer 113c_1 and the second light-emitting layer 113c_2, which are smaller than those of the light-emitting layers in the other two light-emitting devices.

The second electron-transport layer 114c_2 includes the first organic compound having a triazine skeleton. The first layer 119c includes the second organic compound having a phenanthroline skeleton.

The first light-emitting layer 113c_1 and the second light-emitting layer 113c_2 preferably emit light of similar colors. The difference in maximum peak wavelength between the emission spectrum of the compound as the emission center substance of the first light-emitting layer 113c_1 and the emission spectrum of the compound as the emission center substance of the second light-emitting layer 113c_2 is preferably less than or equal to 30 nm, further preferably less than or equal to 20 nm, still further preferably less than or equal to 10 nm. It is further preferable that the first light-emitting layer 113c_1 and the second light-emitting layer 113c_2 include the same emission center substance. Furthermore, it is preferable that the first light-emitting layer 113c_1 and the second light-emitting layer 113c_2 be made of the same material. It is preferable that one, further preferably both, of the first light-emitting layer 113c_1 and the second light-emitting layer 113c_2 have the above-described structure of the light-emitting layer of one embodiment of the present invention.

It is preferable that the first light-emitting layer 113a_1 and the first light-emitting layer 113c_1 be separated from each other and the second light-emitting layer 113a_2 and the second light-emitting layer 113c_2 be separated from each other. It is preferable that the emission color(s) of the first light-emitting layer 113a_1 and the second light-emitting layer 113a_2 be different from the emission color(s) of the first light-emitting layer 113c_1 and the second light-emitting layer 113c_2. It is preferable that the emission center substance included in the first light-emitting layer 113a_1 and the emission center substance included in the first light-emitting layer 113c_1 be different from each other and the emission center substance included in the second light-emitting layer 113a_2 and the emission center substance included in the second light-emitting layer 113c_2 be different from each other.

Note that each of the pairs of the hole-injection layers 111a and 111c, the first hole-transport layers 112a_1 and 112c_1, the first electron-transport layers 114a_1 and 114c_1, the intermediate layers 116a and 116c (the second layers 117a and 117c, the third layers 118a and 118c, and the first layers 119a and 119c), and the second hole-transport layers 112a_2 and 112c_2 in this example are separate layers independent of each other between the light-emitting device 130a and the light-emitting device 130c, and the second electron-transport layers 114a_2 and 114c_2 in this example are a continuous layer. In this manner, one light-emitting device may include both continuous and separate layers. This allows the light-emitting device or the display device to balance productivity and characteristics. In particular, the second electron-transport layer 114a_2 and the second electron-transport layer 114c_2 are preferably one continuous layer, in which case both the light-emitting device 130a and the light-emitting device 130c can have favorable characteristics.

In the case where light-emitting devices exhibiting three colors consist of, for example, two light-emitting devices including fluorescent emission center substances and one light-emitting device including a phosphorescent emission center substance, the light-emitting devices including the fluorescent emission center substances preferably have one continuous carrier-transport layer, and the light-emitting device including the phosphorescent emission center substance preferably has a carrier-transport layer separated from that in the light-emitting devices exhibiting the other emission colors. Alternatively, in the case where light-emitting devices exhibiting three colors consist of two light-emitting devices including phosphorescent emission center substances and one light-emitting device including a fluorescent emission center substance, the light-emitting devices including the phosphorescent emission center substances preferably have one continuous carrier-transport layer, and the light-emitting device including the fluorescent emission center substance preferably has a carrier-transport layer separated from that in the light-emitting devices exhibiting the other emission colors.

The light-emitting device of one embodiment of the present invention that has such a structure can have high current efficiency, low energy loss, and favorable characteristics. A display device of one embodiment of the present invention that includes such a light-emitting device can achieve low power consumption, high reliability, high-luminance display, and high visibility. This embodiment can be freely combined with any of the other embodiments.

### Embodiment 2

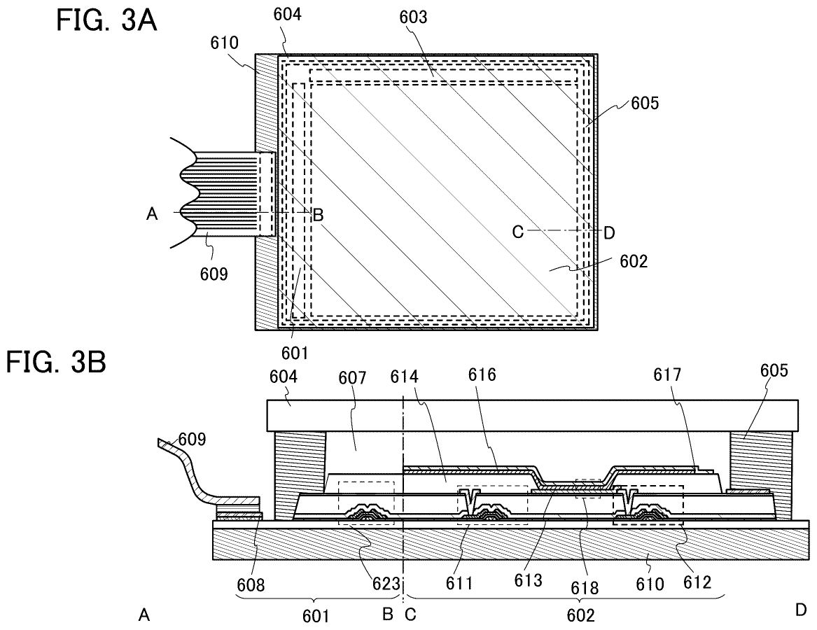

In this embodiment, a display device manufactured using the light-emitting device described in Embodiment 1 is described with reference to FIGS. 3A and 3B. Note that FIG. 3A is a top view of the display device and FIG. 3B is a cross-sectional view taken along the lines A-B and C-D in FIG. 3A. This display device includes a driver circuit portion (source line driver circuit) 601, a pixel portion 602, and a driver circuit portion (gate line driver circuit) 603, which are to control light emission of the light-emitting device and illustrated with dotted lines. Reference numeral 604 denotes a sealing substrate; 605, a sealing material; and 607, a space surrounded by the sealing material 605.

Reference numeral 608 denotes a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The display device in this specification includes, in its category, not only the display device itself but also the display device provided with the FPC or the PWB.

Next, a cross-sectional structure is described with reference to FIG. 3B. The driver circuit portions and the pixel portion are formed over an element substrate 610; FIG. 3B illustrates the source line driver circuit 601, which is a driver circuit portion, and one pixel in the pixel portion 602.

The element substrate 610 may be a substrate formed of glass, quartz, an organic resin, a metal, an alloy, or a semiconductor or a plastic substrate formed of fiber reinforced plastic (FRP), polyvinyl fluoride (PVF), polyester, or an acrylic resin.

The structure of transistors used in the pixels and the driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. It is preferable to use a semiconductor having crystallinity, in which case degradation of transistor characteristics can be inhibited.

Here, an oxide semiconductor is preferably used for semiconductor devices such as the transistors provided in the pixels and the driver circuits and transistors used for touch sensors described later, and the like. In particular, an oxide semiconductor having a wider band gap than silicon is preferably used. When an oxide semiconductor having a wider band gap than silicon is used, off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image in each display region is maintained. As a result, an electronic appliance with extremely low power consumption can be obtained.

For stable characteristics of the transistor and the like, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

Note that an FET 623 is illustrated as a transistor formed in the driver circuit portion 601. In addition, the driver circuit may be formed with any of a variety of circuits such as a CMOS circuit, a PMOS circuit, or an NMOS circuit. Although a driver integrated type in which the driver circuit is formed over the substrate is described in this embodiment, the driver circuit is not necessarily formed over the substrate, and can be formed outside.

The pixel portion 602 includes a plurality of pixels including a switching FET 611, a current controlling FET 612, and a first electrode 613 electrically connected to a drain of the current controlling FET 612. One embodiment of the present invention is not limited to the structure, and the pixel portion 602 may include three or more FETs and a capacitor in combination.

Note that an insulator 614 is formed to cover an end portion of the first electrode 613. Here, the insulator 614 can be formed using a positive photosensitive acrylic resin film.

In order to improve coverage with an organic compound layer or the like which is formed later, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 μm to 3 μm). For the insulator 614, either a negative photosensitive resin or a positive photosensitive resin can be used.

An organic compound layer 616 and a second electrode 617 are formed over the first electrode 613. Here, as a material used for the first electrode 613 functioning as an anode, a material having a high work function is preferably used. For example, a single-layer film of an ITO film, an indium tin oxide film including silicon, an indium oxide film including zinc oxide at 2 wt % to 20 wt %, a titanium nitride film, a chromium film, a tungsten film, a Zn film, a Pt film, or the like, a stack of a titanium nitride film and a film including aluminum as its main component, a stack of three layers of a titanium nitride film, a film including aluminum as its main component, and a titanium nitride film, or the like can be used. The stacked-layer structure enables low wiring resistance, favorable ohmic contact, and a function as an anode.

The organic compound layer 616 is formed by any of a variety of methods such as an evaporation method using an evaporation mask, an ink-jet method, and a spin coating method. The organic compound layer 616 has the structure described in Embodiment 1. As another material included in the organic compound layer 616, a low molecular compound or a high molecular compound (including an oligomer or a dendrimer) may be used.

As a material used for the second electrode 617, which is formed over the organic compound layer 616 and functions as a cathode, a material having a low work function (e.g., Al, Mg, Li, and Ca, or an alloy or a compound thereof, such as MgAg, MgIn, and AlLi) is preferably used. In the case where light generated in the organic compound layer 616 is transmitted through the second electrode 617, a stack of a thin metal film and a transparent conductive film (e.g., ITO, indium oxide containing zinc oxide at 2 wt % to 20 wt %, indium tin oxide containing silicon, or zinc oxide (ZnO)) is preferably used for the second electrode 617.

Note that the light-emitting device is formed with the first electrode 613, the organic compound layer 616, and the second electrode 617. The light-emitting device is the light-emitting device described in Embodiment 1. In the display device of this embodiment, the pixel portion, which includes a plurality of light-emitting devices, may include both the light-emitting device described in Embodiment 1 and a light-emitting device having a different structure.

The sealing substrate 604 is bonded to the element substrate 610 with the sealing material 605, so that a light-emitting device 618 is provided in the space 607 surrounded by the element substrate 610, the sealing substrate 604, and the sealing material 605. The space 607 may be filled with a filler, or may be filled with an inert gas (such as nitrogen or argon), or the sealing material. It is preferable that the sealing substrate be provided with a recessed portion and a drying agent be provided in the recessed portion, in which case deterioration due to the influence of moisture can be suppressed.

An epoxy-based resin or glass frit is preferably used for the sealing material 605. It is desirable that such a material not be permeable to moisture or oxygen as much as possible. As the sealing substrate 604, a glass substrate, a quartz substrate, or a plastic substrate formed of fiber reinforced plastic (FRP), polyvinyl fluoride (PVF), polyester, an acrylic resin, or the like can be used.

Although not illustrated in FIG. 3B, a protective film may be provided over the second electrode 617. As the protective film, an organic resin film or an inorganic insulating film may be formed. The protective film may be formed so as to cover an exposed portion of the sealing material 605. The protective film may be provided so as to cover surfaces and side surfaces of the pair of substrates and exposed side surfaces of a sealing layer, an insulating layer, and the like.

The protective film can be formed using a material that is less likely to transmit an impurity such as water. Thus, diffusion of an impurity such as water from the outside into the inside can be effectively suppressed.

As a material for the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a film formation method with favorable step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

As described above, the display device manufactured using the light-emitting device described in Embodiment 1 can be obtained.

The display device in this embodiment is manufactured using the light-emitting device described in Embodiment 1 and thus can have favorable characteristics. Specifically, since the light-emitting device described in Embodiment 1 has high emission efficiency, the display device can achieve low power consumption. Since the light-emitting device described in Embodiment 1 has high reliability, the display device can be highly reliable. In addition, since the light-emitting device described in Embodiment 1 can have favorable chromaticity and high color purity, the display device can achieve high display quality.

This embodiment can be freely combined with any of the other embodiments.

### Embodiment 3

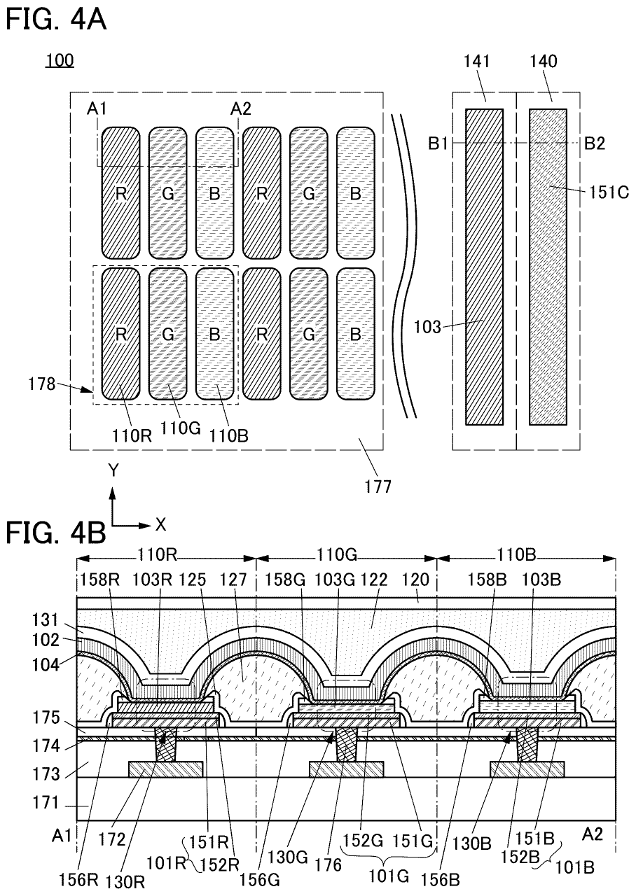

As illustrated in FIGS. 4A and 4B, a plurality of the light-emitting devices 130 are formed over the insulating layer 175 to constitute a display device. In this embodiment, the display device of another embodiment of the present invention will be described in detail.

A display device 100 includes a pixel portion 177 in which a plurality of pixels 178 are arranged in a matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and Y, and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 4A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. In the case where the region 141 is provided, the region 141 is provided between the pixel portion 177 and the connection portion 140. In the case where the region 141 is provided, an organic compound layer is provided in the region 141. A conductive layer 151C is provided in the connection portion 140.

Although FIG. 4A illustrates an example where the region 141 and the connection portion 140 are positioned on the right side of the pixel portion 177, the positions of the region 141 and the connection portion 140 are not particularly limited. The number of the regions 141 and the number of the connection portions 140 can each be one or more.

FIG. 4B is an example of a cross-sectional view along the dashed-dotted line A1-A2 in FIG. 4A. As illustrated in FIG. 4B, the display device 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 4B illustrates cross sections of a plurality of the inorganic insulating layers 125 and a plurality of the insulating layers 127, the inorganic insulating layers 125 are preferably connected to each other and the insulating layers 127 are preferably connected to each other when the display device 100 is seen from above.

In FIG. 4B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display device of one embodiment of the present invention can be, for example, a top-emission display device where light is emitted in the direction opposite to a substrate over which light-emitting devices are formed. Note that the display device of one embodiment of the present invention may be of a bottom emission type.

The light-emitting device 130R includes a first electrode 101R (pixel electrode) including a conductive layer 151R and a conductive layer 152R, an organic compound layer 103R over the first electrode, a common layer 104 over the organic compound layer 103R, and the second electrode 102 (common electrode) over the common layer 104. Although the common layer 104 is not necessarily provided, it is preferable to provide the common layer 104 to reduce damage to the organic compound layer 103R during processing.

The light-emitting device 130G includes a first electrode 101G (pixel electrode) including a conductive layer 151G and a conductive layer 152G, an organic compound layer 103G over the first electrode, the common layer 104 over the organic compound layer 103G, and the second electrode 102 (common electrode) over the common layer 104. Although the common layer 104 is not necessarily provided, it is preferable to provide the common layer 104 to reduce damage to the organic compound layer 103G during processing.

The light-emitting device 130B has a structure as described in Embodiment 1. The light-emitting device 130B includes a first electrode 101B (pixel electrode) including a conductive layer 151B and a conductive layer 152B, an organic compound layer 103B over the first electrode, the common layer 104 over the organic compound layer 103B, and the second electrode 102 (common electrode) over the common layer 104. Although the common layer 104 is not necessarily provided, it is preferable to provide the common layer 104 to reduce damage to the organic compound layer 103B during processing. Furthermore, in the case where the common layer 104 is provided, a stack of the organic compound layer 103B and the common layer 104 corresponds to the organic compound layer 103 described in Embodiment 1; in the case where the common layer 104 is not provided, the organic compound layer 103B corresponds to the organic compound layer 103 described in Embodiment 1.

Note that the common layer 104 is preferably an electron-transport layer. In the case where the common layer 104 is an electron-transport layer, it is preferable that the electron-transport layer have a stacked-layer structure, and it is further preferable that, among the stacked layers, a layer on the second electrode side be the common layer 104 and a layer on the light-emitting layer side be the organic compound layer 103.

The light-emitting devices 130R and 130G are manufactured through a photolithography process.

In the light-emitting device 130, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, 103G, and 103B are island-shaped layers that are independent of each other on a light-emitting device basis or on an emission color basis. Providing the island-shaped organic compound layer 103 in each of the light-emitting devices 130 can inhibit leakage current between the adjacent light-emitting devices 130 even in a high-resolution display device. This can prevent crosstalk, so that a display device with extremely high contrast can be obtained. Specifically, a display device having high current efficiency at low luminance can be obtained.

The island-shaped organic compound layer 103 is formed by forming an organic compound film and processing the organic compound film by a photolithography method.

The organic compound layer 103 is preferably provided to cover the top surface and the side surface of the first electrode (pixel electrode) of the light-emitting device 130. In this case, the aperture ratio of the display device 100 can be easily increased as compared to the structure where an end portion of the organic compound layer 103 is positioned inside an end portion of the pixel electrode. Covering the side surface of the pixel electrode of the light-emitting device 130 with the organic compound layer 103 can inhibit the pixel electrode from being in contact with the second electrode 102; hence, a short circuit of the light-emitting device 130 can be inhibited.

In the display device of one embodiment of the present invention, the first electrode (pixel electrode) of the light-emitting device preferably has a stacked-layer structure. For example, in the example illustrated in FIG. 4B, the first electrode of the light-emitting device 130 is a stack of the conductive layer 151 and the conductive layer 152.

A metal material can be used for the conductive layer 151, for example. Specifically, it is possible to use a metal such as aluminum (Al), titanium (T₁), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a work function higher than or equal to 4.0 eV, for example.

The conductive layer 151 and the conductive layer 152 may each be a stack of a plurality of layers including different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

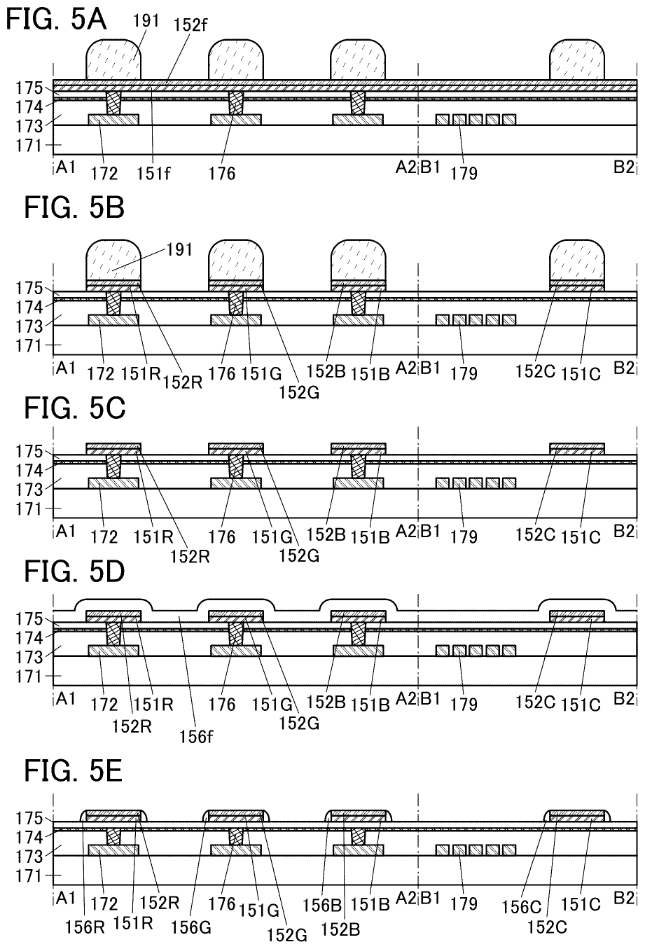

Next, an exemplary method for manufacturing the display device 100 having the structure illustrated in FIG. 4A is described with reference to FIGS. 5A to 5E, FIGS. 6A and 6B, FIGS. 7A to 7D, FIGS. 8A to 8C, FIGS. 9A to 9C, and FIGS. 10A to 10C. Note that although a light-emitting device is fabricated without using a metal mask in the following manufacturing method, the light-emitting device or the display device of one embodiment of the present invention may, of course, be fabricated by a typical evaporation method using a metal mask.

### Manufacturing Method Example 1

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like.

Thin films included in the display device (e.g., insulating films, semiconductor films, and conductive films) can also be formed by a wet process such as spin coating, dipping, spray coating, ink-jetting, dispensing, screen printing, offset printing, doctor blade coating, slit coating, roll coating, curtain coating, or knife coating.

Thin films included in the display device can be processed by a photolithography method, for example.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used.

For etching of thin films, a dry etching method, a wet etching method, a sandblast method, or the like can be used.

First, as illustrated in FIG. 5A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 5A, an opening reaching the conductive layer 172 is formed in the insulating layers 175, 174, and 173. Then, the plug 176 is formed to fill the opening.

Subsequently, as illustrated in FIG. 5A, a conductive film 151f to be the conductive layers 151R, 151G, 151B, and 151C and a conductive film 152f to be the conductive layers 152R, 152G, 152B, and 152C are formed over the plug 176 and the insulating layer 175. A metal material can be used for the conductive film 151f, for example. For the conductive film 152f, an oxide containing one or more selected from indium, tin, zinc, gallium, titanium, aluminum, and silicon can be used, for example.

Then, as illustrated in FIG. 5A, a resist mask 191 is formed over the conductive film 152f. The resist mask 191 can be formed by application of a photosensitive material (photoresist), light exposure, and development.

Subsequently, as illustrated in FIG. 5B, the conductive films 151f and 152f in a region not overlapping with the resist mask 191 are removed, for example. In this manner, the conductive layers 151 and 152 are formed.

Next, the resist mask 191 is removed as illustrated in FIG. 5C. The resist mask 191 can be removed by ashing using oxygen plasma, for example.

Then, as illustrated in FIG. 5D, an insulating film 156f to be an insulating layer 156R, an insulating layer 156G, an insulating layer 156B, and an insulating layer 156C is formed over the conductive layers 152R, 152G, 152B, and 152C and the insulating layer 175.

As the insulating film 156f, an inorganic insulating film such as an oxide insulating film, a nitride insulating film, an oxynitride insulating film, or a nitride oxide insulating film, e.g., a silicon oxynitride film, can be used.

Subsequently, as illustrated in FIG. 5E, the insulating film 156f is processed to form the insulating layers 156R, 156G, 156B, and 156C.

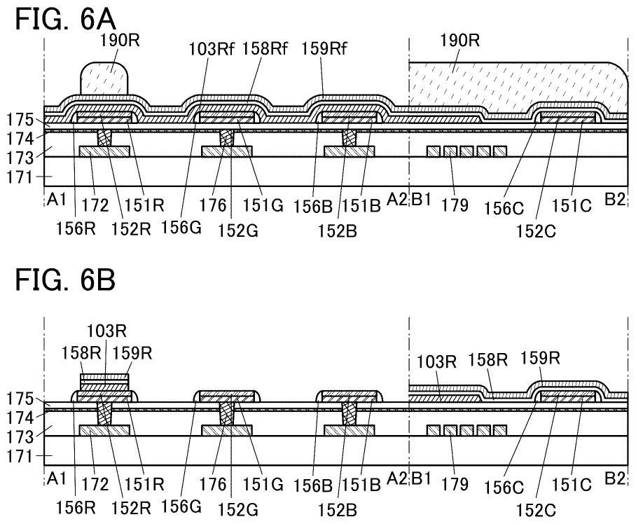

Next, as illustrated in FIG. 6A, an organic compound film 103Rf is formed over the conductive layers 152R, 152G, and 152B and the insulating layer 175. As illustrated in FIG. 6A, the organic compound film 103Rf is not formed over the conductive layer 152C.

Then, as illustrated in FIG. 6A, a sacrificial film 158Rf and a mask film 159Rf are formed.

Providing the sacrificial film 158Rf over the organic compound film 103Rf can reduce damage to the organic compound film 103Rf in the manufacturing process of the display device, resulting in an increase in the reliability of the light-emitting device.

As the sacrificial film 158Rf, a film that is highly resistant to the process conditions for the organic compound film 103Rf, specifically, a film having high etching selectivity with respect to the organic compound film 103Rf is used. For the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each higher than or equal to 100° C. and lower than or equal to 200° C., preferably higher than or equal to 100° C. and lower than or equal to 150° C., further preferably higher than or equal to 100° C. and lower than or equal to 120° C. The light-emitting device of one embodiment of the present invention includes the first organic compound, and thus enables a display device with high display quality even when manufactured through a heating process at a higher temperature.

The sacrificial film 158Rf and the mask film 159Rf are preferably films that can be removed by a wet etching method or a dry etching method.

Note that the sacrificial film 158Rf formed over and in contact with the organic compound film 103Rf is preferably formed by a formation method that is less likely to damage the organic compound film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, an inorganic insulating film, and the like can be used, for example.

For each of the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. It is preferable to use a metal material that can block ultraviolet rays for one or both of the sacrificial film 158Rf and the mask film 159Rf, in which case the organic compound film 103Rf can be inhibited from being irradiated with ultraviolet rays in light exposure for patterning, and deterioration of the organic compound film 103Rf can be inhibited.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In the above metal oxide, in place of gallium, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The sacrificial film 158Rf and the mask film 159Rf are preferably formed using a semiconductor material such as silicon or germanium for excellent compatibility with a semiconductor manufacturing process. Alternatively, a compound containing the above semiconductor material can be used.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film.

Subsequently, a resist mask 190R is formed as illustrated in FIG. 6A. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display device.

Next, as illustrated in FIG. 6B, part of the mask film 159Rf is removed using the resist mask 190R, whereby a mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), whereby a sacrificial layer 158R is formed.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use an alkaline aqueous solution such as a developer or a tetramethylammonium hydroxide (TMAH) aqueous solution, or an acid aqueous solution such as dilute hydrofluoric acid, oxalic acid, phosphoric acid, acetic acid, nitric acid, or a chemical solution containing a mixed solution of any of these acids, for example.

In the case of using a dry etching method to process the sacrificial film 158Rf, deterioration of the organic compound film 103Rf can be inhibited by not using a gas containing oxygen as the etching gas.

The resist mask 190R can be removed by a method similar to that for the resist mask 191.

Next, as illustrated in FIG. 6B, the organic compound film 103Rf is processed to form the organic compound layer 103R. For example, part of the organic compound film 103Rf is removed using the mask layer 159R and the sacrificial layer 158R as a hard mask, whereby the organic compound layer 103R is formed.

Accordingly, as illustrated in FIG. 6B, the stacked-layer structure of the organic compound layer 103R, the sacrificial layer 158R, and the mask layer 159R remains over the conductive layer 152R. The conductive layers 152G and 152B are exposed.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

A gas containing oxygen may be used as the etching gas. When the etching gas contains oxygen, the etching rate can be increased. Thus, the etching can be performed under a low-power condition while an adequately high etching rate is maintained. Accordingly, damage to the organic compound film 103Rf can be reduced. Furthermore, a defect such as attachment of a reaction product generated during the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas.

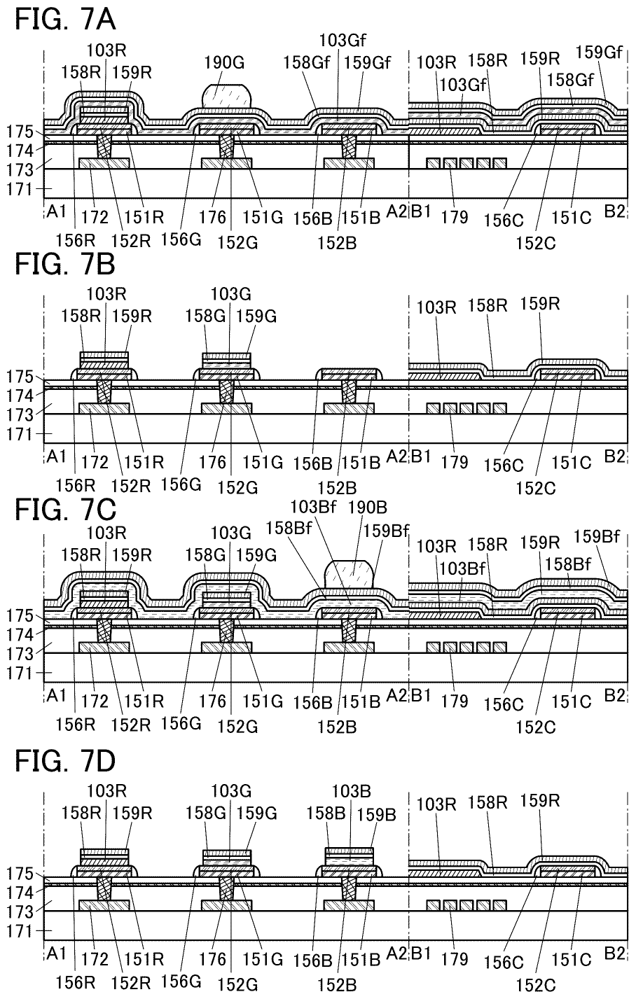

Then, as illustrated in FIG. 7A, an organic compound film 103Gf to be the organic compound layer 103G is formed.

The organic compound film 103Gf can be formed by a method similar to that for forming the organic compound film 103Rf. The organic compound film 103Gf can have a structure similar to that of the organic compound film 103Rf.

Subsequently, a sacrificial film 158Gf and a mask film 159Gf are formed in this order as illustrated in FIG. 7A. After that, a resist mask 190G is formed. The materials and the formation methods of the sacrificial film 158Gf and the mask film 159Gf are similar to those for the sacrificial film 158Rf and the mask film 159Rf. The material and the formation method of the resist mask 190G are similar to those for the resist mask 190R.

The resist mask 190G is provided at a position overlapping with the conductive layer 152G.

Subsequently, as illustrated in FIG. 7B, part of the mask film 159Gf is removed using the resist mask 190G, whereby a mask layer 159G is formed. The mask layer 159G remains over the conductive layer 152G. After that, the resist mask 190G is removed. Then, part of the sacrificial film 158Gf is removed using the mask layer 159G as a mask, whereby a sacrificial layer 158G is formed. Next, the organic compound film 103Gf is processed to form the organic compound layer 103G.

Then, an organic compound film 103Bf is formed as illustrated in FIG. 7C.

The organic compound film 103Bf can be formed by a method similar to that for forming the organic compound film 103Rf. The organic compound film 103Bf can have a structure similar to that of the organic compound film 103Rf.

Subsequently, a sacrificial film 158Bf and a mask film 159Bf are formed in this order as illustrated in FIG. 7C. After that, a resist mask 190B is formed. The materials and the formation methods of the sacrificial film 158Bf and the mask film 159Bf are similar to those for the sacrificial film 158Rf and the mask film 159Rf. The material and the formation method of the resist mask 190B are similar to those for the resist mask 190R.

The resist mask 190B is provided at a position overlapping with the conductive layer 152B.

Subsequently, as illustrated in FIG. 7D, part of the mask film 159Bf is removed using the resist mask 190B, whereby a mask layer 159B is formed. The mask layer 159B remains over the conductive layer 152B. After that, the resist mask 190B is removed. Then, part of the sacrificial film 158Bf is removed using the mask layer 159B as a mask, whereby a sacrificial layer 158B is formed. Next, the organic compound film 103Bf is processed to form the organic compound layer 103B. For example, part of the organic compound film 103Bf is removed using the mask layer 159B and the sacrificial layer 158B as a hard mask, whereby the organic compound layer 103B is formed.

Accordingly, as illustrated in FIG. 7D, the stacked-layer structure of the organic compound layer 103B, the sacrificial layer 158B, and the mask layer 159B remains over the conductive layer 152B. The mask layers 159R and 159G are exposed.

Note that the side surfaces of the organic compound layers 103R, 103G, and 103B are preferably perpendicular or substantially perpendicular to their formation surfaces. For example, the angle between the formation surfaces and these side surfaces is preferably greater than or equal to 60° and less than or equal to 90°.

The distance between two adjacent layers among the organic compound layers 103R, 103G, and 103B, which are formed by a photolithography method as described above, can be reduced to less than or equal to 8 μm, less than or equal to 5 μm, less than or equal to 3 μm, less than or equal to 2 μm, or less than or equal to 1 μm. Here, the distance can be specified, for example, by a distance between facing end portions of two adjacent layers among the organic compound layers 103R, 103G, and 103B. Reducing the distance between the island-shaped organic compound layers makes it possible to provide a display device having high resolution and a high aperture ratio. In addition, the distance between the first electrodes of adjacent light-emitting devices can also be reduced to for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

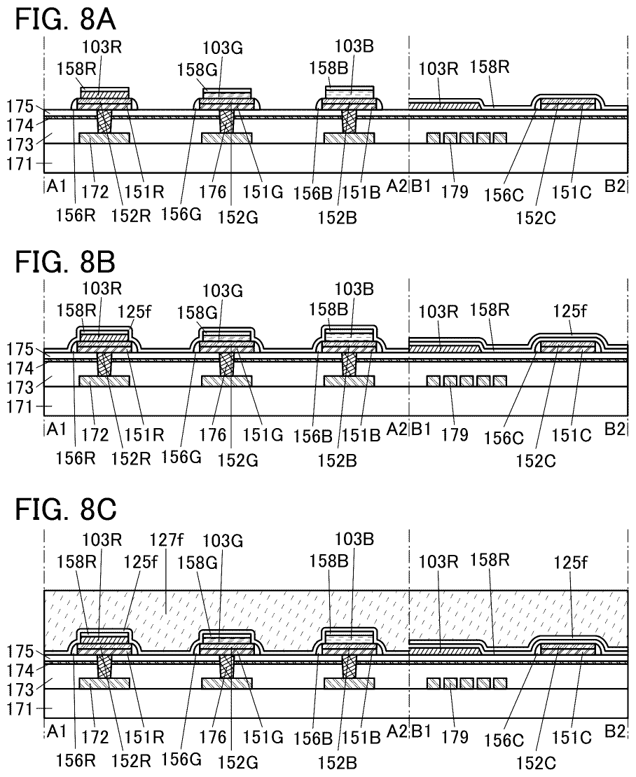

Next, as illustrated in FIG. 8A, the mask layers 159R, 159G, and 159B are preferably removed.

The step of removing the mask layers can be performed by a method similar to that for the step of processing the mask films. Specifically, by using a wet etching method, damage to the organic compound layer 103 at the time of removing the mask layers can be reduced as compared to the case of using a dry etching method.

The mask layers may be removed by being dissolved in a polar solvent such as water or an alcohol. Examples of an alcohol include ethyl alcohol, methyl alcohol, isopropyl alcohol (IPA), and glycerin.

After the mask layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, an inorganic insulating film 125f is formed as illustrated in FIG. 8B.

Then, as illustrated in FIG. 8C, an insulating film 127f to be the insulating layer 127 is formed over the inorganic insulating film 125f.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case film formation damage is reduced and a film with good coverage can be formed. As the inorganic insulating film 125f, an aluminum oxide film is preferably formed by an ALD method, for example.

The insulating film 127f is preferably formed by the aforementioned wet process. The insulating film 127f is preferably formed by spin coating using a photosensitive material, for example, and specifically preferably formed using a photosensitive resin composition containing an acrylic resin.

Then, part of the insulating film 127f is exposed to visible light or ultraviolet rays. The insulating layer 127 is formed in regions that are interposed between any two of the conductive layers 152R, 152G, and 152B and around the conductive layer 152C.

The width of the insulating layer 127 formed later can be controlled with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). Furthermore, light used for the exposure may include at least one of the g-line (wavelength: 436 nm) and the h-line (wavelength: 405 nm).

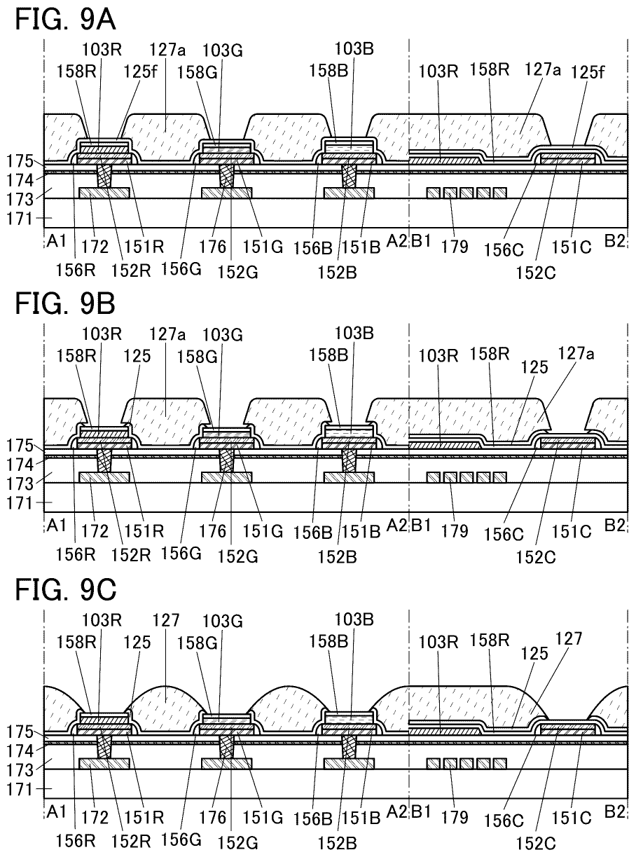

Next, as illustrated in FIG. 9A, development is performed to remove the exposed region of the insulating film 127f, whereby an insulating layer 127a is formed.

Next, as illustrated in FIG. 9B, etching treatment is performed using the insulating layer 127a as a mask to remove part of the inorganic insulating film 125f and reduce the thickness of part of the sacrificial layers 158R, 158G, and 158B. Thus, the inorganic insulating layer 125 is formed under the insulating layer 127a. Moreover, the surfaces of the thin portions of the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that for the sacrificial layers 158R, 158G, and 158B, in which case the first etching treatment can be performed concurrently.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of wet etching can reduce damage to the organic compound layers 103R, 103G, and 103B, as compared to the case of using dry etching. Wet etching can be performed using an alkaline solution, for example. For instance, TMAH, which is an alkaline solution, can be used for the wet etching of an aluminum oxide film. Alternatively, an acid solution containing fluoride can also be used. In this case, puddle wet etching can be performed. Note that the inorganic insulating film 125f is preferably formed using a material similar to that for the sacrificial layers 158R, 158G, and 158B, in which case the above etching treatment can be performed concurrently.

The sacrificial layers 158R, 158G, and 158B are not removed completely by the first etching treatment, and the etching treatment is stopped when the thickness of the sacrificial layers 158R, 158G, and 158B is reduced. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (e.g., an aluminum oxide film) exists as each of the sacrificial layers 158R, 158G, and 158B, diffusion of oxygen to the organic compound layers 103R, 103G, and 103B can be inhibited.

Then, heat treatment (also referred to as post-baking) is performed. The heat treatment can change the insulating layer 127a into the insulating layer 127 having a tapered side surface (FIG. 9C). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the organic compound layers 103R, 103G, and 103B can be prevented from being damaged and deteriorating in the heat treatment. This can increase the reliability of the light-emitting devices.

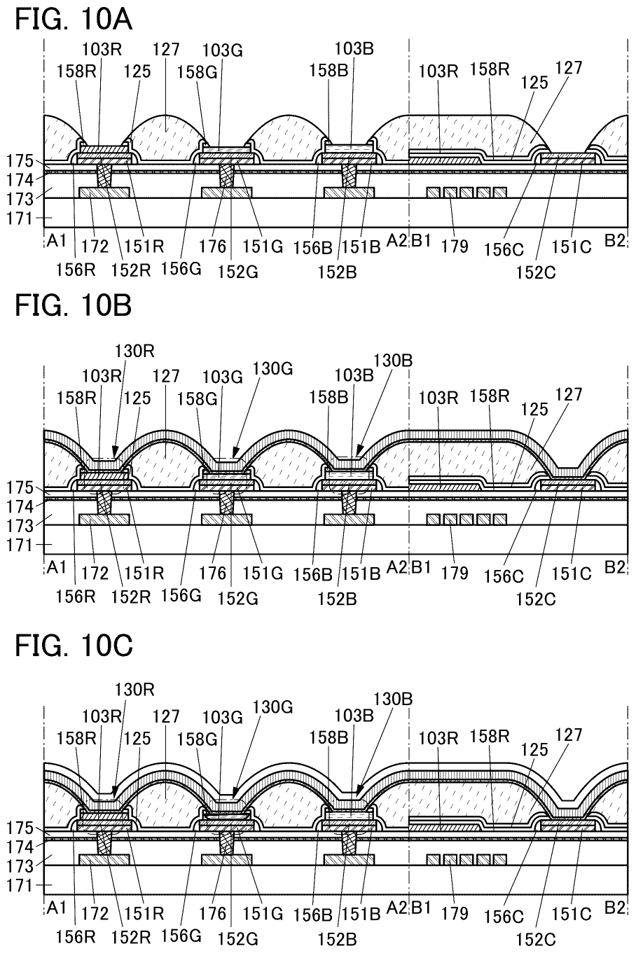

Next, as illustrated in FIG. 10A, etching treatment is performed using the insulating layer 127 as a mask to remove parts of the sacrificial layers 158R, 158G, and 158B. Thus, openings are formed in the sacrificial layers 158R, 158G, and 158B, and the top surfaces of the organic compound layers 103R, 103G, and 103B and the conductive layer 152C are exposed. Note that this etching treatment may be hereinafter referred to as second etching treatment.

An end portion of the inorganic insulating layer 125 is covered with the insulating layer 127. FIG. 10A illustrates an example where part of an end portion of the sacrificial layer 158G (specifically a tapered portion formed by the first etching treatment) is covered with the insulating layer 127 and a tapered portion formed by the second etching treatment is exposed.

The second etching treatment is performed by wet etching. The use of wet etching can reduce damage to the organic compound layers 103R, 103G, and 103B, as compared to the case of using dry etching. Wet etching can be performed using an alkaline solution or an acid solution, for example. An aqueous solution is preferably used in order that the organic compound layer 103 is not dissolved.

Next, as illustrated in FIG. 10B, a common electrode 155 is formed over the organic compound layers 103R, 103G, and 103B, the conductive layer 152C, and the insulating layer 127. The common electrode 155 can be formed by a sputtering method, a vacuum evaporation method, or the like.

Next, as illustrated in FIG. 10C, the protective layer 131 is formed over the common electrode 155. The protective layer 131 can be formed by a vacuum evaporation method, a sputtering method, a CVD method, an ALD method, or the like.

Then, the substrate 120 is bonded to the protective layer 131 using the resin layer 122, so that the display device can be manufactured. In the method for manufacturing the display device of one embodiment of the present invention, the insulating layer 156 is formed to include a region overlapping with the side surface of the conductive layer 151 and the conductive layer 152 is formed to cover the conductive layer 151 and the insulating layer 156 as described above. This can increase the yield of the display device and inhibit generation of defects.

As described above, in the method for manufacturing the display device of one embodiment of the present invention, the island-shaped organic compound layers 103R, 103G, and 103B are formed not by using a fine metal mask but by processing a film formed on the entire surface; thus, the island-shaped layers can be formed to have a uniform thickness. In addition, a high-resolution display device or a display device with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of leakage current between the subpixels can be inhibited. This can prevent crosstalk, so that a display device with extremely high contrast can be obtained. Moreover, even a display device that includes tandem light-emitting devices formed by a photolithography method can have favorable characteristics.

### Embodiment 4

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

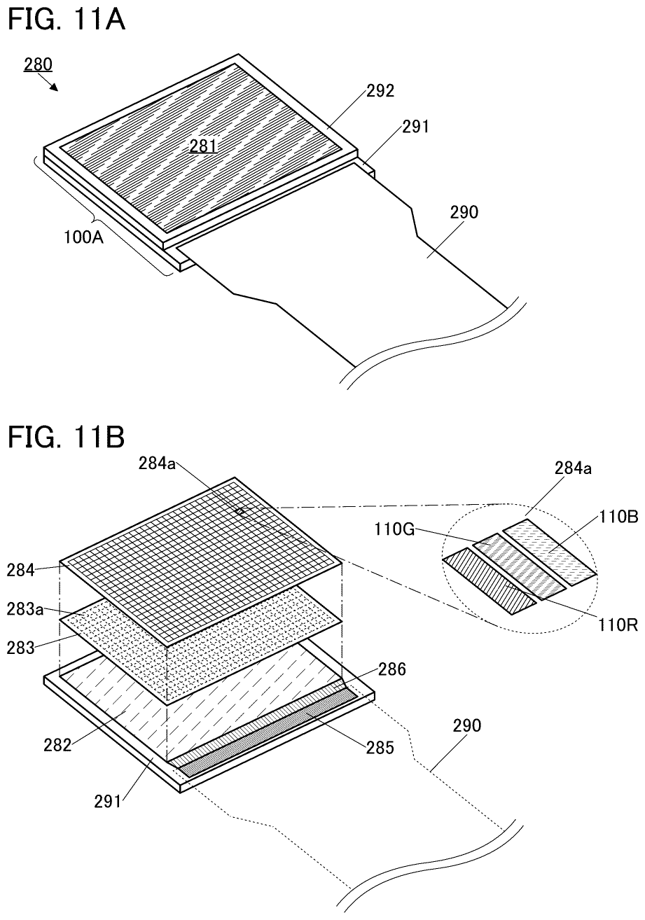

FIG. 11A is a perspective view of a display module 280. The display module 280 includes a display device 100A and an FPC 290. Note that the display device included in the display module 280 is not limited to the display device 100A and may be any of a display device 100B, a display device 100C, a display device 100D, a display device 100D2, a display device 100E, and a display device 100E2 described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 11B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 11B. The pixels 284a can employ any of the structures described in the above embodiments.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Device 100A]

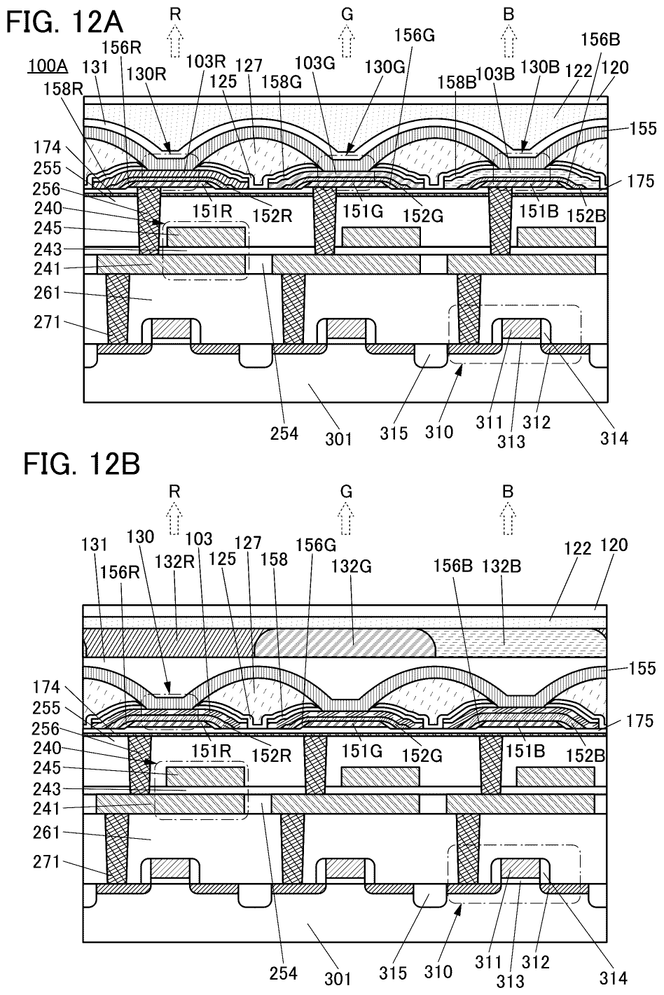

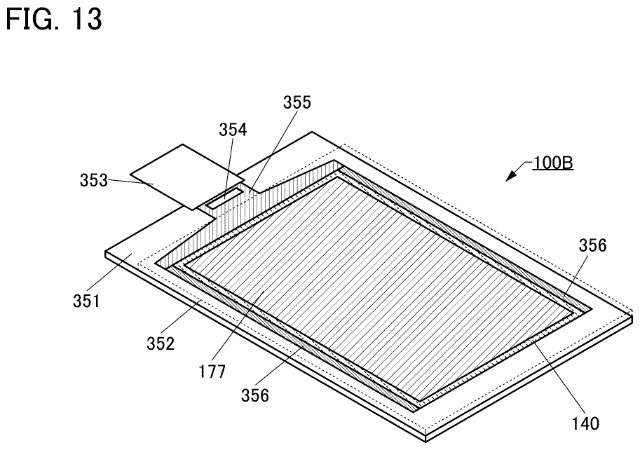

The display device 100A illustrated in FIG. 12A includes a substrate 301, the light-emitting devices 130R, 130G, and 130B, a capacitor 240, and a transistor 310.

The substrate 301 corresponds to the substrate 291 in FIGS. 12A and 12B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the organic compound layer 103R. The sacrificial layer 158G is positioned over the organic compound layer 103G. The sacrificial layer 158B is positioned over the organic compound layer 103B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is bonded to the protective layer 131 with the resin layer 122. Embodiment 3 can be referred to for the details of the light-emitting device 130 and the components thereover up to the substrate 120. The substrate 120 corresponds to the substrate 292 in FIG. 11A.

FIG. 12B illustrates a variation example of the display device 100A illustrated in FIG. 12A. The display device illustrated in FIG. 12B includes a coloring layer 132R, a coloring layer 132G, and a coloring layer 132B, and each of the light-emitting devices 130 includes a region overlapping with one of the coloring layers 132R, 132G, and 132B. In the display device illustrated in FIG. 12B, the light-emitting device 130 can emit white light, for example. The coloring layer 132R, the coloring layer 132G, and the coloring layer 132B can transmit red light, green light, and blue light, respectively, for example.

### [Display Device 100B]

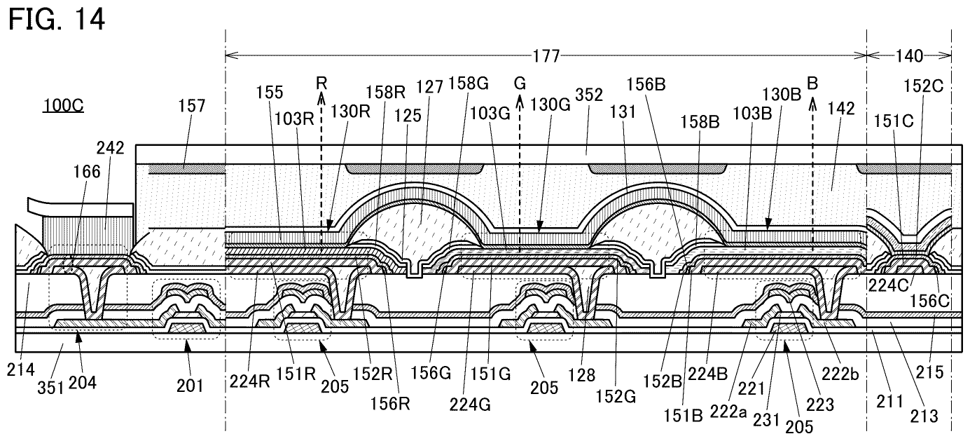

FIG. 13 is a perspective view of the display device 100B, and FIG. 14 is a cross-sectional view of the display device 100C.

In the display device 100B, a substrate 352 and a substrate 351 are bonded to each other. In FIG. 13, the substrate 352 is denoted by a dashed line.

The display device 100B includes the pixel portion 177, the connection portion 140, a circuit 356, a wiring 355, and the like. FIG. 13 illustrates an example where an IC 354 and an FPC 353 are mounted on the display device 100B. Thus, the structure illustrated in FIG. 13 can be regarded as a display module including the display device 100B, the integrated circuit (IC), and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 13 illustrates an example where the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

FIG. 14 illustrates the display device 100C as an example of cross sections of part of a region including the FPC 353, part of the circuit 356, part of the pixel portion 177, part of the connection portion 140, and part of a region including an end portion of the display device 100B in FIG. 13.

### [Display Device 100C]

The display device 100C illustrated in FIG. 14 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 3 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depressed portion covering the opening provided in the insulating layer 214. A layer 128 is embedded in the depressed portion.

The layer 128 has a function of filling the depressed portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depressed portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 14, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Alternatively, the space may be filled with a resin other than the frame-shaped adhesive layer 142.

FIG. 14 illustrates an example where the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 14, the insulating layer 156C is provided to include a region overlapping with the side surface of the conductive layer 151C.

The display device 100C has a top-emission structure. Light from the light-emitting device is emitted toward the substrate 352. For the substrate 352, a material with a high visible-light-transmitting property is preferably used. The pixel electrode includes a material that reflects visible light, and the counter electrode (the common electrode 155) includes a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, one of the source electrode and the drain electrode of the transistor 201 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

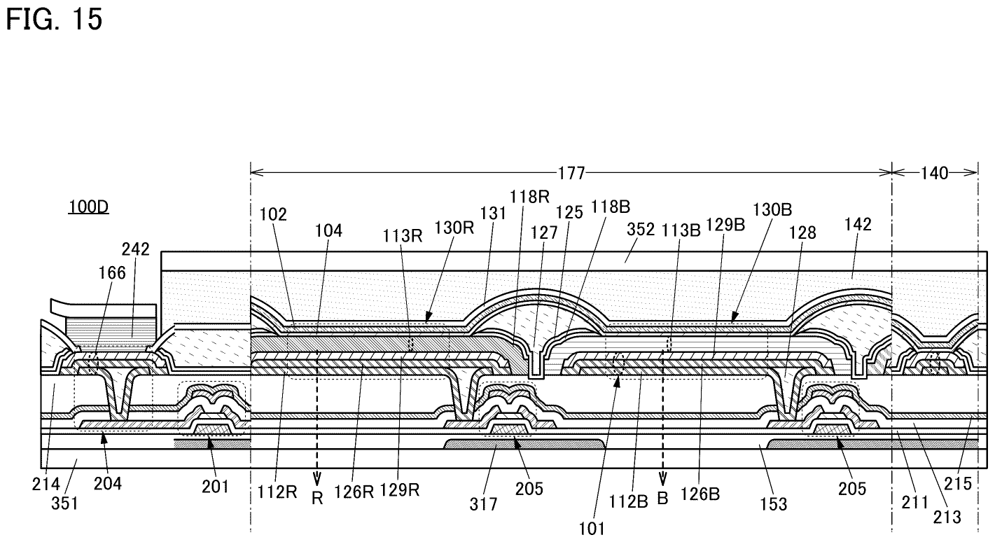

The display device 100D illustrated in FIG. 15 differs from the display device 100C illustrated in FIG. 14 mainly in having a bottom-emission structure.

Light from the light-emitting device is emitted toward the substrate 351. For the substrate 351, a material with a high visible-light-transmitting property is preferably used. By contrast, there is no limitation on the light-transmitting property of a material used for the substrate 352.

A light-blocking layer 317 is preferably formed between the substrate 351 and the transistor 201 and between the substrate 351 and the transistor 205. FIG. 15 illustrates an example where the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material with a high visible-light-transmitting property is used for each of the conductive layers 112R, 112B, 126R, 126B, 129R, and 129B. A material that reflects visible light is preferably used for the second electrode 102.

Although not illustrated in FIG. 15, the light-emitting device 130G is also provided.

Although FIG. 15 and the like illustrate an example where the top surface of the layer 128 includes a flat portion, the shape of the layer 128 is not particularly limited.

### [Display Device 100D2]

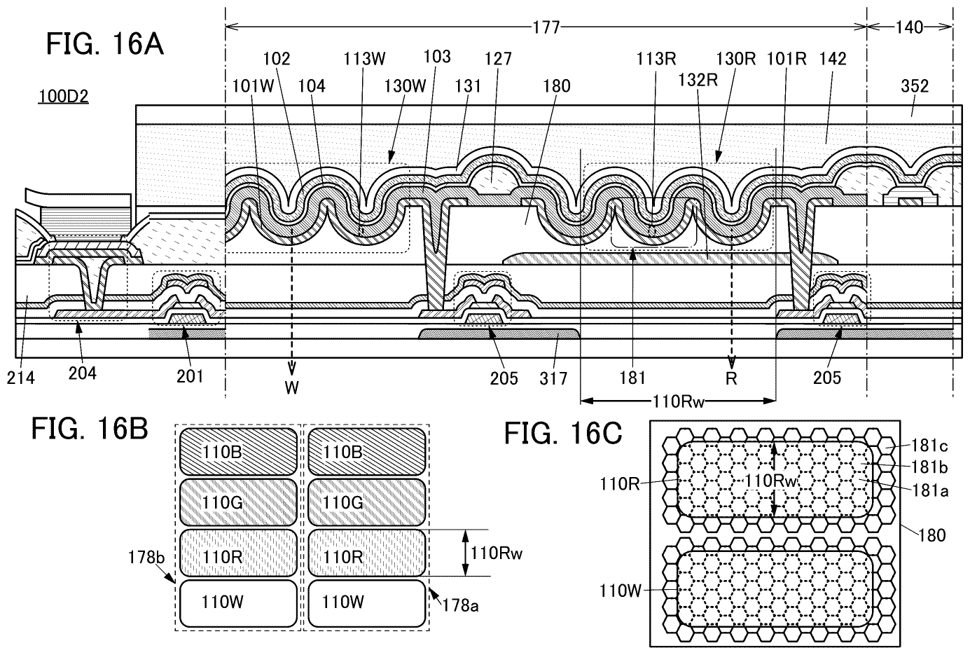

The display device 100D2 illustrated in FIG. 16A is an example of a bottom-emission display device different from the display device 100D illustrated in FIG. 15. The display device 100D2 is different from the display device 100D in including an organic resin layer 180. Note that in the drawings, reference numerals of some of the components that are shown in FIG. 15 are omitted; for the details of the components, the description made with reference to FIG. 15 is to be referred to.

FIG. 16B shows a top-view layout of the pixels 178 (pixels 178a and 178b) each including the subpixels 110 (the subpixels 110R, 110G, and 110B and a subpixel 110W), and FIG. 16C shows a top view of the organic resin layer 180 in a region where the subpixels 110R and 110W of the pixel 178 are formed. Note that the width between the light-blocking layer 317 and another light-blocking layer 317 corresponds to a width 110Rw in the light-emitting region of the subpixel 110R.

As illustrated in FIG. 16A, the organic resin layer 180 is provided over the insulating layer 214. As illustrated in FIG. 16C and the region surrounded by the dashed-dotted line in FIG. 16A, the organic resin layer 180 includes a depressed portion 181 (depressed portions 181a and 181b) having a curved surface at least in a region where the subpixel is formed. Note that the depressed portion 181 outside the light-emitting region, like a depressed portion 181c, may also be provided. With the depressed portion 181c, light emission caused in a region overlapping with the light-blocking layer 317 or light travelled into the region overlapping with the light-blocking layer 317 can be refracted and extracted from the light-emitting region, whereby emission efficiency can be improved.

A plurality of the depressed portions 181 may be formed in a matrix. The depressed portions 181a and 181b may be provided in contact with each other or may be provided to have a flat surface therebetween.

Although the top-view shape and the cross-sectional shape of the depressed portion are hexagonal (FIG. 16C) and semicircular (FIG. 16A), respectively, other shapes may be employed as needed. Examples of the top-view shape of the depressed portion include polygons such as a triangle, a tetragon (including a rectangle and a square), and a pentagon; these polygons with rounded corners; an ellipse; and a circle.

An insulating layer including an organic material can be used as the organic resin layer 180. Examples of materials that can be used for the organic resin layer 180 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. The organic resin layer 180 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

A photosensitive resin can also be used for the organic resin layer 180. A photoresist may be used as the photosensitive resin. As the photosensitive resin, a positive photosensitive material or a negative photosensitive material can be used.

The organic resin layer 180 may include a material absorbing visible light. For example, the organic resin layer 180 itself may be made of a material absorbing visible light, or the organic resin layer 180 may include a pigment absorbing visible light. For example, the organic resin layer 180 can be formed using a resin that can be used as a color filter transmitting red, blue, or green light and absorbing light of the other colors or a resin that contains carbon black as a pigment and functions as a black matrix.

The first electrodes 101 (the first electrode 101R and a first electrode 101W) are over the organic resin layer 180, and the organic compound layer 103 is over the first electrodes 101. End portions of the first electrode 101 and the organic compound layer 103 may be covered with the insulating layer 127.

Along the depressed portion of the organic resin layer 180, the first electrode 101 formed over the organic resin layer 180 has a depressed portion in a manner similar to that of the organic resin layer 180. Furthermore, along the depressed portion of the first electrode 101, the organic compound layer 103 formed over the first electrode 101 has a depressed portion in a manner similar to that of the first electrode 101. Furthermore, along the depressed portion of the organic compound layer 103, the common layer 104 formed over the organic compound layer 103 has a depressed portion in a manner similar to that of the organic compound layer 103. Furthermore, along the depressed portion of the common layer 104, the second electrode 102 formed over the common layer 104 has a depressed portion in a manner similar to that of the common layer 104. That is, the depressed portions of the organic resin layer 180, the first electrode 101, the organic compound layer 103, the common layer 104, and the second electrode 102 overlap with each other.

The common layer 104 is provided over the organic compound layer 103 and the insulating layer 127, and the second electrode 102 is provided over the common layer 104. The protective layer 131 is provided over the second electrode 102, and the substrate 352 is bonded with the use of the adhesive layer 142.

Although the light-emitting devices 130G and 130B are not illustrated in FIGS. 16A to 16C, the light-emitting devices 130G and 130B are also provided.

### [Display Device 100E]

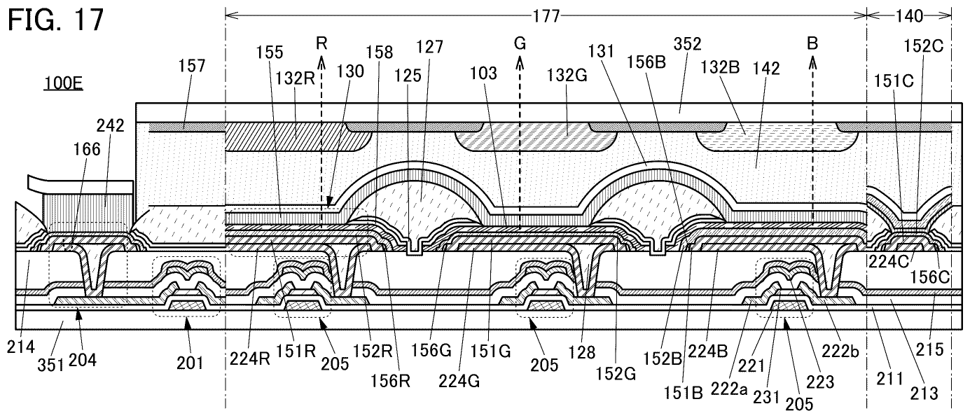

The display device 100E illustrated in FIG. 17 is a variation example of the display device 100C illustrated in FIG. 14 and differs from the display device 100C mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

In the display device 100E, the light-emitting device 130 can emit white light, for example. The coloring layer 132R, the coloring layer 132G, and the coloring layer 132B can transmit red light, green light, and blue light, respectively, for example. Note that in the display device 100E, the coloring layers 132R, 132G, and 132B may be provided between the protective layer 131 and the adhesive layer 142.

### [Display Device 100E2]

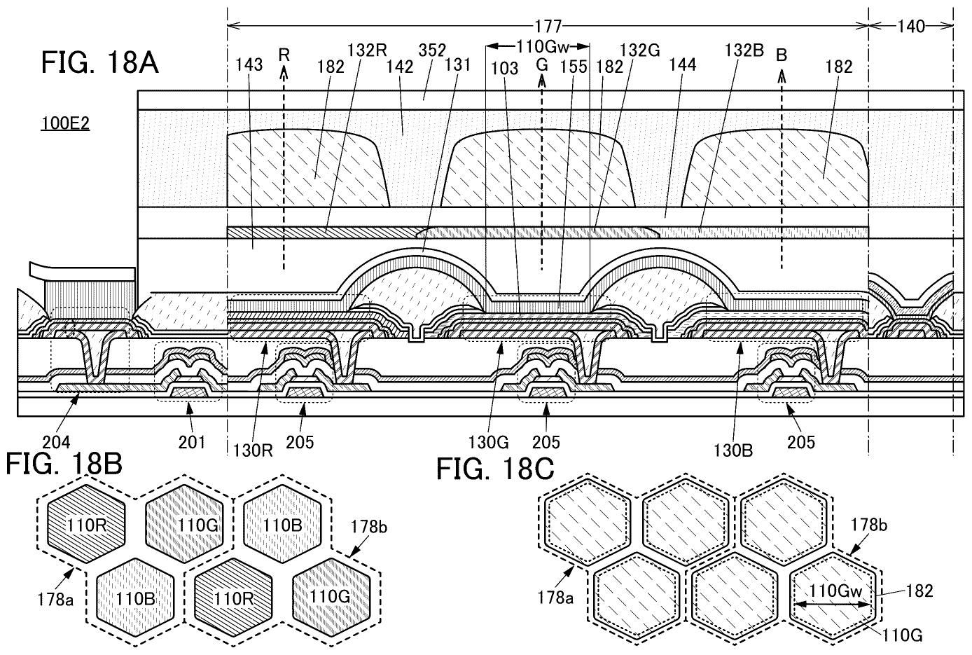

The display device 100E2 illustrated in FIG. 18A is a variation example of the display device 100E illustrated in FIG. 17 and includes microlenses 182 over the coloring layers 132R, 132G, and 132B. Note that in the drawings, reference numerals of some of the components that are shown in FIG. 17 are omitted; for the details of the components, the description made with reference to FIG. 17 is to be referred to.

FIG. 18B shows a top-view layout of the pixels 178 (the pixels 178a and 178b) each including the subpixels 110 (the subpixels 110R, 110G, and 110B), and FIG. 18C shows a top view of the microlenses 182 in a region where the subpixels 110R, 110G, and 110B of the pixels 178 are formed. Note that the width of the region where the common electrode 155 and the organic compound layer 103 are in contact with each other corresponds to a width 110Gw in the light-emitting region of the subpixel 110G.

In the display device 100E2 illustrated in FIG. 18A, a planarization film 143 is provided over the protective layer 131, and the coloring layers 132R, 132G, and 132B are provided over the planarization film 143. A planarization film 144 is provided to cover the coloring layers 132R, 132G, and 132B. The microlenses 182 are provided over the planarization film 144.

Note that as illustrated in FIG. 18C, the microlens 182 is preferably provided for each of the subpixels in the region where the subpixels are formed.

Although the top-view shape of the microlens 182 is hexagonal in FIG. 18C, a different shape may be employed as needed. Examples of the top-view shape of the microlens 182 include polygons such as a triangle, a tetragon (including a rectangle and a square), and a pentagon; these polygons with rounded corners; an ellipse; and a circle.

The microlenses 182 can be formed using a material similar to that for the organic resin layer 180.

This embodiment can be combined as appropriate with the other embodiments or the examples. In this specification, in the case where a plurality of structure examples are shown in one embodiment, the structure examples can be combined as appropriate.

### Embodiment 5

In this embodiment, electronic appliances of embodiments of the present invention will be described.

Electronic appliances in this embodiment each include the display device of one embodiment of the present invention in a display portion. The display device of one embodiment of the present invention has low power consumption and high reliability. Thus, the display device of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

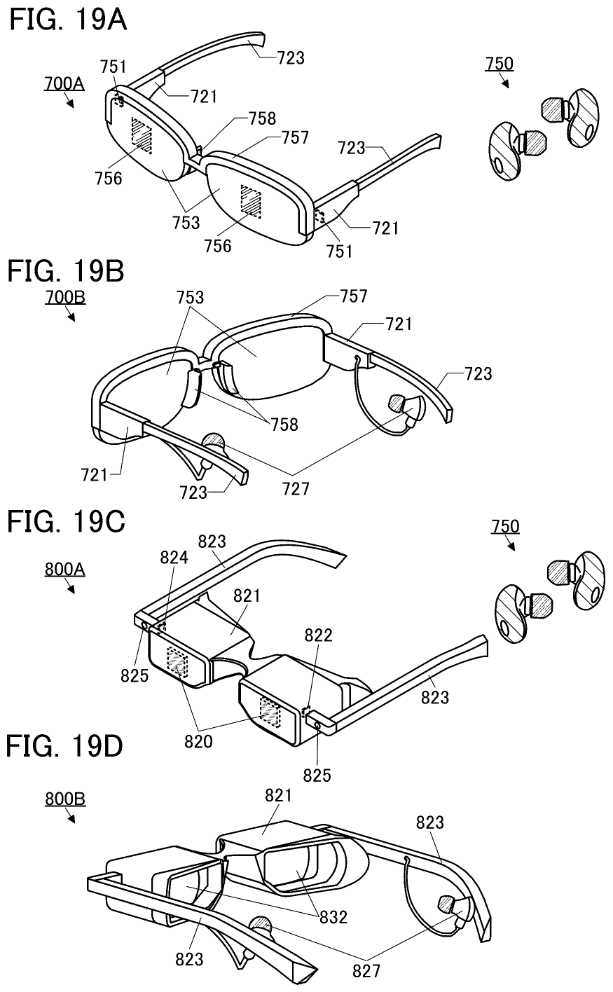

Examples of wearable devices capable of being worn on a head are described with reference to FIGS. 19A to 19D.

An electronic appliance 700A illustrated in FIG. 19A and an electronic appliance 700B illustrated in FIG. 19B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, a highly reliable electronic appliance is obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 19C and an electronic appliance 800B illustrated in FIG. 19D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, a highly reliable electronic appliance is obtained.

The display portions 820 are positioned inside the housing 821 so as to be seen through the lenses 832. When the pair of display portions 820 display different images, three-dimensional display using parallax can be performed.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

The electronic appliance 800A may include a vibration mechanism that functions as bone-conduction earphones.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B illustrated in FIG. 19B includes earphone portions 727. Part of a wiring that connects the earphone portion 727 and the control portion may be positioned inside the housing 721 or the wearing portion 723.

Similarly, the electronic appliance 800B illustrated in FIG. 19D includes earphone portions 827. For example, the earphone portion 827 can be connected to the control portion 824 by wire.

As described above, both the glasses-type device (e.g., the electronic appliances 700A and 700B) and the goggles-type device (e.g., the electronic appliances 800A and 800B) are preferable as the electronic appliance of one embodiment of the present invention.

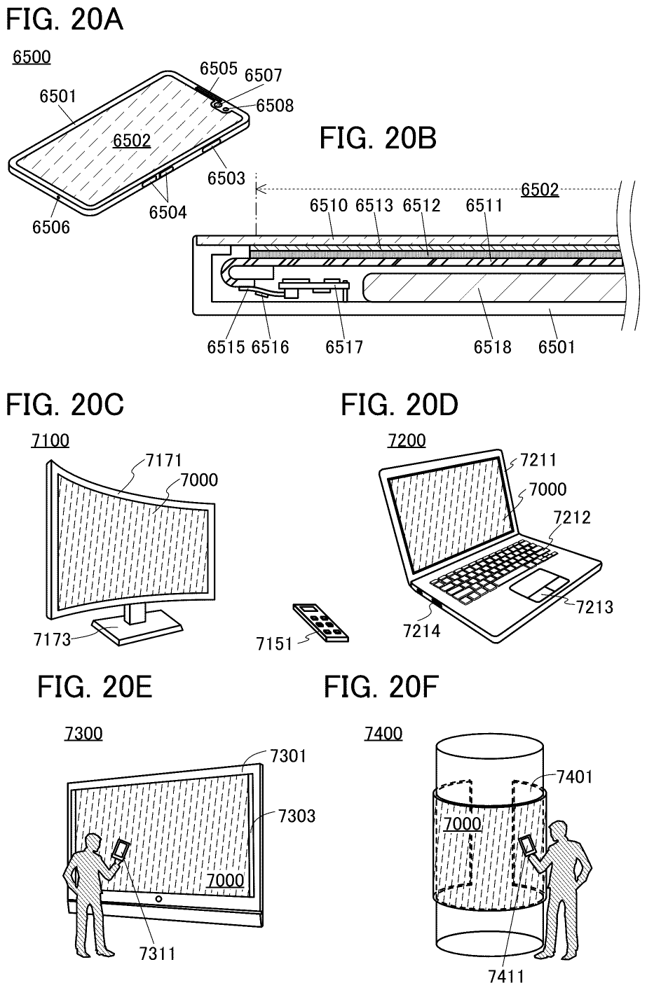

An electronic appliance 6500 illustrated in FIG. 20A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, a highly reliable electronic appliance is obtained.

FIG. 20B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with a bonding layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used in the display panel 6511. Thus, an extremely lightweight electronic appliance can be achieved. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be achieved.

FIG. 20C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, a highly reliable electronic appliance is obtained.

Operation of the television device 7100 illustrated in FIG. 20C can be performed with an operation switch provided in the housing 7171 and a separate remote control 7151.

FIG. 20D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, a highly reliable electronic appliance is obtained.

FIGS. 20E and 20F illustrate examples of digital signage.

Digital signage 7300 illustrated in FIG. 20E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 20F illustrates digital signage 7400 attached to a cylindrical pillar 7401. The digital signage 7400 includes the display portion 7000 provided along a curved surface of the pillar 7401.

In FIGS. 20E and 20F, the display device of one embodiment of the present invention can be used in the display portion 7000. Thus, a highly reliable electronic appliance is obtained.

A larger area of the display portion 7000 can increase the amount of information that can be provided at a time. The larger display portion 7000 attracts more attention, so that the effectiveness of the advertisement can be increased, for example.

As illustrated in FIGS. 20E and 20F, it is preferable that the digital signage 7300 or the digital signage 7400 can work with an information terminal 7311 or an information terminal 7411, such as a smartphone that a user has, through wireless communication.

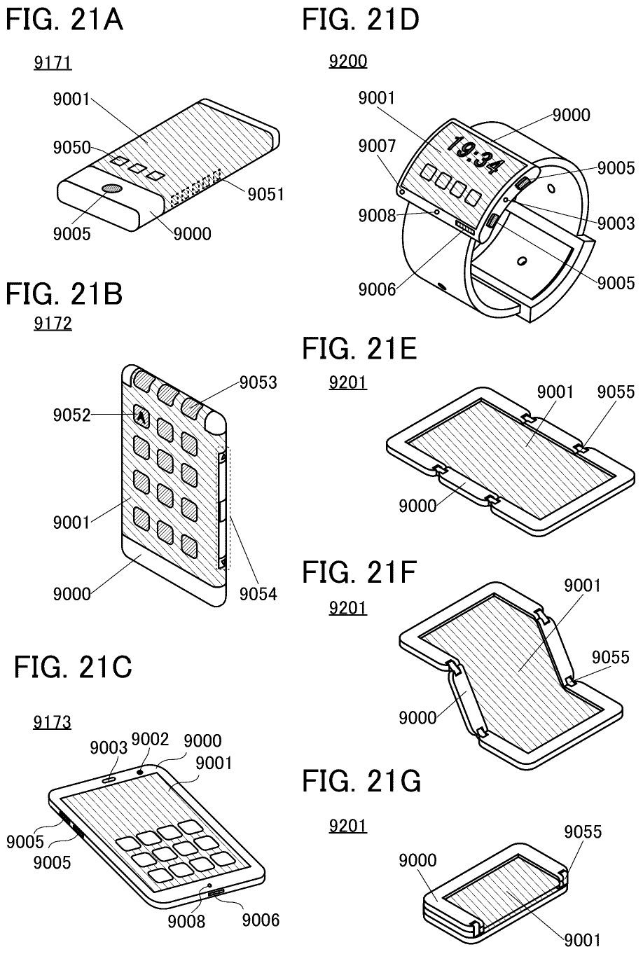

Electronic appliances illustrated in FIGS. 21A to 21G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 21A to 21G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with use of a variety of software (programs), a wireless communication function, and a function of reading out and processing a program or data stored in a recording medium.

The electronic appliances illustrated in FIGS. 21A to 21G are described in detail below.

FIG. 21A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 21A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 21B is a perspective view of a portable information terminal 9172. The portable information terminal 9172 has a function of displaying information on three or more surfaces of the display portion 9001. In the example illustrated here, information 9052, information 9053, and information 9054 are displayed on different surfaces. For example, the user of the portable information terminal 9172 can check the information 9053 displayed such that it can be seen from above the portable information terminal 9172, with the portable information terminal 9172 put in a breast pocket of his/her clothes.

FIG. 21C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 21D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 21E to 21G are perspective views of a foldable portable information terminal 9201. FIG. 21E is a perspective view illustrating the portable information terminal 9201 that is opened. FIG. 21G is a perspective view illustrating the portable information terminal 9201 that is folded. FIG. 21F is a perspective view illustrating the portable information terminal 9201 that is shifted from one of the states in FIGS. 21E and 21G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

### Example 1

Specific fabrication methods and characteristics of a light-emitting device R1, a light-emitting device G1, and a light-emitting device B1, which are light-emitting devices of embodiments of the present invention, and a comparative light-emitting device R1, a comparative light-emitting device G1, and a comparative light-emitting device B1, which are comparative light-emitting devices, are described in this example. Structural formulae of main compounds used in this example are shown below.

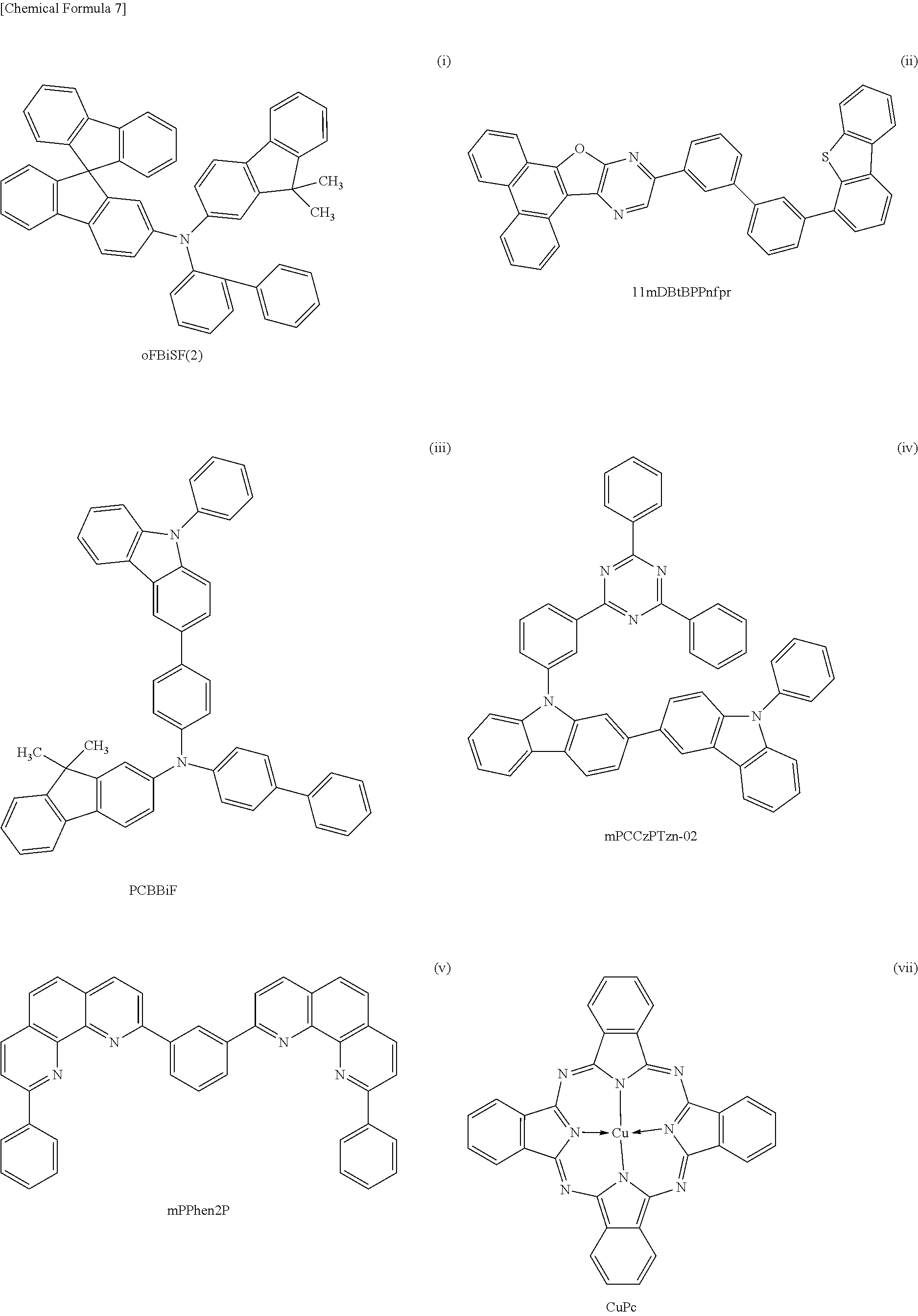

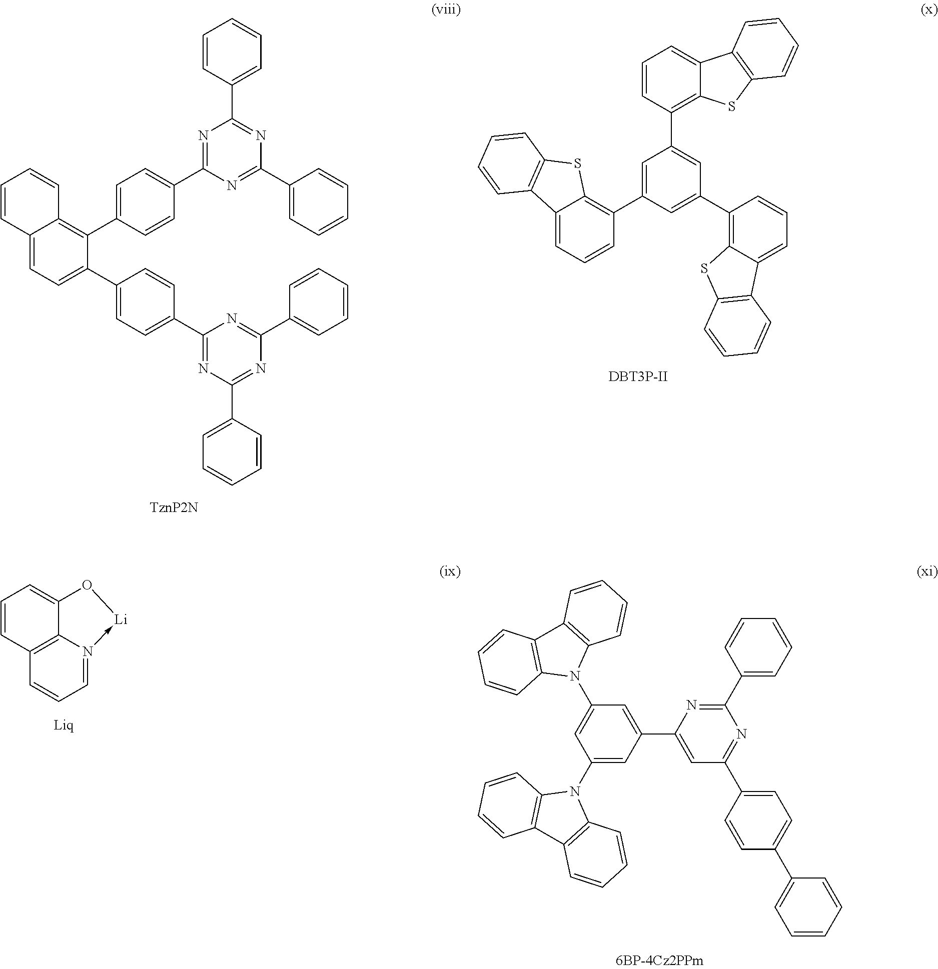

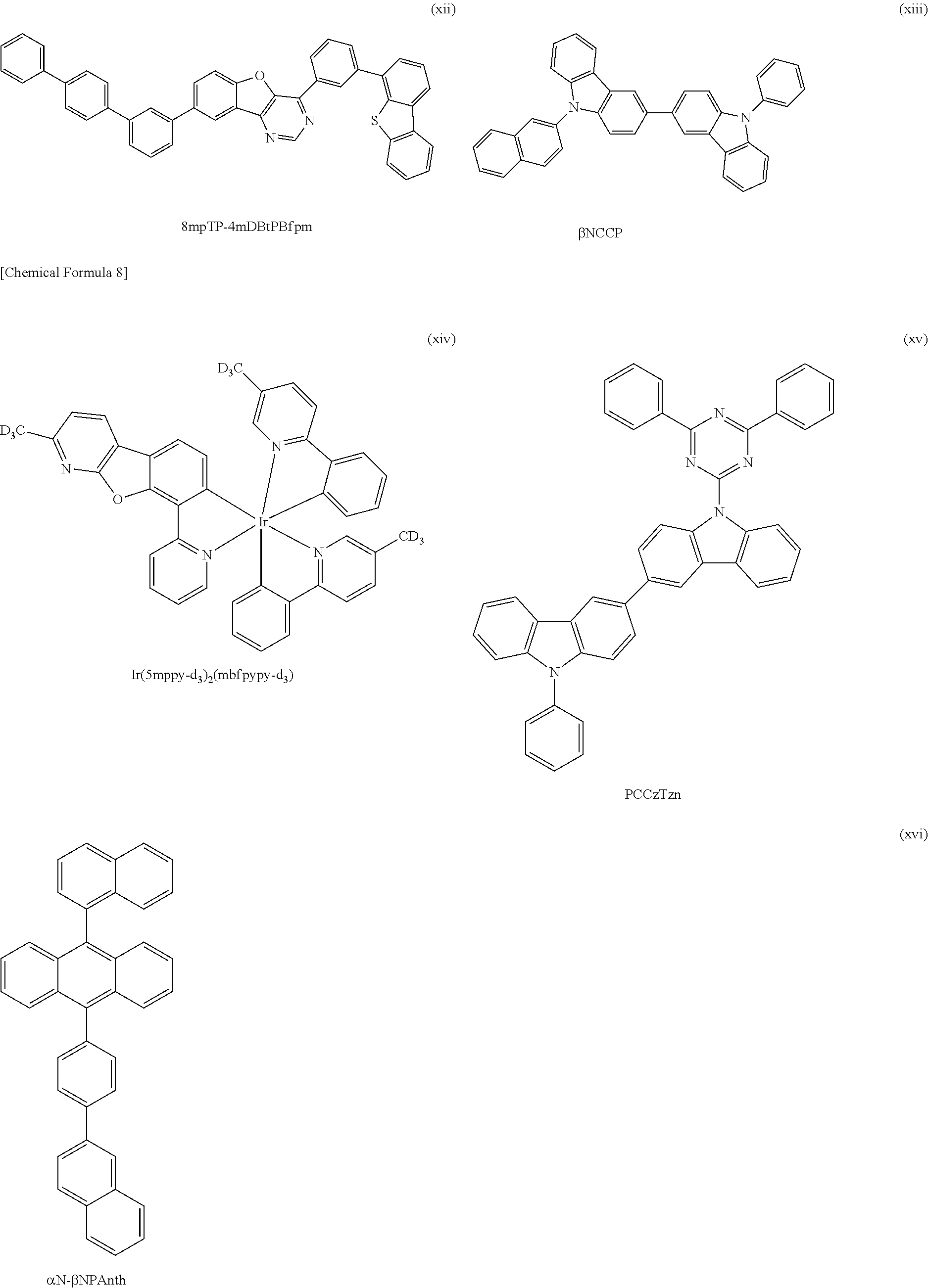

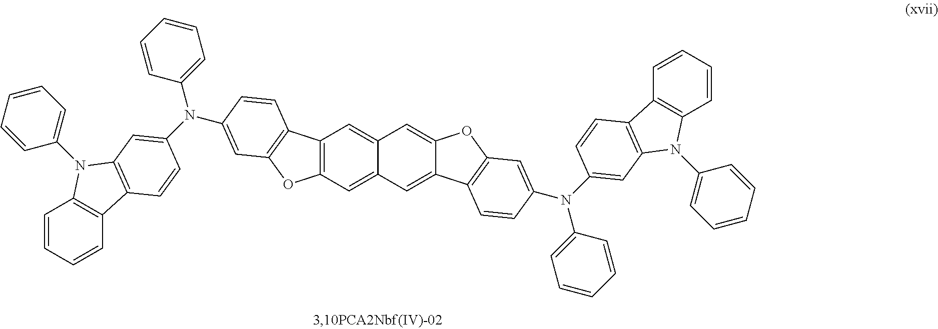 [SMILES: c1ccc(N(c2ccc3c(c2)oc2cc4cc5c(cc4cc23)oc2cc(N(c3ccccc3)c3ccc4c6ccccc6n(-c6ccccc6)c4c3)ccc25)c2ccc3c4ccccc4n(-c4ccccc4)c3c2)cc1]

### (Fabrication Method of Light-Emitting Device R1)

First, 100-nm-thick silver (Ag) and 85-nm-thick indium tin oxide containing silicon oxide (ITSO) were stacked over a glass substrate sequentially from the substrate side by a sputtering method as a reflective electrode and a transparent electrode, respectively, so that the first electrode 101 with a size of 2 mm×2 mm was formed. Note that the transparent electrode functions as an anode, and the transparent electrode and the reflective electrode are collectively regarded as the first electrode 101.

Next, in pretreatment for fabricating the light-emitting device over the substrate, the surface of the substrate was washed with water, and baking was performed at 200° C. for one hour. After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was allowed to cool down for approximately 30 minutes.

Next, the substrate was fixed to a holder provided in the vacuum evaporation apparatus such that the surface on which the first electrode 101 was formed faced downward. Then, N-(biphenyl-2-yl)-N-(9,9-dimethylfluoren-2-yl)-9,9′-spirobi[9H-fluoren]-2-amine (abbreviation: oFBiSF(2)) represented by Structural Formula (i) above and a fluorine-containing material having an electron-acceptor property with a molecular weight of 672 (OCHD-003) were deposited by co-evaporation over the first electrode 101 to a thickness of 10 nm such that the weight ratio of oFBiSF(2) to OCHD-003 was 1:0.03, whereby the hole-injection layer 111 was formed.

Over the hole-injection layer 111, oFBiSF(2) was deposited by evaporation to a thickness of 150 nm, so that the first hole-transport layer was formed.

Next, 11-[3′-(dibenzothiophen-4-yl)biphenyl-3-yl]phenanthro[9′,10′:4,5]furo[2,3-b]pyrazine (abbreviation: 11mDBtBPPnfpr) represented by Structural Formula (ii) above, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (iii) above, and a red phosphorescent material OCPG-006 were deposited by co-evaporation over the first hole-transport layer to a thickness of 40 nm such that the weight ratio of 11mDBtBPPnfpr to PCBBiF to OCPG-006 was 0.7:0.3:0.05, whereby the first light-emitting layer was formed.

After that, 9-[3-(4,6-diphenyl-1,3,5-triazin-2-yl)phenyl]-9′-phenyl-2,3′-bi-9H-carbazole (abbreviation: mPCCzPTzn-02) represented by Structural Formula (iv) above was deposited by evaporation to a thickness of 10 nm, so that the first electron-transport layer was formed.

After the first electron-transport layer was formed, 2,2′-(1,3-phenylene)bis(9-phenyl-1,10-phenanthroline) (abbreviation: mPPhen2P) represented by Structural Formula (v) above as the second organic compound having a phenanthroline skeleton and lithium oxide (Li₂O) were deposited by co-evaporation to a thickness of 5 nm such that the weight ratio of mPPhen2P to Li₂O was 1:0.02, whereby the first layer was formed. Then, copper phthalocyanine (abbreviation: CuPc) represented by Structural Formula (vii) above was deposited by evaporation to a thickness of 2 nm, whereby the third layer was formed. Furthermore, oFBiSF(2) and OCHD-003 were deposited by co-evaporation to a thickness of 10 nm such that the weight ratio of oFBiSF(2) to OCHD-003 was 1:0.15, whereby the second layer was formed. Thus, the intermediate layer was formed.

Over the intermediate layer, oFBiSF(2) was deposited by evaporation to a thickness of 75 nm, so that the second hole-transport layer was formed.

Over the second hole-transport layer, 11mDBtBPPnfpr, PCBBiF, and OCPG-006 were deposited by co-evaporation to a thickness of 40 nm such that the weight ratio of 11mDBtBPPnfpr to PCBBiF to OCPG-006 was 0.7:0.3:0.05, whereby the second light-emitting layer was formed.

Then, 2,2′-[1,2-naphthalendiyldi(4,1-phenylene)]bis(4,6-diphenyl-1,3,5-triazine) (abbreviation: TznP2N) represented by Structural Formula (viii) above and 8-hydroxyquinolinato-lithium (abbreviation: Liq) represented by Structural Formula (ix) above were deposited by co-evaporation to a thickness of 25 nm such that the weight ratio of TznP2N to Liq was 1:1, whereby the second electron-transport layer was formed.

Then, Liq was deposited by evaporation to a thickness of 1 nm and silver (Ag) and magnesium (Mg) were deposited by co-evaporation to a thickness of 15 nm such that the volume ratio of Ag to Mg was 1:0.1, whereby the second electrode 102 was formed. Over the second electrode 102, a film of 4,4′,4″-(benzene-1,3,5-triyl)tri(dibenzothiophene) (abbreviation: DBT3P-II) represented by Structural Formula (x) above was formed to a thickness of 70 nm as a cap layer to improve light extraction efficiency.

Next, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device R1 was fabricated.

### (Fabrication Method of Comparative Light-Emitting Device R1)

The comparative light-emitting device R1 was fabricated in a manner similar to that of the light-emitting device R1 except that 4-[3,5-bis(9H-carbazol-9-yl)phenyl]-2-phenyl-6-(biphenyl-4-yl)pyrimidine (abbreviation: 6BP-4Cz2PPm) represented by Structural Formula (xi) above was used instead of TznP2N in the second electron-transport layer.

### (Fabrication Method of Light-Emitting Device G1)

The light-emitting device G1 was fabricated in a manner similar to that of the light-emitting device R1 except that the thickness of the first hole-transport layer was changed to 80 nm, the thickness of the second hole-transport layer was changed to 60 nm, and the first light-emitting layer and the second light-emitting layer were each formed by co-evaporation of 8-(p-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (xii) above, 9-(2-naphthyl)-9′-phenyl-3,3′-bi-9H-carbazole (abbreviation: βNCCP) represented by Structural Formula (xiii) above, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) represented by Structural Formula (xiv) above such that the weight ratio of 8mpTP-4mDBtPBfpm to βNCCP to Ir(5mppy-d₃)₂(mbfpypy-d₃) was 0.5:0.5:0.1.

### (Fabrication Method of Comparative Light-Emitting Device G1)

The comparative light-emitting device G1 was fabricated in a manner similar to that of the light-emitting device G1 except that 6BP-4Cz2PPm was used instead of TznP2N in the second electron-transport layer and the first light-emitting layer and the second light-emitting layer were each formed by co-evaporation of 9-(4,6-diphenyl-1,3,5-triazin-2-yl)-9′-phenyl-9H,9′H-3,3′-bicarbazole (abbreviation: PCCzTzn) represented by Structural Formula (xv) above and Ir(5mppy-d₃)₂(mbfpypy-d₃) such that the weight ratio of PCCzTzn to Ir(5mppy-d₃)₂(mbfpypy-d₃) was 1:0.1.

### (Fabrication Method of Light-Emitting Device B1)

The light-emitting device B1 was fabricated in a manner similar to that of the light-emitting device R1 except that the thickness of the first hole-transport layer was changed to 45 nm, the thickness of the second hole-transport layer was changed to 55 nm, and the first light-emitting layer and the second light-emitting layer were each formed to a thickness of 25 nm by co-evaporation of 9-(1-naphthyl)-10-[4-(2-naphthyl)phenyl]anthracene (abbreviation: αN-βNPAnth) represented by Structural Formula (xvi) above and N,N′-diphenyl-N,N′-bis(9-phenyl-9H-carbazol-2-yl) naphtho[2,3-b;6,7-b′]bisbenzofuran-3,10-diamine (abbreviation: 3,10PCA2Nbf(IV)-02) represented by Structural Formula (xvii) above such that the weight ratio of αN-βNPAnth to 3,10PCA2Nbf(IV)-02 was 1:0.015.

### (Fabrication Method of Comparative Light-Emitting Device B1)

The comparative light-emitting device B1 was fabricated in a manner similar to that of the light-emitting device B1 except that 6BP-4Cz2PPm was used instead of TznP2N in the second electron-transport layer.

The structures of the light-emitting device R1, the light-emitting device G1, the light-emitting device B1, the comparative light-emitting device R1, the comparative light-emitting device G1, and the comparative light-emitting device B1 are shown below.

TABLE 1

| | | |
|---|---|---|
| | | Comparative |
| Thickness | Light-emitting | light-emitting |
| (nm) | device R1 | device R1 |

| Cap layer | | 70 | DBT3P-II |
|---|---|---|---|
| Second electrode | 2 | 15 | Ag:Mg (1:0.1) |
| | 1 | 1 | Liq |

| | | | |
|---|---|---|---|
| Second electron-transport | 25 | TznP2N:Liq | 6BP-4Cz2PPm:Liq |
| layer | | (1:1) | (1:1) |

| Second light-emitting layer | | 40 | 11mDBtBPPnfpr:PCBBiF:OCPG-006 |
|---|---|---|---|
| | | | (0.7:0.3:0.05) |
| Second hole-transport layer | | 75 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | | 10 | mPCCzPTzn-02 |
|---|---|---|---|
| First light-emitting layer | | 40 | 11mDBtBPPnfpr:PCBBiF:OCPG-006 |
| | | | (0.7:0.3:0.05) |
| First hole-transport layer | | 150 | oFBiSF(2) |
| Hole-injection layer | | 10 | oFBiSF(2):OCHD-003 (1:0.03) |
| First electrode | 2 | 85 | ITSO |
| | 1 | 100 | Ag |

TABLE 2

| | | |
|---|---|---|
| | | Comparative |
| Thickness | Light-emitting | light-emitting |
| (nm) | device G1 | device G1 |

| Cap layer | | 70 | DBT3P-II |
|---|---|---|---|
| Second electrode | 2 | 15 | Ag:Mg (1:0.1) |
| | 1 | 1 | Liq |

| | | | |
|---|---|---|---|
| Second electron-transport | 25 | TznP2N:Liq | 6BP-4Cz2PPm:Liq |
| layer | | (1:1) | (1:1) |

| Second light-emitting layer | | 40 | *1 |
|---|---|---|---|
| Second hole-transport layer | | 60 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | | 10 | mPCCzPTzn-02 |
|---|---|---|---|
| First light-emitting layer | | 40 | *1 |
| First hole-transport layer | | 80 | oFBiSF(2) |
| Hole-injection layer | | 10 | oFBiSF(2):OCHD-003 (1:0.03) |
| First electrode | 2 | 85 | ITSO |
| | 1 | 100 | Ag |

TABLE 3

| | *1 |
|---|---|
| Light-emitting | 8mpTP-4mDBtPBfpm:βNCCP:Ir(5mppy-d₃)₂(mbfpypy-d₃) |
| device G1 | (0.5:0.5:0.1) |
| Comparative light- | PCCzTzn:Ir(5mppy-d₃)₂(mbfpypy-d₃) |
| emitting device G1 | (1:0.1) |

TABLE 4

| | | |
|---|---|---|
| | | Comparative |
| Thickness | Light-emitting | light-emitting |
| (nm) | device B1 | device B1 |

| Cap layer | | 70 | DBT3P-II |
|---|---|---|---|
| Second electrode | 2 | 15 | Ag:Mg (1:0.1) |
| | 1 | 1 | Liq |

| | | | |
|---|---|---|---|
| Second electron-transport | 25 | TznP2N:Liq | 6BP-4Cz2PPm:Liq |
| layer | | (1:1) | (1:1) |

| Second light-emitting layer | | 25 | αN-βNPAnth:3,10PCA2Nbf(IV)-02 |
|---|---|---|---|
| | | | (1:0.015) |
| Second hole-transport layer | | 55 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | | 10 | mPCCzPTzn-02 |
|---|---|---|---|
| First light-emitting layer | | 25 | αN-βNPAnth:3,10PCA2Nbf(IV)-02 |
| | | | (1:0.015) |
| First hole-transport layer | | 45 | oFBiSF(2) |
| Hole-injection layer | | 10 | oFBiSF(2):OCHD-003 (1:0.03) |
| First electrode | 2 | 85 | ITSO |
| | 1 | 100 | Ag |

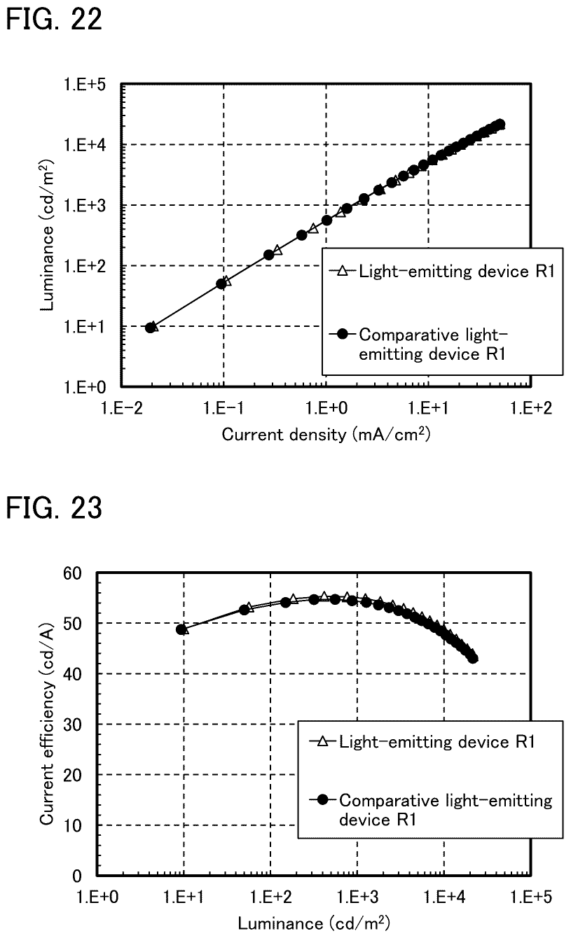

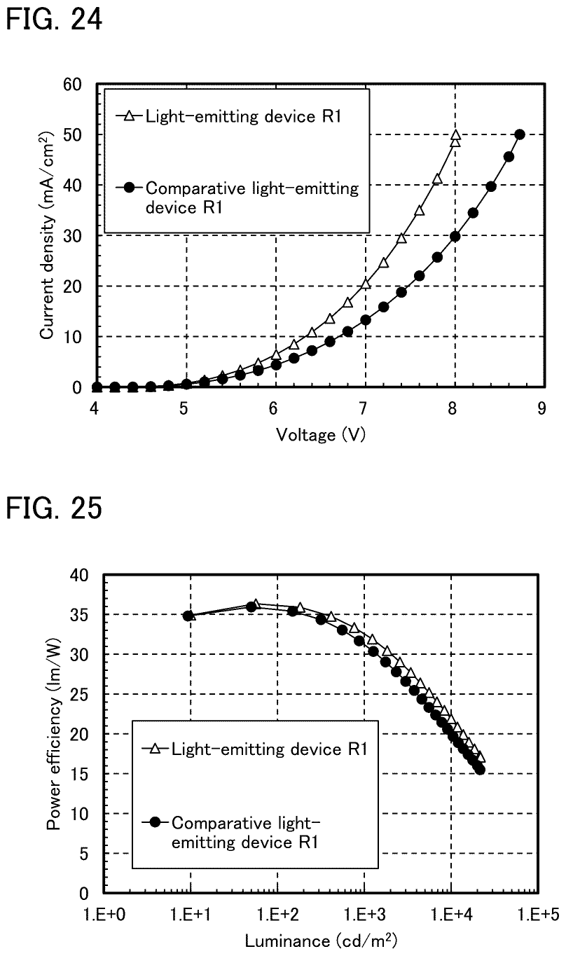

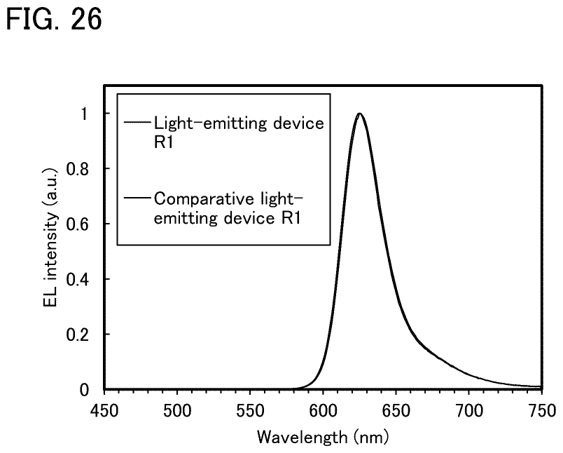

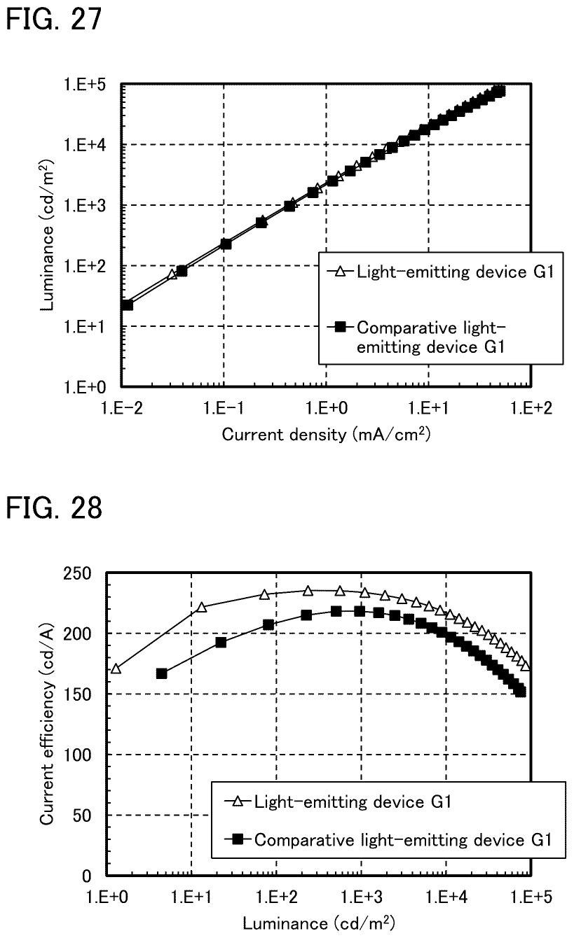

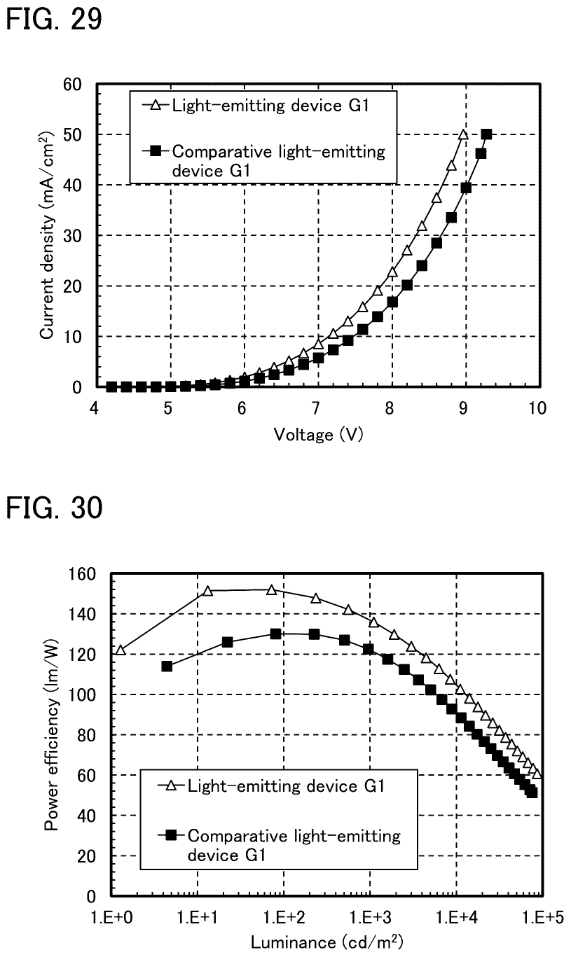

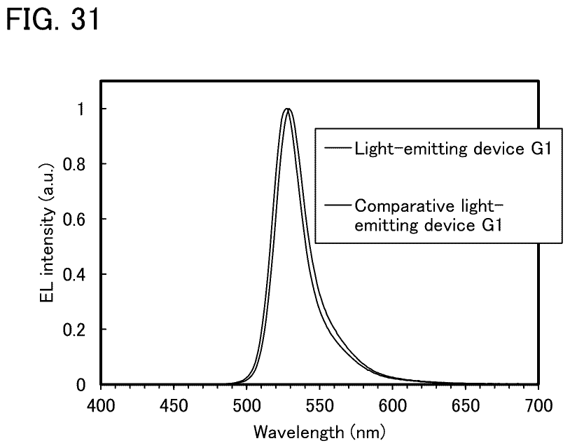

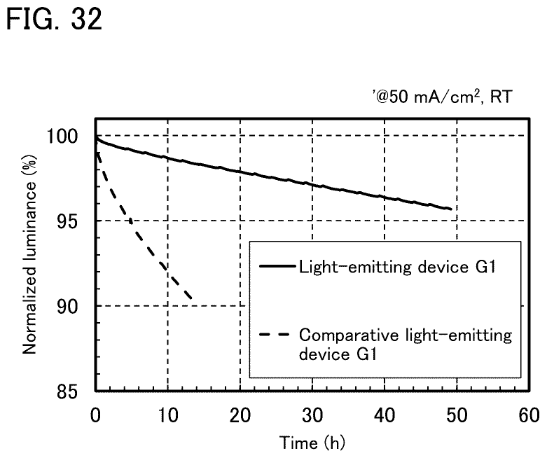

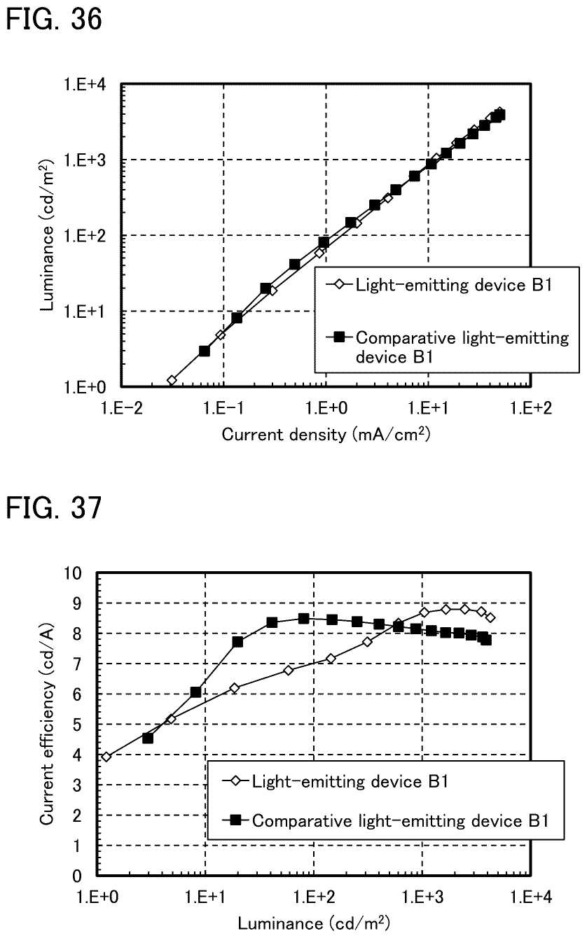

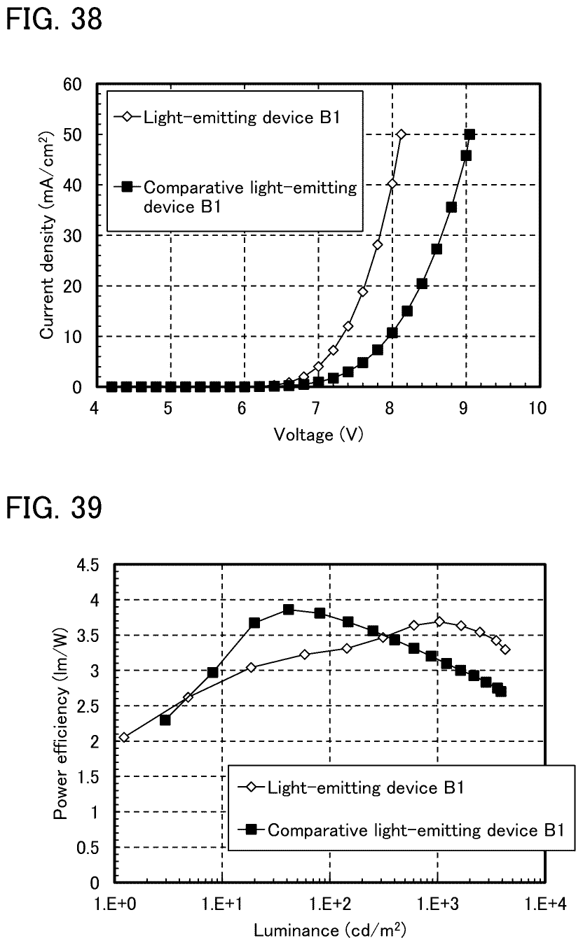

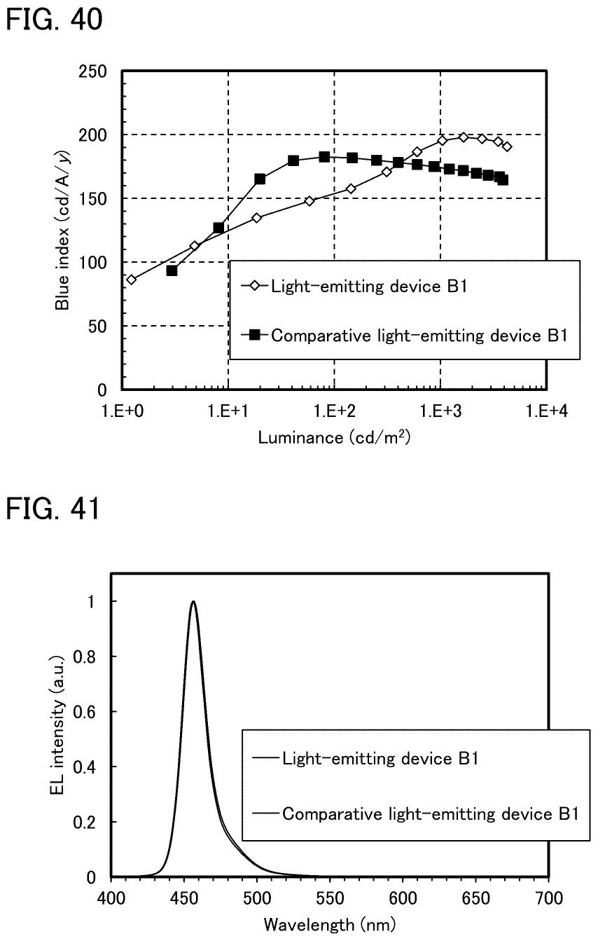

FIG. 22, FIG. 23, FIG. 24, FIG. 25, and FIG. 26 respectively show the luminance-current density characteristics, current efficiency-luminance characteristics, current density-voltage characteristics, power efficiency-luminance characteristics, and electroluminescence spectra of the light-emitting device R1 and the comparative light-emitting device R1. FIG. 27, FIG. 28, FIG. 29, FIG. 30, FIG. 31, and FIG. 32 respectively show the luminance-current density characteristics, current efficiency-luminance characteristics, current density-voltage characteristics, power efficiency-luminance characteristics, electroluminescence spectra, and time dependence of normalized luminance of the light-emitting device G1 and the comparative light-emitting device G1. FIG. 36, FIG. 37, FIG. 38, FIG. 39, FIG. 40, and FIG. 41 respectively show the luminance-current density characteristics, current efficiency-luminance characteristics, current density-voltage characteristics, power efficiency-luminance characteristics, blue index-luminance characteristics, and electroluminescence spectra of the light-emitting device B1 and the comparative light-emitting device B1.

Table 5 shows the main characteristics of the light-emitting device R1 and the comparative light-emitting device R1 at approximately 1000 cd/m². Table 6 shows those of the light-emitting device G1 and the comparative light-emitting device G1 at approximately 1000 cd/m². Table 7 shows those of the light-emitting device B1 and the comparative light-emitting device B1 at approximately 1000 cd/m². The luminance, CIE chromaticity, and electroluminescence spectra were measured at room temperature with a spectroradiometer (SR-ULIR, TOPCON TECHNOHOUSE CORPORATION).

TABLE 5

| | | | Current | | | Current | Power |
|---|---|---|---|---|---|---|---|
| | Voltage | Current | density | Chromaticity | Chromaticity | efficiency | efficiency |
| | (V) | (mA) | (mA/cm²) | x | y | (cd/A) | (lm/W) |
| Light-emitting | 5.20 | 0.06 | 1.4 | 0.69 | 0.31 | 55.2 | 33.4 |
| device R1 | | | | | | | |
| Comparative | 5.40 | 0.06 | 1.6 | 0.69 | 0.31 | 54.5 | 31.7 |
| light-emitting | | | | | | | |
| device R1 | | | | | | | |

FIGS. 22 to 26 and Table 5 reveal that red light emission with an electroluminescence spectrum peak wavelength of 625 nm can be obtained from both the light-emitting device R1 and the comparative light-emitting device R1. Although both the light-emitting device R1 and the comparative light-emitting device R1 have high current efficiency, FIG. 24 shows that the light-emitting device R1 has a lower driving voltage and more favorable characteristics than the comparative light-emitting device R1. This indicates that the light-emitting device R1 of one embodiment of the present invention is a tandem light-emitting device with favorable characteristics.

TABLE 6

| | | | Current | | | Current | Power |
|---|---|---|---|---|---|---|---|
| | Voltage | Current | density | Chromaticity | Chromaticity | efficiency | efficiency |
| | (V) | (mA) | (mA/cm²) | x | y | (cd/A) | (lm/W) |
| Light-emitting | 5.40 | 0.02 | 0.5 | 0.24 | 0.72 | 233.6 | 135.9 |
| device G1 | | | | | | | |
| Comparative | 5.60 | 0.02 | 0.4 | 0.23 | 0.73 | 218.2 | 122.4 |
| light-emitting | | | | | | | |
| device G1 | | | | | | | |

FIGS. 27 to 31 and Table 6 reveal that green light emission with an electroluminescence spectrum peak wavelength of approximately 528 nm can be obtained from both the light-emitting device G1 and the comparative light-emitting device G1. Although both the light-emitting device G1 and the comparative light-emitting device G1 have high current efficiency, the light-emitting device G1 has higher power efficiency because of having higher current efficiency. It was also found that the light-emitting device G1 has a lower driving voltage and lower power consumption than the comparative light-emitting device G1 and have favorable characteristics. This indicates that the light-emitting device G1 of one embodiment of the present invention is a tandem light-emitting device with favorable characteristics.

FIG. 32 shows the time-dependence of normalized luminance of the light-emitting device G1 and the comparative light-emitting device G1 at a current density of 50 mA/cm².

FIG. 32 shows that the light-emitting device G1 of one embodiment of the present invention has lower time dependence of normalized luminance than the comparative light-emitting device G1 and has high reliability.

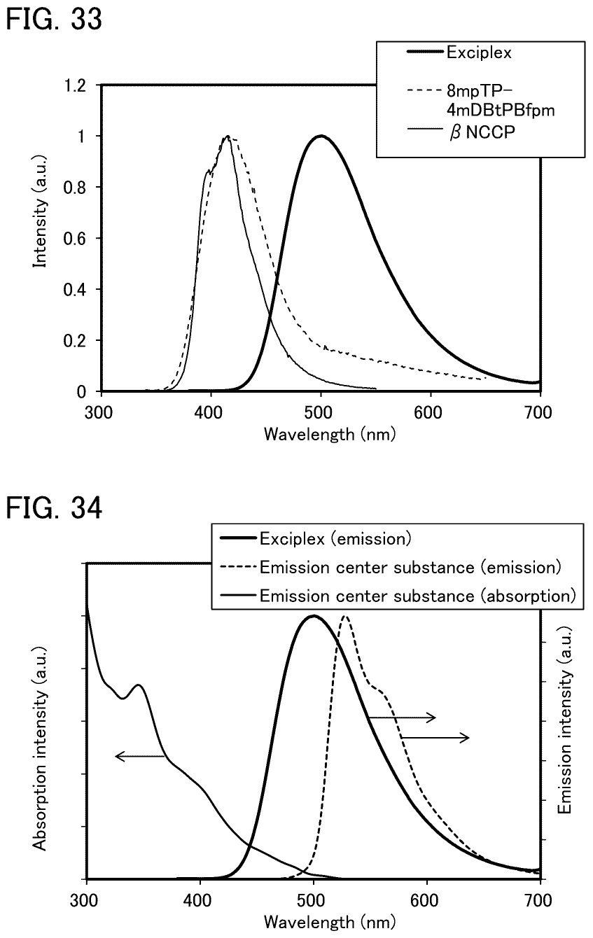

FIG. 33 shows measured PL spectra of a film formed by evaporation of 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), a film formed by evaporation of 9-(2-naphthyl)-9′-phenyl-3,3′-bi-9H-carbazole (abbreviation: βNCCP), and a film (mixed film) formed by co-evaporation of 8mpTP-4mDBtPBfpm and βNCCP such that the weight ratio of 8mpTP-4mDBtPBfpm to βNCCP was 1:1. As shown in the graph, the emission spectrum of the co-evaporation film is on a longer wavelength side than the emission spectrum of each organic compound, which indicates that 8mpTP-4mDBtPBfpm and βNCCP form an exciplex in combination.

FIG. 34 shows a PL spectrum of a film (mixed film) formed by co-evaporation of 8mpTP-4mDBtPBfpm and βNCCP such that the weight ratio of 8mpTP-4mDBtPBfpm to βNCCP was 1:1 (an emission spectrum of an exciplex) and an absorption spectrum and a PL spectrum of Ir(5mppy-d₃)₂(mbfpypy-d₃), which is the emission center substance. As can be seen from FIG. 34, the emission edge (442 nm) on a shorter wavelength side of the PL spectrum of the exciplex of 8mpTP-4mDBtPBfpm and βNCCP is positioned at a shorter wavelength than the absorption edge (526 nm) on a longer wavelength side of the absorption spectrum of Ir(5mppy-d₃)₂(mbfpypy-d₃). Since the PL spectrum of the exciplex of 8mpTP-4mDBtPBfpm and βNCCP and the absorption edge of Ir(5mppy-d₃)₂(mbfpypy-d₃) have such a positional relation, excitation energy can be efficiently transferred to Ir(5mppy-d₃)₂(mbfpypy-d₃) in the light-emitting device G1.

Alternatively, the peak wavelength (500 nm) of the PL spectrum of the exciplex formed by 8mpTP-4mDBtPBfpm and βNCCP is shorter than the peak wavelength (528 nm) of the PL spectrum of Ir(5mppy-d₃)₂(mbfpypy-d₃). The difference between the peak wavelength of the PL spectrum of the exciplex and the peak wavelength of the PL spectrum of Ir(5mppy-d₃)₂(mbfpypy-d₃) is less than or equal to 30 nm. Such a relationship between the peak wavelength of the PL spectrum of the exciplex and the peak wavelength of the PL spectrum of Ir(5mppy-d₃)₂(mbfpypy-d₃) enables efficient energy transfer.

Alternatively, the difference between the peak wavelength (500 nm) of the PL spectrum of the exciplex formed by 8mpTP-4mDBtPBfpm and βNCCP and the wavelength (526 nm) of the absorption edge on a longer wavelength side of the absorption spectrum of Ir(5mppy-d₃)₂(mbfpypy-d₃) is 26 nm, which is less than or equal to 30 nm. Such a relationship between the peak wavelength of the PL spectrum of the exciplex and the wavelength of the absorption edge on a longer wavelength side of the absorption spectrum of Ir(5mppy-d₃)₂(mbfpypy-d₃) enables efficient energy transfer.

Note that the PL spectrum of the exciplex was measured using a film formed by co-evaporation of 8mpTP-4mDBtPBfpm and βNCCP. The PL spectrum or the absorption spectrum of Ir(5mppy-d₃)₂(mbfpypy-d₃) was measured using a solution thereof in which chloroform was used as a solvent.

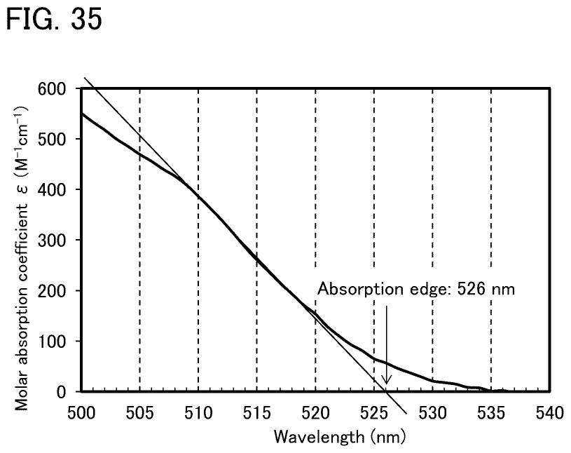

The absorption edge of the absorption spectrum was determined as the intersection between a tangent and the horizontal axis or the baseline. The tangent was drawn at a point at which the slope on a longer wavelength side of the longest-wavelength peak (or the longest-wavelength shoulder peak) of the absorption spectrum has the maximum absolute value. The emission edge on a shorter wavelength side of the PL spectrum was determined as the intersection between a tangent and the horizontal axis or the baseline. The tangent was drawn at a point at which the slope on a shorter wavelength side of the shortest-wavelength peak (or the shortest-wavelength shoulder peak) of the PL spectrum has the maximum absolute value. FIG. 35 shows an example of determining the absorption edge of the absorption spectrum of Ir(5mppy-d₃)₂(mbfpypy-d₃). In this manner, the absorption edge of Ir(5mppy-d₃)₂(mbfpypy-d₃) can be determined to be at 526 nm.

The HOMO level of βNCCP as the organic compound having a hole-transport property was −5.62 eV; the HOMO level of 8mpTP-4mDBtPBfpm as the organic compound having an electron-transport property was −6.2 eV (reference value); the LUMO level of βNCCP as the organic compound having a hole-transport property was −2.21 eV; and the LUMO level of 8mpTP-4mDBtPBfpm as the organic compound having an electron-transport property was −3.01 eV. Since the HOMO level of the organic compound having a hole-transport property is higher than or equal to the HOMO level of the organic compound having an electron-transport property and the LUMO level of the organic compound having a hole-transport property is higher than or equal to the LUMO level of the organic compound having an electron-transport property, the light-emitting device G1 was found to have a structure in which an exciplex can be formed more efficiently.

The HOMO level and the LUMO level of Ir(5mppy-d₃)₂(mbfpypy-d₃) were −5.32 eV and −2.39 eV, respectively. The energy difference between the HOMO level and the LUMO level of the exciplex was 2.61 eV, which corresponds to the energy difference between the HOMO level (−5.62 eV) of βNCCP as the organic compound having a hole-transport property and the LUMO level (−3.01 eV) of 8mpTP-4mDBtPBfpm as the organic compound having an electron-transport property. The energy difference (2.93 eV) between the HOMO level (−5.32 eV) and the LUMO level (−2.39 eV) of Ir(5mppy-d₃)₂(mbfpypy-d₃), which corresponds to the band gap thereof, was found to be larger than the energy difference between the HOMO level and the LUMO level of the exciplex.

The values of the HOMO level and the LUMO level were obtained through a cyclic voltammetry (CV) measurement. In the cyclic voltammetry (CV) measurement, the values (E) of the HOMO and LUMO levels were calculated on the basis of an oxidation peak potential (Eₚₐ) and a reduction peak potential (E_{pc}), which were obtained by changing the potential of a working electrode with respect to a reference electrode. In the measurement, the HOMO level and the LUMO level were obtained by potential scanning in the positive direction and potential scanning in the negative direction, respectively. The scanning speed in the measurement was 0.1 V/s. Specifically, a standard oxidation-reduction potential (Eₒ) (=Eₚₐ+E_{pc})/2) was calculated from an oxidation peak potential (Eₚₐ) and a reduction peak potential (E_{pc}), which were obtained by the cyclic voltammogram of a material. Then, the standard oxidation-reduction potential (Eₒ) was subtracted from the potential energy (Eₓ) of the reference electrode with respect to a vacuum level, whereby each of the values (E) (=Eₓ−Eₒ) of the HOMO and LUMO levels was obtained. Note that the reversible oxidation-reduction wave was obtained in the above case; in the case where an irreversible oxidation-reduction wave is obtained, the HOMO level is calculated as follows: a value obtained by subtracting a predetermined value (0.1 eV) from an oxidation peak potential (Eₚₐ) is assumed to be a reduction peak potential (E_{pc}), and a standard oxidation-reduction potential (Eₒ) is calculated to one decimal place. To calculate the LUMO level, a value obtained by adding a predetermined value (0.1 eV) to a reduction peak potential (E_{pc}) was assumed to be an oxidation peak potential (Eₚₐ), and a standard oxidation-reduction potential (Eₒ) was calculated to one decimal place.

TABLE 7

| | | | Current | | | Current | Power | |
|---|---|---|---|---|---|---|---|---|
| | Voltage | Current | density | Chromaticity | Chromaticity | efficiency | efficiency | BI |
| | (V) | (mA) | (mA/cm²) | x | y | (cd/A) | (lm/W) | (cd/A/y) |
| Light-emitting | 7.40 | 0.48 | 12.0 | 0.14 | 0.04 | 8.7 | 3.7 | 195 |
| device B1 | | | | | | | | |
| Comparative | 8.00 | 0.43 | 10.7 | 0.14 | 0.05 | 8.1 | 3.2 | 175 |
| light-emitting | | | | | | | | |
| device B1 | | | | | | | | |

FIGS. 36 to 41 and Table 7 reveal that blue light emission with an electroluminescence spectrum peak wavelength of approximately 456 nm can be obtained from both the light-emitting device B1 and the comparative light-emitting device B1. Although both the light-emitting device B1 and the comparative light-emitting device B1 have high current efficiency, the light-emitting device B1 has lower power consumption and more favorable characteristics because of its driving voltage lower than that of the comparative light-emitting device B1. It was also found that the light-emitting device B1 has a high blue index. This indicates that the light-emitting device B1 of one embodiment of the present invention is a tandem light-emitting device with favorable characteristics. In addition, the light-emitting device B1 has especially favorable characteristics at a practical luminance of and above 500 cd/cm².

Note that the blue index (BI) is a value obtained by dividing current efficiency (cd/A) by the y value of CIE chromaticity (x, y), and is one of the indicators of characteristics of blue light emission. As the y chromaticity value of blue light emission becomes smaller, the color purity thereof tends to be higher. Blue light emission having a small y chromaticity value and high color purity enables expression of blue colors with a wide range of chromaticity in a display. Using blue light emission with high color purity reduces the luminance of blue light emission necessary for a display to express white, leading to lower power consumption of the display. Thus, BI, which is current efficiency based on a y chromaticity value as one of the indicators of color purity of blue, is suitably used as a means for showing efficiency of blue light emission in some cases. The light-emitting device with higher BI can be regarded as a blue-light-emitting device having higher efficiency for a display.

Here, the second electron-transport layers of the light-emitting device R1, the light-emitting device G1, and the light-emitting device B1 include the same material (the first organic compound having a triazine skeleton). Thus, the light-emitting devices of different emission colors of embodiments of the present invention can each have favorable characteristics even when the second electron-transport layers of the light-emitting devices are made of the same material.

Next, a display device of this example including the light-emitting device R1, the light-emitting device G1, and the light-emitting device B1 respectively in red, green, and blue subpixels and a display device of a comparative example including the comparative light-emitting device R1, the comparative light-emitting device G1, and the comparative light-emitting device B1 respectively in red, green, and blue subpixels were assumed, and the power consumption of their display portions (except for the power consumption of a driving transistor, a driving circuit, and the like) was tentatively calculated. Note that each of the light-emitting devices assumed to be used in the display devices is a tandem light-emitting device, and the same emission center substance is used in a plurality of light-emitting layers in each of the light-emitting devices. Thus, both of the display devices employ a side-by-side patterning method.

The conditions of the display devices assumed for the tentative calculation are as follows.

TABLE 8

| | | |
|---|---|---|
| Panel size | 5 | inches (16:9) |
| Panel area | 68.9 | cm² |

| | | | |
|---|---|---|---|
| Aperture ratio | 30% | Red | 10% |
| | | Green | 10% |
| | | Blue | 10% |

| | | |
|---|---|---|
| Effective luminance | 1000 | cd/m² in displaying white on the entire screen |

| | |
|---|---|
| Circularly polarizing plate | Not used |

First, in each of the display devices under the above-described conditions, the luminance (effective luminance) of the light-emitting devices of RGB to obtain 1000 cd/m² emission of white light with CIE 1931 chromaticity coordinates (x, y)=(0.31, 0.33) when the display device is made to emit white light from the entire screen was calculated.

Next, the luminance (intrinsic luminance) required to obtain the calculated effective luminance of the light-emitting devices of RGB was calculated in consideration of the aperture ratios. The intrinsic luminance is the luminance at which each light-emitting device actually emits light in order to obtain the effective luminance of 1000 cd/m² when the display device is made to emit white light with CIE 1931 chromaticity coordinates (x, y)=(0.31, 0.33) from the entire screen. Since the aperture ratio of the whole display device subjected to the tentative calculation is 30% and the aperture ratio per emission color is 10%, the intrinsic luminance is approximately ten times the effective luminance.

From the measurement results of the light-emitting devices described above and the intrinsic luminance, the current density and voltage for making each light-emitting device emit light at the intrinsic luminance can be obtained. In other words, in each of the display devices under the above-described conditions, the current density and voltage of each light-emitting device to obtain 1000 cd/m² luminance emission of white light with CIE 1931 chromaticity coordinates (x, y)=(0.31, 0.33) when the display device is made to emit white light from the entire screen can be obtained.

The power consumption is calculated by multiplying the amount of current by the voltage. The amount of current is calculated by multiplying the current density, the panel area, and the aperture ratio. The display devices subjected to the tentative calculation each have a diagonal size of 5 inches, an aspect ratio of 16:9, a panel area of 68.9 cm², and an aperture ratio of the light-emitting device of each color of 10%, and the amount of current can be calculated by multiplying the current density calculated in the previous paragraph by these values. Furthermore, power consumption of the light-emitting device of each emission color can be calculated by multiplying the amount of current by the voltage obtained in the previous paragraph. By calculating and summing up the power consumptions of the light-emitting devices of RGB, the total power consumption of the display portion of the display device (except for the power consumption of the driving transistor, the driving circuit, and the like) can be obtained.

Table 9 shows the calculated power consumption of the display device of this example assumed to use the light-emitting device R1, the light-emitting device G1, and the light-emitting device B1, and Table 10 shows the calculated power consumption of the display device of the comparative example assumed to use the comparative light-emitting device R1, the comparative light-emitting device G1, and the comparative light-emitting device B1.

TABLE 9
This example

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/cm²) | (mA) | (V) | (mW) |
| Red | 0.69 | 0.31 | 236 | 2361 | 53.8 | 4.4 | 30.3 | 5.74 | 173.8 |
| Green | 0.24 | 0.72 | 706 | 7059 | 221.4 | 3.2 | 22.0 | 6.27 | 137.8 |
| Blue | 0.14 | 0.04 | 58 | 580 | 8.3 | 7.0 | 48.2 | 7.18 | 346.5 |
| White on the | 0.31 | 0.33 | 1000 | — | 68.6 | — | 100.5 | — | 658.1 |
| entire screen | | | | | | | | | |

TABLE 10
Comparative example

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/m²) | (mA) | (V) | (mW) |
| Red | 0.69 | 0.31 | 246 | 2460 | 53.0 | 4.6 | 32.0 | 6.04 | 193.4 |
| Green | 0.22 | 0.73 | 694 | 6938 | 204.4 | 3.4 | 23.4 | 6.61 | 154.6 |
| Blue | 0.14 | 0.05 | 60 | 601 | 8.2 | 7.3 | 50.4 | 7.80 | 392.9 |
| White on the | 0.31 | 0.33 | 1000 | — | 65.1 | — | 105.8 | — | 740.9 |
| entire screen | | | | | | | | | |

Table 9 and Table 10 show that the display device of this example has higher current efficiency in white light emission and a lower driving voltage than the display device of the comparative example. Moreover, the power consumption of the display device of this example is lower than that of the display device of the comparative example.

Thus, the display device including the light-emitting devices of embodiments of the present invention, in each of which at least one of the light-emitting layers includes the emission center substance, the first host material, and the second host material and the first host material and the second host material are organic compounds and form an exciplex in combination, can have low power consumption because the light-emitting devices have high efficiency, high reliability, and a low driving voltage. It was found that the display device including the tandem light-emitting devices in each of which the second electron-transport layer includes the first organic compound having a triazine skeleton, the intermediate layer includes the mixed layer of the second organic compound having a phenanthroline skeleton and lithium or a lithium compound, and the difference in maximum peak wavelength between the emission spectra of light emitted from the light-emitting layers is less than or equal to 30 nm can have favorable characteristics with lower power consumption. In addition, since the tandem light-emitting devices are fabricated by a side-by-side patterning method (i.e., the light-emitting layer included in the tandem light-emitting device is separated from a light-emitting layer included in at least one adjacent light-emitting device or is different from a light-emitting layer included in at least one adjacent light-emitting device, the emission color of the tandem light-emitting device is different from the emission color of at least one adjacent light-emitting device, or the emission center substance included in the light-emitting layer of the tandem light-emitting device has a structure different from that of an emission center substance included in a light-emitting layer of at least one adjacent light-emitting device), the tandem light-emitting devices can have extremely high current efficiency and can thus have higher power efficiency and higher energy efficiency.

The structure in which the second electron-transport layer includes the first organic compound having a triazine skeleton and the intermediate layer includes the mixed layer of the second organic compound having a phenanthroline skeleton and lithium or a lithium compound is common between the red-, green-, and blue-light-emitting devices. When the materials of the functional layers are common between the light-emitting devices of different colors, the raw material procurement cost can be reduced and the convenience in manufacturing can be improved. In the display device of one embodiment of the present invention, owing to the above structures of the second electron-transport layer and the intermediate layer, the light-emitting devices of all emission colors can have favorable characteristics even when the materials of the functional layers other than the light-emitting layer are common between the light-emitting devices.

### Example 2

Specific fabrication methods and characteristics of a light-emitting device R2, a light-emitting device G2, and a light-emitting device B2, which are light-emitting devices of embodiments of the present invention, and a comparative light-emitting device R2, a comparative light-emitting device G2, and a comparative light-emitting device B2, which are comparative light-emitting devices, are described in this example. Structural formulae of main compounds used in this example are shown below.

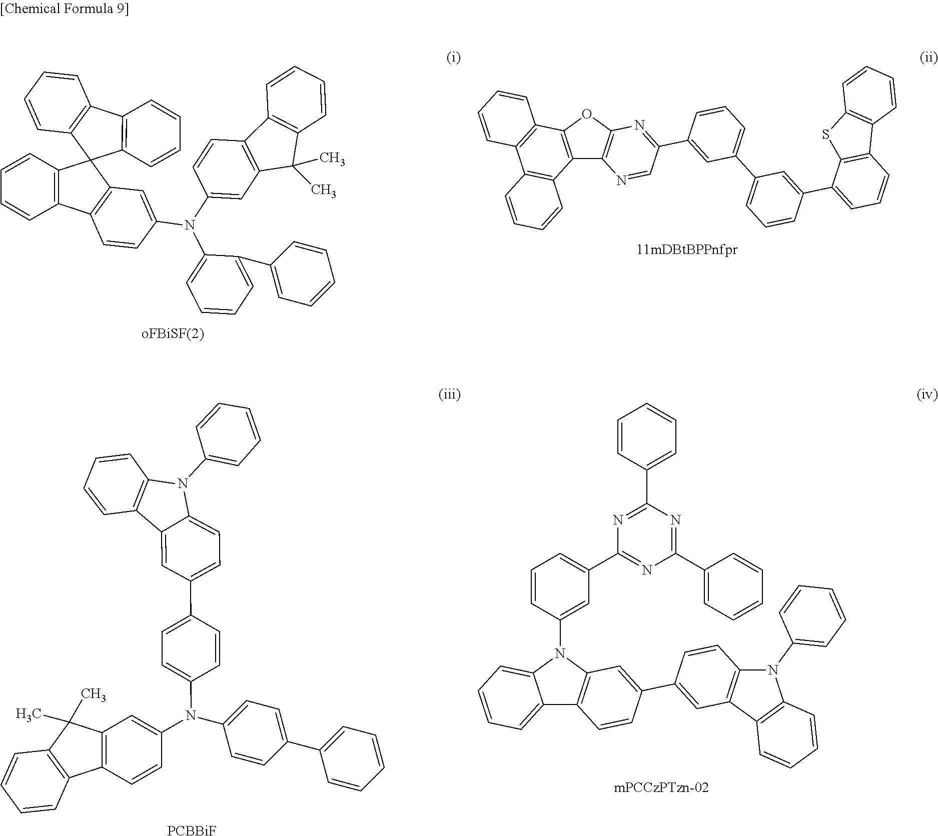

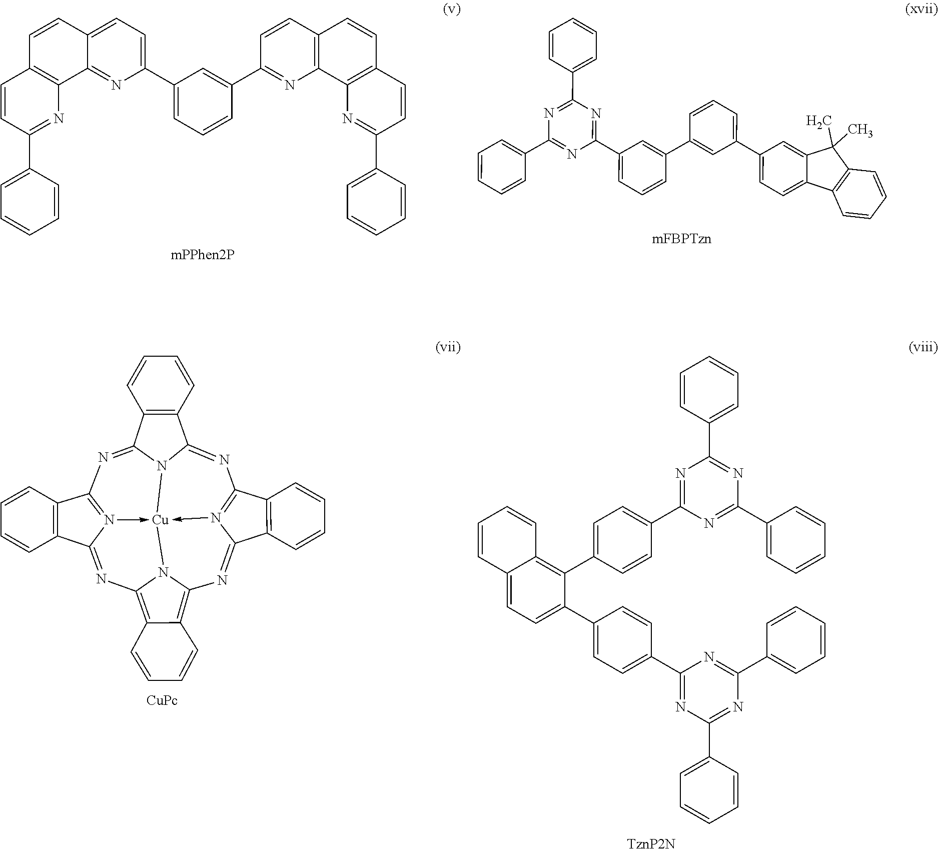

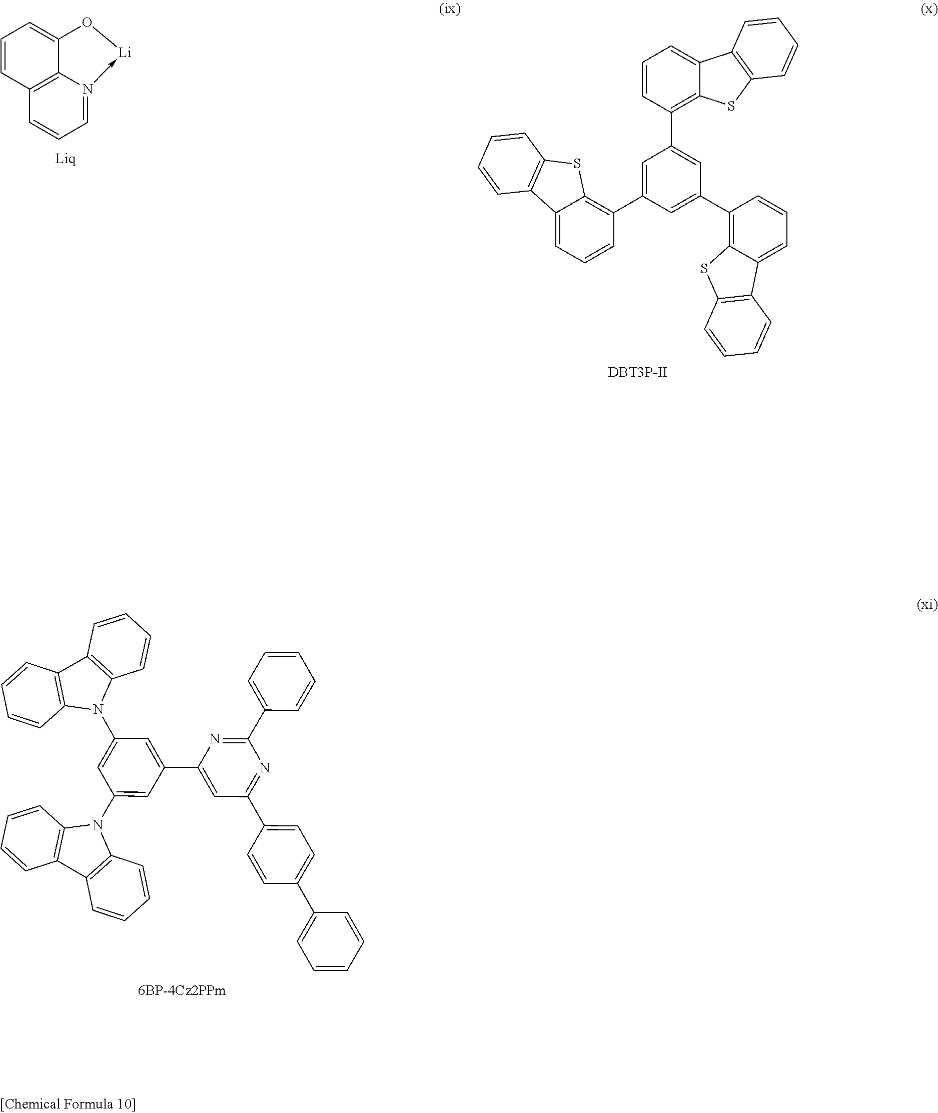

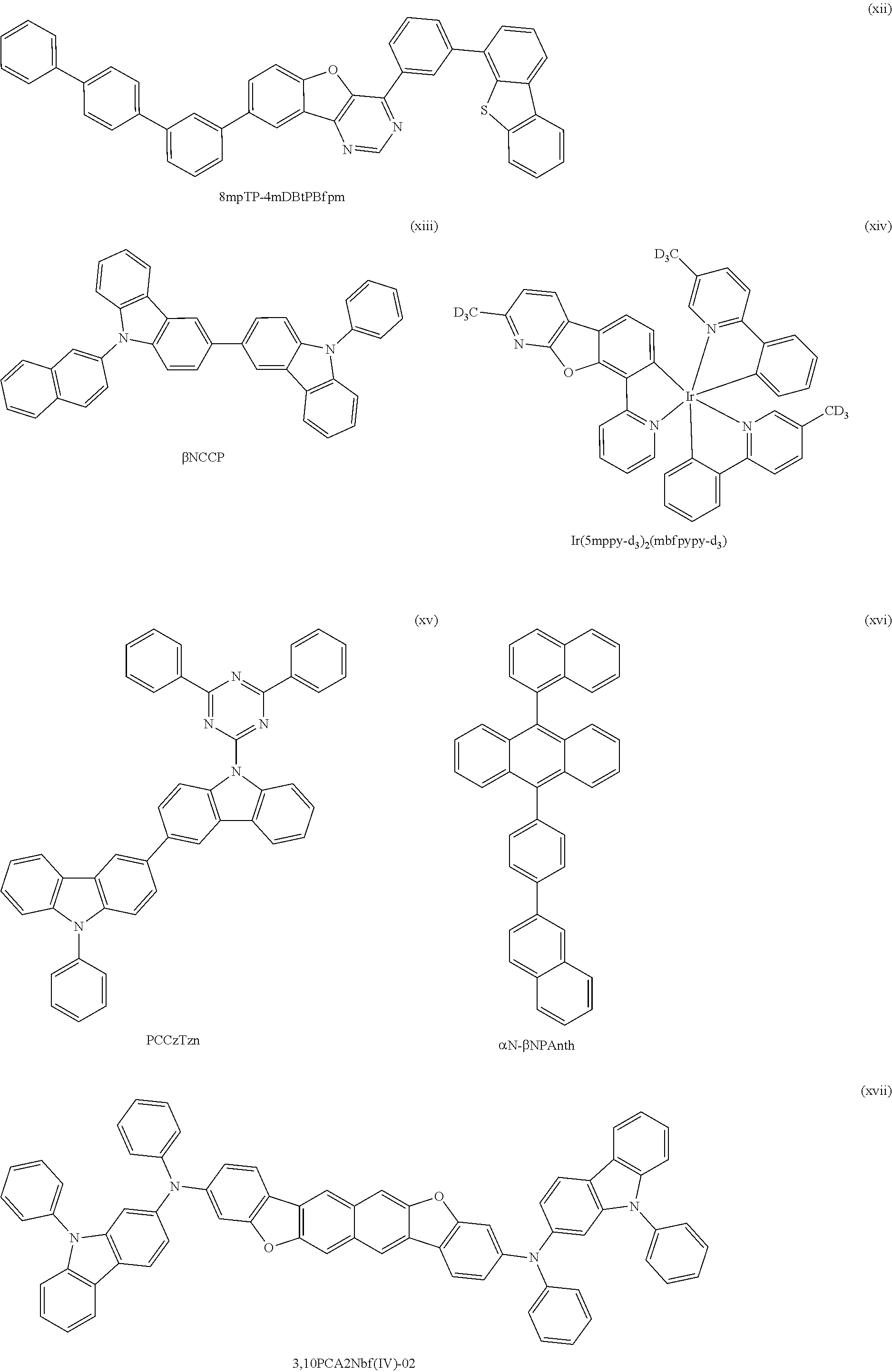

### (Fabrication Method of Light-Emitting Device R2)

First, 100-nm-thick silver (Ag) and 85-nm-thick indium tin oxide containing silicon oxide (ITSO) were stacked over a glass substrate sequentially from the substrate side by a sputtering method as a reflective electrode and a transparent electrode, respectively, so that the first electrode 101 with a size of 2 mm×2 mm was formed. Note that the transparent electrode functions as an anode, and the transparent electrode and the reflective electrode are collectively regarded as the first electrode 101.

Next, in pretreatment for fabricating the light-emitting device over the substrate, the surface of the substrate was washed with water, and baking was performed at 200° C. for one hour. After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was allowed to cool down for approximately 30 minutes.

Next, the substrate was fixed to a holder provided in the vacuum evaporation apparatus such that the surface on which the first electrode 101 was formed faced downward. Then, N-(biphenyl-2-yl)-N-(9,9-dimethylfluoren-2-yl)-9,9′-spirobi[9H-fluoren]-2-amine (abbreviation: oFBiSF(2)) represented by Structural Formula (i) above and a fluorine-containing material having an electron-acceptor property with a molecular weight of 672(OCHD-003) were deposited by co-evaporation over the first electrode 101 to a thickness of 10 nm such that the weight ratio of oFBiSF(2) to OCHD-003 was 1:0.03, whereby the hole-injection layer 111 was formed.

Over the hole-injection layer 111, oFBiSF(2) was deposited by evaporation to a thickness of 150 nm, so that the first hole-transport layer was formed.

Next, 11-[3′-(dibenzothiophen-4-yl)biphenyl-3-yl]phenanthro[9′,10′:4,5]furo[2,3-b]pyrazine (abbreviation: 11mDBtBPPnfpr) represented by Structural Formula (ii) above, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (iii) above, and a red phosphorescent material OCPG-006 were deposited by co-evaporation over the first hole-transport layer to a thickness of 40 nm such that the weight ratio of 11mDBtBPPnfpr to PCBBiF to OCPG-006 was 0.7:0.3:0.05, whereby the first light-emitting layer was formed.

After that, 9-[3-(4,6-diphenyl-1,3,5-triazin-2-yl)phenyl]-9′-phenyl-2,3′-bi-9H-carbazole (abbreviation: mPCCzPTzn-02) represented by Structural Formula (iv) above was deposited by evaporation to a thickness of 10 nm, so that the first electron-transport layer was formed.

After the first electron-transport layer was formed, 2,2′-(1,3-phenylene)bis(9-phenyl-1,10-phenanthroline) (abbreviation: mPPhen2P) represented by Structural Formula (v) above as the second organic compound having a phenanthroline skeleton and lithium oxide (Li₂O) were deposited by co-evaporation to a thickness of 5 nm such that the weight ratio of mPPhen2P to Li₂O was 1:0.02, whereby the first layer was formed. Then, copper phthalocyanine (abbreviation: CuPc) represented by Structural Formula (vii) above was deposited by evaporation to a thickness of 2 nm, whereby the third layer was formed. Furthermore, oFBiSF(2) and OCHD-003 were deposited by co-evaporation to a thickness of 10 nm such that the weight ratio of oFBiSF(2) to OCHD-003 was 1:0.15, whereby the second layer was formed. Thus, the intermediate layer was formed.

Over the intermediate layer, oFBiSF(2) was deposited by evaporation to a thickness of 65 nm, so that the second hole-transport layer was formed.

Over the second hole-transport layer, 11mDBtBPPnfpr, PCBBiF, and OCPG-006 were deposited by co-evaporation to a thickness of 40 nm such that the weight ratio of 11mDBtBPPnfpr to PCBBiF to OCPG-006 was 0.7:0.3:0.05, whereby the second light-emitting layer was formed.

Subsequently, 2-[3′-(9,9-dimethyl-9H-fluoren-2-yl)biphenyl-3-yl]-4,6-diphenyl-1,3,5-triazine (abbreviation: mFBPTzn) represented by Structural Formula (xviii) above was deposited by evaporation to a thickness of 10 nm and then, 2,2′-[1,2-naphthalendiyldi(4,1-phenylene)]bis(4,6-diphenyl-1,3,5-triazine) (abbreviation: TznP2N) represented by Structural Formula (viii) above and 8-hydroxyquinolinato-lithium (abbreviation: Liq) represented by Structural Formula (ix) above were deposited by co-evaporation to a thickness of 25 nm such that the weight ratio of TznP2N to Liq was 1:1, whereby the second electron-transport layer was formed.

Then, Liq was deposited by evaporation to a thickness of 1 nm and silver (Ag) and magnesium (Mg) were deposited by co-evaporation to a thickness of 15 nm such that the volume ratio of Ag to Mg was 1:0.1, whereby the second electrode 102 was formed. Over the second electrode 102, a film of 4,4′,4″-(benzene-1,3,5-triyl)tri(dibenzothiophene) (abbreviation: DBT3P-II) represented by Structural Formula (x) above was formed to a thickness of 70 nm as a cap layer to improve light extraction efficiency.

Next, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device R2 was fabricated.

### (Fabrication Method of Comparative Light-Emitting Device R2)

The comparative light-emitting device R2 was fabricated in a manner similar to that of the light-emitting device R2 except that 4-[3,5-bis(9H-carbazol-9-yl)phenyl]-2-phenyl-6-(biphenyl-4-yl)pyrimidine (abbreviation: 6BP-4Cz2PPm) represented by Structural Formula (xi) above was used instead of TznP2N in the second electron-transport layer.

### (Fabrication Method of Light-Emitting Device G2)

The light-emitting device G2 was fabricated in a manner similar to that of the light-emitting device R2 except that the thickness of the first hole-transport layer was changed to 80 nm, the thickness of the second hole-transport layer was changed to 50 nm, and the first light-emitting layer and the second light-emitting layer were each formed by co-evaporation of 8-(p-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (xii) above, 9-(2-naphthyl)-9′-phenyl-3,3′-bi-9H-carbazole (abbreviation: βNCCP) represented by Structural Formula (xiii) above, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) represented by Structural Formula (xiv) above such that the weight ratio of 8mpTP-4mDBtPBfpm to βNCCP to Ir(5mppy-d₃)₂(mbfpypy-d₃) was 0.5:0.5:0.1.

### (Fabrication Method of Comparative Light-Emitting Device G2)

The comparative light-emitting device G2 was fabricated in a manner similar to that of the light-emitting device G2 except that 6BP-4Cz2PPm was used instead of TznP2N in the second electron-transport layer and the first light-emitting layer and the second light-emitting layer were each formed by co-evaporation of 9-(4,6-diphenyl-1,3,5-triazin-2-yl)-9′-phenyl-9H,9′H-3,3′-bicarbazole (abbreviation: PCCzTzn) represented by Structural Formula (xv) above and Ir(5mppy-d₃)₂(mbfpypy-d₃) such that the weight ratio of PCCzTzn to Ir(5mppy-d₃)₂(mbfpypy-d₃) was 1:0.1.

### (Fabrication Method of Light-Emitting Device B2)

The light-emitting device B2 was fabricated in a manner similar to that of the light-emitting device R2 except that the thickness of the first hole-transport layer was changed to 45 nm, the thickness of the second hole-transport layer was changed to 45 nm, and the first light-emitting layer and the second light-emitting layer were each formed to a thickness of 25 nm by co-evaporation of 9-(1-naphthyl)-10-[4-(2-naphthyl)phenyl]anthracene (abbreviation: αN-βNPAnth) represented by Structural Formula (xvi) above and N,N′-diphenyl-N,N′-bis(9-phenyl-9H-carbazol-2-yl) naphtho[2,3-b;6,7-b′]bisbenzofuran-3,10-diamine (abbreviation: 3,10PCA2Nbf(IV)-02) represented by Structural Formula (xvii) above such that the weight ratio of αN-βNPAnth to 3,10PCA2Nbf(IV)-02 was 1:0.015.

### (Fabrication Method of Comparative Light-Emitting Device B2)

The comparative light-emitting device B2 was fabricated in a manner similar to that of the light-emitting device B2 except that 6BP-4Cz2PPm was used instead of TznP2N in the second electron-transport layer.

The structures of the light-emitting device R2, the light-emitting device G2, the light-emitting device B2, the comparative light-emitting device R2, the comparative light-emitting device G2, and the comparative light-emitting device B2 are shown below.

TABLE 11

| | | | | Comparative |
|---|---|---|---|---|
| | | Thickness | Light-emitting | light-emitting |
| | | (nm) | device R2 | device R2 |
| Cap layer | | 70 | DBT3P-II | |
| Second electrode | 2 | 15 | Ag:Mg (1:0.1) | |
| | 1 | 1 | Liq | |
| Second electron-transport | b | 25 | TznP2N:Liq | 6BP-4Cz2PPm:Liq |
| layer | | | (1:1) | (1:1) |

| | | |
|---|---|---|
| a | 10 | mFBPTzn |

| Second light-emitting layer | | 40 | 11mDBtBPPnfpr:PCBBiF:OCPG-006 |
|---|---|---|---|
| | | | (0.7:0.3:0.05) |
| Second hole-transport layer | | 65 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | | 10 | mPCCzPTzn-02 |
|---|---|---|---|
| First light-emitting layer | | 40 | 11mDBtBPPnfpr:PCBBiF:OCPG-006 |
| | | | (0.7:0.3:0.05) |
| First hole-transport layer | | 150 | oFBiSF(2) |
| Hole-injection layer | | 10 | oFBiSF(2):OCHD-003 (1:0.03) |
| First electrode | 2 | 85 | ITSO |
| | 1 | 100 | Ag |

TABLE 12

| | | | | Comparative |
|---|---|---|---|---|
| | | Thickness | Light-emitting | light-emitting |
| | | (nm) | device G2 | device G2 |
| Cap layer | | 70 | DBT3P-II | |
| Second electrode | 2 | 15 | Ag:Mg (1:0.1) | |
| | 1 | 1 | Liq | |
| Second electron-transport | b | 25 | TznP2N:Liq | 6BP-4Cz2PPm:Liq |
| layer | | | (1:1) | (1:1) |

| | | |
|---|---|---|
| a | 10 | mFBPTzn |

| Second light-emitting layer | | 40 | *2 |
|---|---|---|---|
| Second hole-transport layer | | 50 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | | 10 | mPCCzPTzn-02 |
|---|---|---|---|
| First light-emitting layer | | 40 | *2 |
| First hole-transport layer | | 80 | oFBiSF(2) |
| Hole-injection layer | | 10 | oFBiSF(2):OCHD-003 (1:0.03) |
| First electrode | 2 | 85 | ITSO |
| | 1 | 100 | Ag |

TABLE 13

| | *2 |
|---|---|
| Light-emitting | 8mpTP-4mDBtPBfpm:βNCCP:Ir(5mppy-d₃)₂(mbfpypy-d₃) |
| device G2 | (0.5:0.5:0.1) |
| Comparative light- | PCCzTzn:Ir(5mppy-d₃)₂(mbfpypy-d₃) |
| emitting device G2 | (1:0.1) |

TABLE 14

| | | | | Comparative |
|---|---|---|---|---|
| | | Thickness | Light-emitting | light-emitting |
| | | (nm) | device B2 | device B2 |
| Cap layer | | 70 | DBT3P-II | |
| Second electrode | 2 | 15 | Ag:Mg (1:0.1) | |
| | 1 | 1 | Liq | |
| Second electron- | b | 25 | TznP2N:Liq | 6BP-4Cz2PPm:Liq |
| | | | (1:1) | (1:1) |

| | | | |
|---|---|---|---|
| transport layer | a | 10 | mFBPTzn |

| Second light-emitting layer | | 25 | αN-βNPAnth:3,10PCA2Nbf(IV)-02 |
|---|---|---|---|
| | | | (1:0.015) |
| Second hole-transport layer | | 45 | oFBiSF(2) |
| Intermediate | Second layer | 10 | oFBiSF(2):OCHD-003 (1:0.15) |
| layer | Third layer | 2 | CuPc |
| | First layer | 5 | mPPhen2P:Li₂O (1:0.02) |

| First electron-transport layer | | 10 | mPCCzPTzn-02 |
|---|---|---|---|
| First light-emitting layer | | 25 | αN-βNPAnth:3,10PCA2Nbf(IV)-02 |
| | | | (1:0.015) |
| First hole-transport layer | | 45 | oFBiSF(2) |
| Hole-injection layer | | 10 | oFBiSF(2):OCHD-003 (1:0.03) |
| First electrode | 2 | 85 | ITSO |
| | 1 | 100 | Ag |

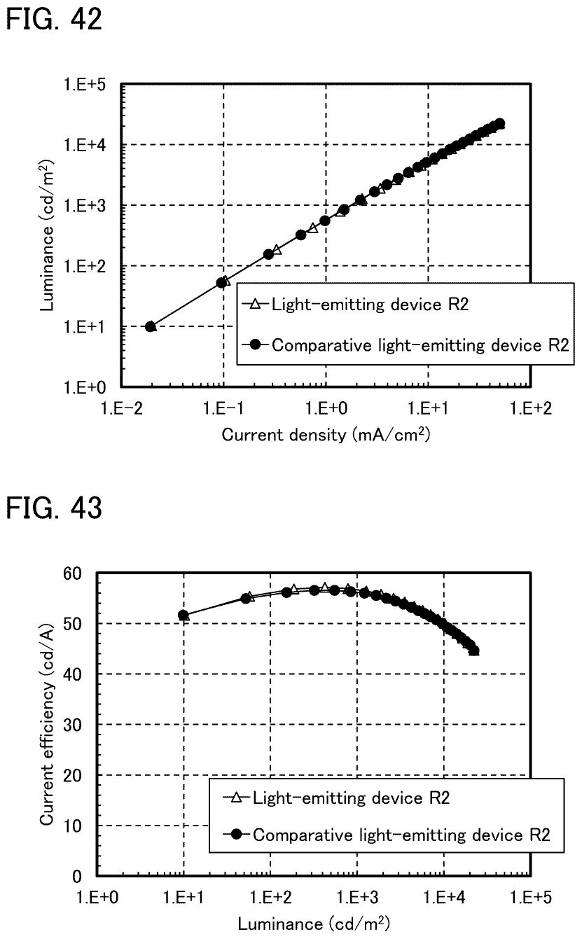

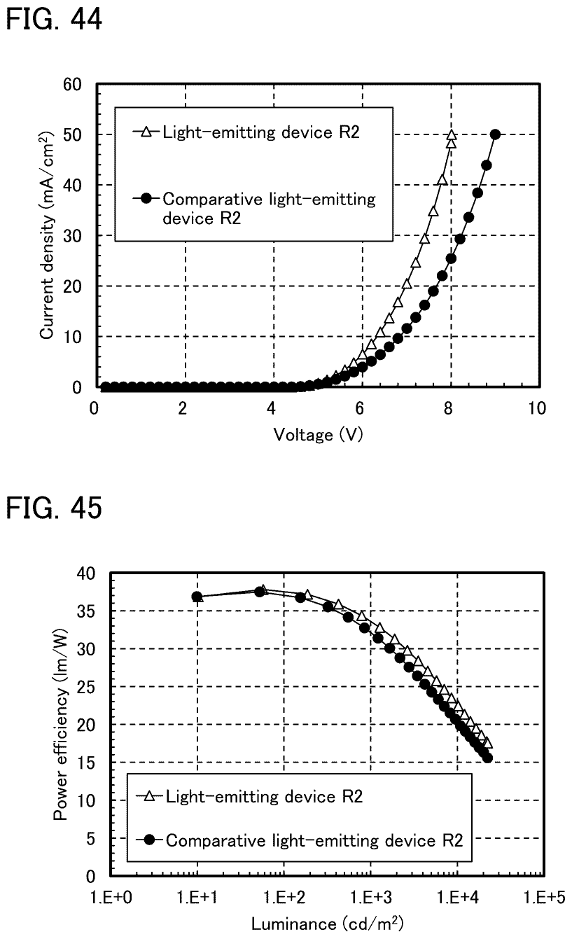

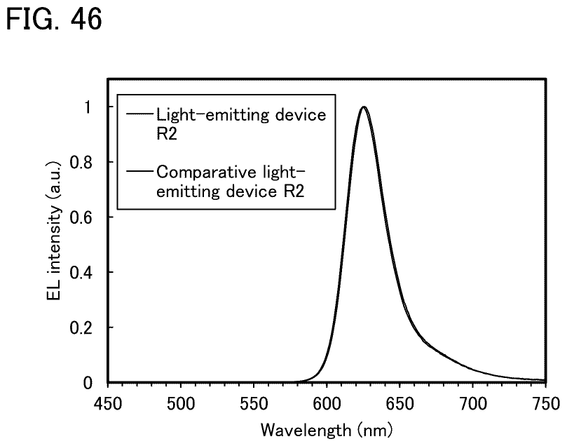

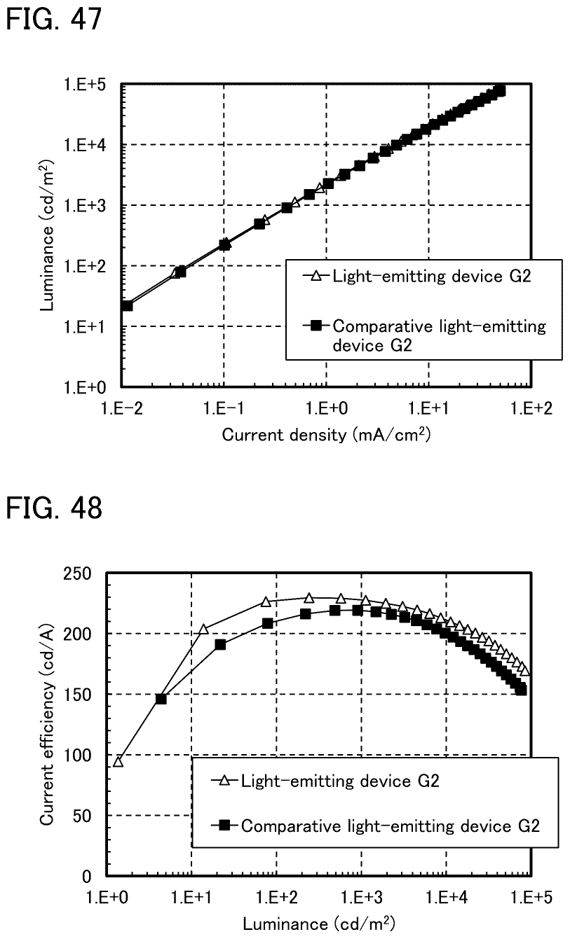

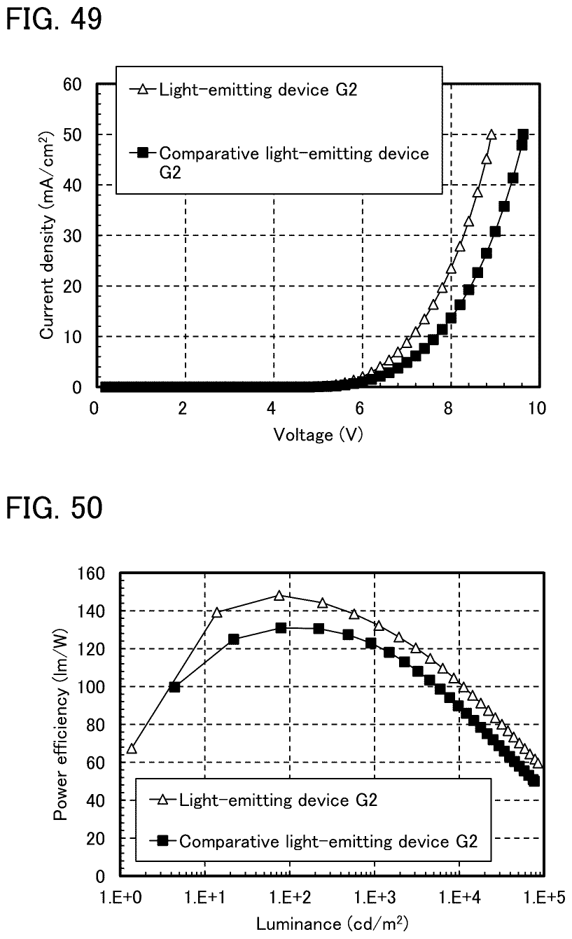

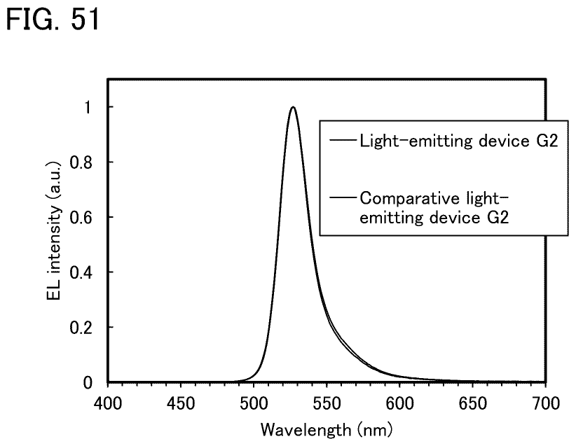

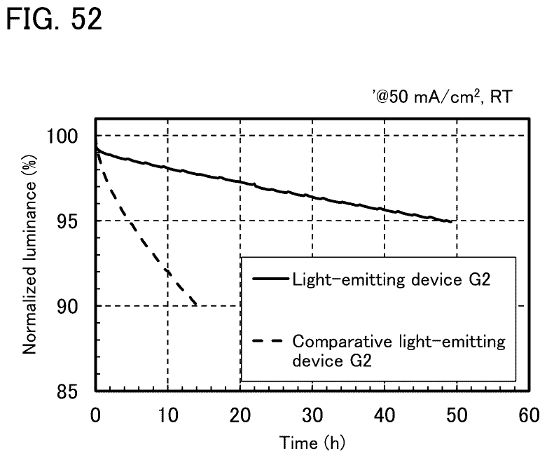

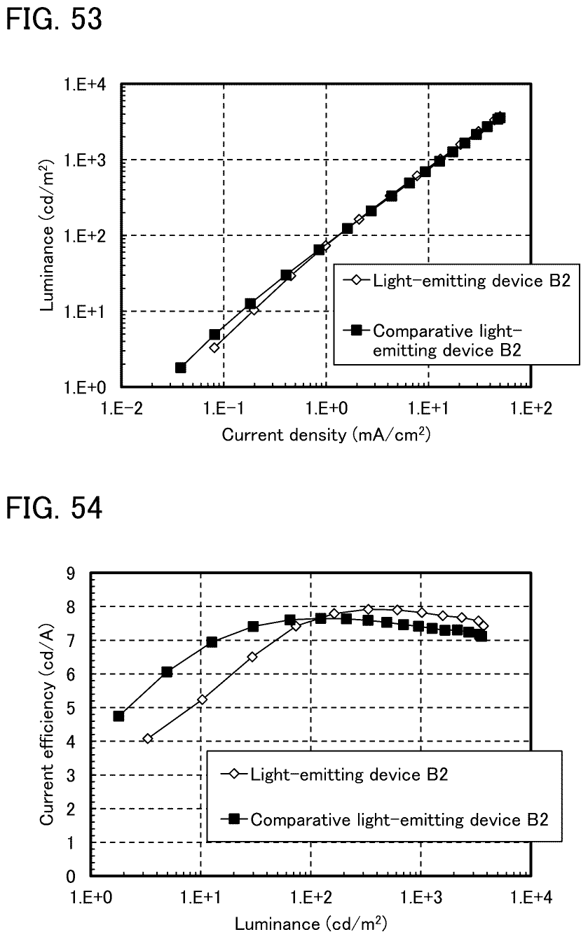

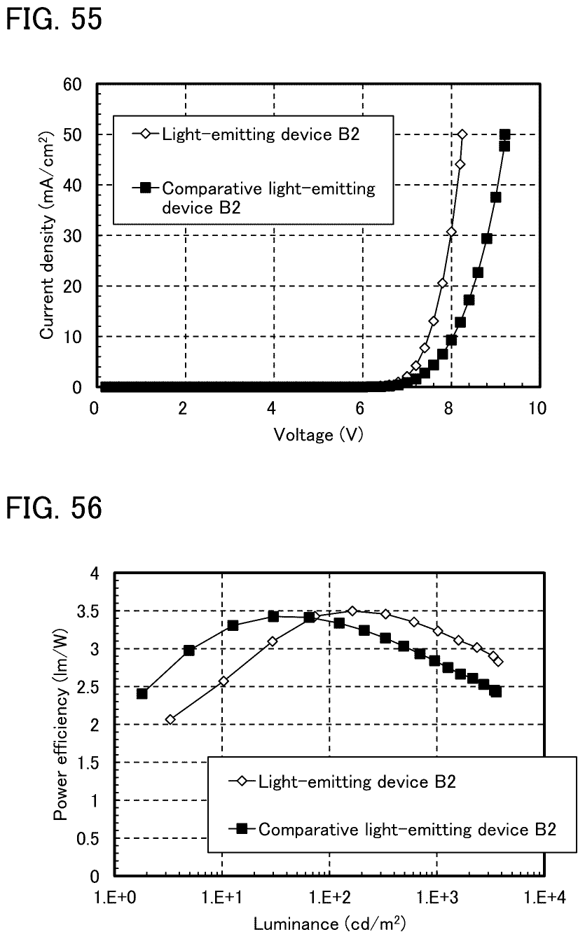

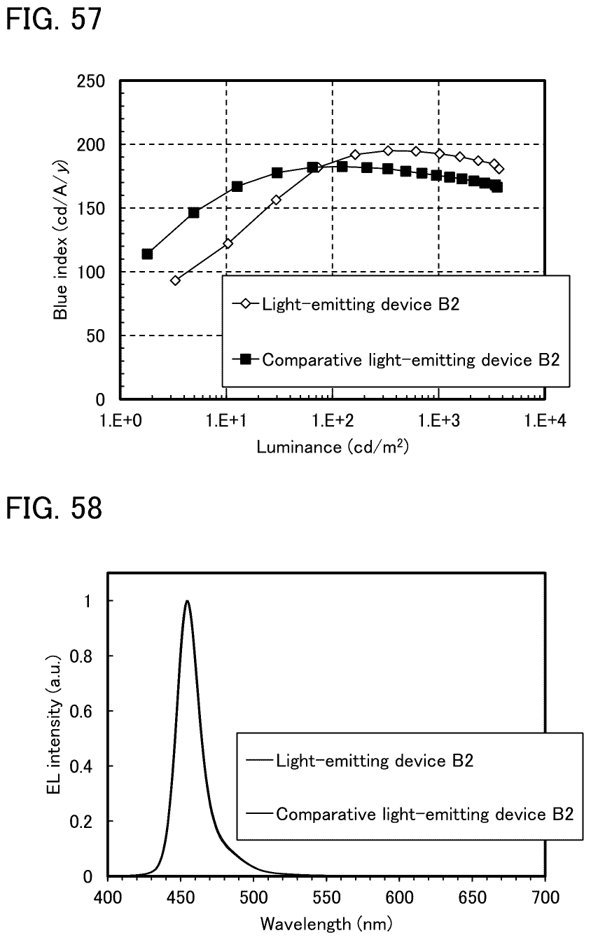

FIG. 42, FIG. 43, FIG. 44, FIG. 45, and FIG. 46 respectively show the luminance-current density characteristics, current efficiency-luminance characteristics, current density-voltage characteristics, power efficiency-luminance characteristics, and electroluminescence spectra of the light-emitting device R2 and the comparative light-emitting device R2. FIG. 47, FIG. 48, FIG. 49, FIG. 50, FIG. 51, and FIG. 52 respectively show the luminance-current density characteristics, current efficiency-luminance characteristics, current density-voltage characteristics, power efficiency-luminance characteristics, electroluminescence spectra, and time dependence of normalized luminance of the light-emitting device G2 and the comparative light-emitting device G2. FIG. 53, FIG. 54, FIG. 55, FIG. 56, FIG. 57, and FIG. 58 respectively show the luminance-current density characteristics, current efficiency-luminance characteristics, current density-voltage characteristics, power efficiency-luminance characteristics, blue index-luminance characteristics, and electroluminescence spectra of the light-emitting device B2 and the comparative light-emitting device B2.

Note that the blue index (BI) is a value obtained by dividing current efficiency (cd/A) by the y value of CIE chromaticity (x, y), and is one of the indicators of characteristics of blue light emission. As the y chromaticity value of blue light emission becomes smaller, the color purity thereof tends to be higher. Blue light emission having a small y chromaticity value and high color purity enables expression of blue colors with a wide range of chromaticity in a display. Using blue light emission with high color purity reduces the luminance of blue light emission necessary for a display to express white, leading to lower power consumption of the display. Thus, BI, which is current efficiency based on a y chromaticity value as one of the indicators of color purity of blue, is suitably used as a means for showing efficiency of blue light emission in some cases. The light-emitting device with higher BI can be regarded as a blue-light-emitting device having higher efficiency for a display.

Table 15 shows the main characteristics of the light-emitting device R2 and the comparative light-emitting device R2 at approximately 1000 cd/m². Table 16 shows those of the light-emitting device G2 and the comparative light-emitting device G2 at approximately 1000 cd/m². Table 17 shows those of the light-emitting device B2 and the comparative light-emitting device B2 at approximately 1000 cd/m². The luminance, CIE chromaticity, and electroluminescence spectra were measured at room temperature with a spectroradiometer (SR-ULIR, TOPCON TECHNOHOUSE CORPORATION).

TABLE 15

| | | | Current | | | Current | Power |
|---|---|---|---|---|---|---|---|
| | Voltage | Current | density | Chromaticity | Chromaticity | efficiency | efficiency |
| | (V) | (mA) | (mA/m²) | x | y | (cd/A) | (lm/W) |
| Light-emitting | 5.20 | 0.06 | 1.4 | 0.69 | 0.31 | 56.9 | 34.4 |
| device R2 | | | | | | | |
| Comparative | 5.40 | 0.06 | 1.5 | 0.69 | 0.31 | 56.3 | 32.7 |
| light-emitting | | | | | | | |
| device R2 | | | | | | | |

FIGS. 42 to 46 and Table 15 reveal that red light emission with an electroluminescence spectrum peak wavelength of 625 nm can be obtained from both the light-emitting device R2 and the comparative light-emitting device R2. Although both the light-emitting device R2 and the comparative light-emitting device R2 have high current efficiency, FIG. 44 shows that the light-emitting device R2 has a lower driving voltage and more favorable characteristics than the comparative light-emitting device R2. This indicates that the light-emitting device R2 of one embodiment of the present invention is a tandem light-emitting device with favorable characteristics.

TABLE 16

| | | | Current | | | Current | Power |
|---|---|---|---|---|---|---|---|
| | Voltage | Current | density | Chromaticity | Chromaticity | efficiency | efficiency |
| | (V) | (mA) | (mA/m²) | x | y | (cd/A) | (lm/W) |
| Light-emitting | 5.40 | 0.02 | 0.5 | 0.23 | 0.73 | 227.4 | 132.3 |
| device G2 | | | | | | | |
| Comparative | 5.60 | 0.02 | 0.4 | 0.22 | 0.74 | 219.2 | 122.9 |
| light-emitting | | | | | | | |
| device G2 | | | | | | | |

FIGS. 47 to 51 and Table 16 reveal that green light emission with an electroluminescence spectrum peak wavelength of 527 nm can be obtained from both the light-emitting device G2 and the comparative light-emitting device G2. Although both the light-emitting device G2 and the comparative light-emitting device G2 have high current efficiency, the light-emitting device G2 has higher current efficiency. It was also found that the light-emitting device G2 has a lower driving voltage and lower power consumption than the comparative light-emitting device G2 and have favorable characteristics. This indicates that the light-emitting device G2 of one embodiment of the present invention is a tandem light-emitting device with favorable characteristics.

FIG. 52 shows the time-dependence of normalized luminance of the light-emitting device G2 and the comparative light-emitting device G2 at a current density of 50 mA/cm².

FIG. 52 shows that the light-emitting device G2 of one embodiment of the present invention has lower time dependence of normalized luminance than the comparative light-emitting device G2 and has high reliability.

FIG. 33 shows measured PL spectra of a film formed by evaporation of 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), a film formed by evaporation of 9-(2-naphthyl)-9′-phenyl-3,3′-bi-9H-carbazole (abbreviation: βNCCP), and a film (mixed film) formed by co-evaporation of 8mpTP-4mDBtPBfpm and βNCCP such that the weight ratio of 8mpTP-4mDBtPBfpm to βNCCP was 1:1. As shown in the graph, the emission spectrum of the co-evaporation film is on a longer wavelength side than the emission spectrum of each organic compound, which indicates that 8mpTP-4mDBtPBfpm and βNCCP form an exciplex in combination.

FIG. 34 shows a PL spectrum of a film (mixed film) formed by co-evaporation of 8mpTP-4mDBtPBfpm and βNCCP such that the weight ratio of 8mpTP-4mDBtPBfpm to βNCCP was 1:1 (an emission spectrum of an exciplex) and an absorption spectrum and a PL spectrum of Ir(5mppy-d₃)₂(mbfpypy-d₃), which is the emission center substance. As can be seen from FIG. 34, the emission edge (442 nm) on a shorter wavelength side of the PL spectrum of the exciplex of 8mpTP-4mDBtPBfpm and βNCCP is positioned at a shorter wavelength than the absorption edge (526 nm) on a longer wavelength side of the absorption spectrum of Ir(5mppy-d₃)₂(mbfpypy-d₃). Since the PL spectrum of the exciplex of 8mpTP-4mDBtPBfpm and βNCCP and the absorption edge of Ir(5mppy-d₃)₂(mbfpypy-d₃) have such a positional relation, excitation energy can be efficiently transferred to Ir(5mppy-d₃)₂(mbfpypy-d₃) in the light-emitting device G1.

Alternatively, the peak wavelength (500 nm) of the PL spectrum of the exciplex formed by 8mpTP-4mDBtPBfpm and βNCCP is shorter than the peak wavelength (528 nm) of the PL spectrum of Ir(5mppy-d₃)₂(mbfpypy-d₃). The difference between the peak wavelength of the PL spectrum of the exciplex and the peak wavelength of the PL spectrum of Ir(5mppy-d₃)₂(mbfpypy-d₃) is less than or equal to 30 nm. Such a relationship between the peak wavelength of the PL spectrum of the exciplex and the peak wavelength of the PL spectrum of Ir(5mppy-d₃)₂(mbfpypy-d₃) enables efficient energy transfer.

Alternatively, the difference between the peak wavelength (500 nm) of the PL spectrum of the exciplex formed by 8mpTP-4mDBtPBfpm and βNCCP and the wavelength (526 nm) of the absorption edge on a longer wavelength side of the absorption spectrum of Ir(5mppy-d₃)₂(mbfpypy-d₃) is 26 nm, which is less than or equal to 30 nm. Such a relationship between the peak wavelength of the PL spectrum of the exciplex and the wavelength of the absorption edge on a longer wavelength side of the absorption spectrum of Ir(5mppy-d₃)₂(mbfpypy-d₃) enables efficient energy transfer.

Note that the PL spectrum of the exciplex was measured using a film formed by co-evaporation of 8mpTP-4mDBtPBfpm and βNCCP. The PL spectrum or the absorption spectrum of Ir(5mppy-d₃)₂(mbfpypy-d₃) was measured using a solution thereof in which chloroform was used as a solvent.

The absorption edge of the absorption spectrum was determined as the intersection between a tangent and the horizontal axis or the baseline. The tangent was drawn at a point at which the slope on a longer wavelength side of the longest-wavelength peak (or the longest-wavelength shoulder peak) of the absorption spectrum has the maximum absolute value. The emission edge on a shorter wavelength side of the PL spectrum was determined as the intersection between a tangent and the horizontal axis or the baseline. The tangent was drawn at a point at which the slope on a shorter wavelength side of the shortest-wavelength peak (or the shortest-wavelength shoulder peak) of the PL spectrum has the maximum absolute value. FIG. 35 shows an example of determining the absorption edge of the absorption spectrum of Ir(5mppy-d₃)₂(mbfpypy-d₃). In this manner, the absorption edge of Ir(5mppy-d₃)₂(mbfpypy-d₃) can be determined to be at 526 nm.

The HOMO level of βNCCP as the organic compound having a hole-transport property was −5.62 eV; the HOMO level of 8mpTP-4mDBtPBfpm as the organic compound having an electron-transport property was −6.2 eV (reference value); the LUMO level of βNCCP as the organic compound having a hole-transport property was −2.21 eV; and the LUMO level of 8mpTP-4mDBtPBfpm as the organic compound having an electron-transport property was −3.01 eV. Since the HOMO level of the organic compound having a hole-transport property is higher than or equal to the HOMO level of the organic compound having an electron-transport property and the LUMO level of the organic compound having a hole-transport property is higher than or equal to the LUMO level of the organic compound having an electron-transport property, the light-emitting device G1 was found to have a structure in which an exciplex can be formed more efficiently.

The HOMO level and the LUMO level of Ir(5mppy-d₃)₂(mbfpypy-d₃) were −5.32 eV and −2.39 eV, respectively. The energy difference between the HOMO level and the LUMO level of the exciplex was 2.61 eV, which corresponds to the energy difference between the HOMO level (−5.62 eV) of βNCCP as the organic compound having a hole-transport property and the LUMO level (−3.01 eV) of 8mpTP-4mDBtPBfpm as the organic compound having an electron-transport property. The energy difference (2.93 eV) between the HOMO level (−5.32 eV) and the LUMO level (−2.39 eV) of Ir(5mppy-d₃)₂(mbfpypy-d₃), which corresponds to the band gap thereof, was found to be larger than the energy difference between the HOMO level and the LUMO level of the exciplex.

The values of the HOMO level and the LUMO level were calculated in a manner similar to that in Example 1.

TABLE 17

| | | | Current | | | Current | Power | |
|---|---|---|---|---|---|---|---|---|
| | Voltage | Current | density | Chromaticity | Chromaticity | efficiency | efficiency | BI |
| | (V) | (mA) | (mA/m²) | x | y | (cd/A) | (lm/W) | (cd/A/y) |
| Light-emitting | 7.60 | 0.52 | 13.1 | 0.15 | 0.04 | 7.8 | 3.2 | 192.6 |
| device B2 | | | | | | | | |
| Comparative | 8.20 | 0.51 | 12.8 | 0.15 | 0.04 | 7.4 | 2.8 | 175.7 |
| light-emitting | | | | | | | | |
| device B2 | | | | | | | | |

FIGS. 53 to 58 and Table 17 reveal that blue light emission with an electroluminescence spectrum peak wavelength of approximately 456 nm can be obtained from both the light-emitting device B2 and the comparative light-emitting device B2. Although both the light-emitting device B2 and the comparative light-emitting device B2 have high current efficiency, the light-emitting device B2 has lower power consumption and more favorable characteristics because of its driving voltage lower than that of the comparative light-emitting device B2. It was also found that the light-emitting device B2 has a high blue index. This indicates that the light-emitting device B2 of one embodiment of the present invention is a tandem light-emitting device with favorable characteristics. In addition, the light-emitting device B2 has especially favorable characteristics at a practical luminance of and above 500 cd/cm².

Here, the second electron-transport layers of the light-emitting device R2, the light-emitting device G2, and the light-emitting device B2 include the same material (the first organic compound having a triazine skeleton). Thus, the light-emitting devices of different emission colors of embodiments of the present invention can each have favorable characteristics even when the second electron-transport layers of the light-emitting devices are made of the same material.

Next, a display device of this example including the light-emitting device R2, the light-emitting device G2, and the light-emitting device B2 respectively in red, green, and blue subpixels and a display device of a comparative example including the comparative light-emitting device R2, the comparative light-emitting device G2, and the comparative light-emitting device B2 respectively in red, green, and blue subpixels were assumed, and the power consumption of their display portions (except for the power consumption of a driving transistor, a driving circuit, and the like) was tentatively calculated. Note that each of the light-emitting devices assumed to be used in the display devices is a tandem light-emitting device, and the same emission center substance is used in a plurality of light-emitting layers in each of the light-emitting devices. Thus, both of the display devices employ a side-by-side patterning method.

The conditions of the display devices assumed for the tentative calculation are as follows.

TABLE 18

| | | |
|---|---|---|
| Panel size | 5 | inches (16:9) |
| Panel area | 68.9 | cm² |

| | | | |
|---|---|---|---|
| Aperture ratio | 30% | Red | 10% |
| | | Green | 10% |
| | | Blue | 10% |

| | | |
|---|---|---|
| Effective luminance | 1000 | cd/m² in displaying white on the entire screen |

| | |
|---|---|
| Circularly polarizing plate | Not used |

First, in each of the display devices under the above-described conditions, the luminance (effective luminance) of the light-emitting devices of RGB to obtain 1000 cd/m² emission of white light with CIE 1931 chromaticity coordinates (x, y)=(0.31, 0.33) when the display device is made to emit white light from the entire screen was calculated.

Next, the luminance (intrinsic luminance) required to obtain the calculated effective luminance of the light-emitting devices of RGB was calculated in consideration of the aperture ratios. The intrinsic luminance is the luminance at which each light-emitting device actually emits light in order to obtain the effective luminance of 1000 cd/m² when the display device is made to emit white light with CIE 1931 chromaticity coordinates (x, y)=(0.31, 0.33) from the entire screen. Since the aperture ratio of the whole display device subjected to the tentative calculation is 30% and the aperture ratio per emission color is 10%, the intrinsic luminance is approximately ten times the effective luminance.

From the measurement results of the light-emitting devices described above and the intrinsic luminance, the current density and voltage for making each light-emitting device emit light at the intrinsic luminance can be obtained. In other words, in each of the display devices under the above-described conditions, the current density and voltage of each light-emitting device to obtain 1000 cd/m² luminance emission of white light with CIE 1931 chromaticity coordinates (x, y)=(0.31, 0.33) when the display device is made to emit white light from the entire screen can be obtained.

The power consumption is calculated by multiplying the amount of current by the voltage. The amount of current is calculated by multiplying the current density, the panel area, and the aperture ratio. The display devices subjected to the tentative calculation each have a diagonal size of 5 inches, an aspect ratio of 16:9, a panel area of 68.9 cm², and an aperture ratio of the light-emitting device of each color of 10%, and the amount of current can be calculated by multiplying the current density calculated in the previous paragraph by these values. Furthermore, power consumption of the light-emitting device of each emission color can be calculated by multiplying the amount of current by the voltage obtained in the previous paragraph. By calculating and summing up the power consumptions of the light-emitting devices of RGB, the total power consumption of the display portion of the display device (except for the power consumption of the driving transistor, the driving circuit, and the like) can be obtained.

Table 19 shows the calculated power consumption of the display device of this example assumed to use the light-emitting device R2, the light-emitting device G2, and the light-emitting device B2, and Table 20 shows the calculated power consumption of the display device of the comparative example assumed to use the comparative light-emitting device R2, the comparative light-emitting device G2, and the comparative light-emitting device B2.

TABLE 19
This example

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/m²) | (mA) | (V) | (mW) |
| Red | 0.69 | 0.31 | 244 | 2444 | 55.2 | 4.4 | 30.5 | 5.75 | 175.5 |
| Green | 0.22 | 0.73 | 703 | 7033 | 215.4 | 3.3 | 22.5 | 6.26 | 140.8 |
| Blue | 0.15 | 0.04 | 52 | 523 | 7.9 | 6.6 | 45.6 | 7.34 | 334.4 |
| White on the | 0.31 | 0.33 | 1000 | — | 69.9 | — | 98.6 | — | 650.7 |
| entire screen | | | | | | | | | |

TABLE 20
Comparative example

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/m²) | (mA) | (V) | (mW) |
| Red | 0.69 | 0.31 | 248 | 2478 | 54.7 | 4.5 | 31.2 | 6.10 | 190.6 |
| Green | 0.22 | 0.74 | 698 | 6980 | 205.2 | 3.4 | 23.4 | 6.72 | 157.5 |
| Blue | 0.15 | 0.04 | 54 | 542 | 7.5 | 7.2 | 49.7 | 7.85 | 389.9 |
| White on the | 0.31 | 0.33 | 1000 | — | 66.0 | — | 104.4 | — | 738.1 |
| entire screen | | | | | | | | | |

Table 19 and Table 20 show that the display device of this example has higher current efficiency in white light emission and a lower driving voltage than the display device of the comparative example. Moreover, the power consumption of the display device of this example is lower than that of the display device of the comparative example.

Thus, the display device including the light-emitting devices of embodiments of the present invention, in each of which at least one of the light-emitting layers includes the emission center substance, the first host material, and the second host material and the first host material and the second host material are organic compounds and form an exciplex in combination, can have low power consumption because the light-emitting devices have high efficiency, high reliability, and a low driving voltage. It was found that the display device including the tandem light-emitting devices in each of which the second electron-transport layer includes the first organic compound having a triazine skeleton, the intermediate layer includes the mixed layer of the second organic compound having a phenanthroline skeleton and lithium or a lithium compound, and the difference in maximum peak wavelength between the emission spectra of light emitted from the light-emitting layers is less than or equal to 30 nm can have favorable characteristics with lower power consumption. In addition, since the tandem light-emitting devices are fabricated by a side-by-side patterning method (i.e., the light-emitting layer included in the tandem light-emitting device is separated from a light-emitting layer included in at least one adjacent light-emitting device or is different from a light-emitting layer included in at least one adjacent light-emitting device, the emission color of the tandem light-emitting device is different from the emission color of at least one adjacent light-emitting device, or the emission center substance included in the light-emitting layer of the tandem light-emitting device has a structure different from that of an emission center substance included in a light-emitting layer of at least one adjacent light-emitting device), the tandem light-emitting devices can have extremely high current efficiency and can thus have higher power efficiency and higher energy efficiency.

The structure in which the second electron-transport layer includes the first organic compound having a triazine skeleton and the intermediate layer includes the mixed layer of the second organic compound having a phenanthroline skeleton and lithium or a lithium compound is common between the red-, green-, and blue-light-emitting devices. When the materials of the functional layers are common between the light-emitting devices of different colors, the raw material procurement cost can be reduced and the convenience in manufacturing can be improved. In the display device of one embodiment of the present invention, owing to the above structures of the second electron-transport layer and the intermediate layer, the light-emitting devices of all emission colors can have favorable characteristics even when the materials of the functional layers other than the light-emitting layer are common between the light-emitting devices.

### Example 3

Specific fabrication methods and characteristics of a light-emitting device R3, a light-emitting device G3, and a light-emitting device B3, which are light-emitting devices of embodiments of the present invention, are described in this example. Structural formulae of main compounds used in this example are shown below.

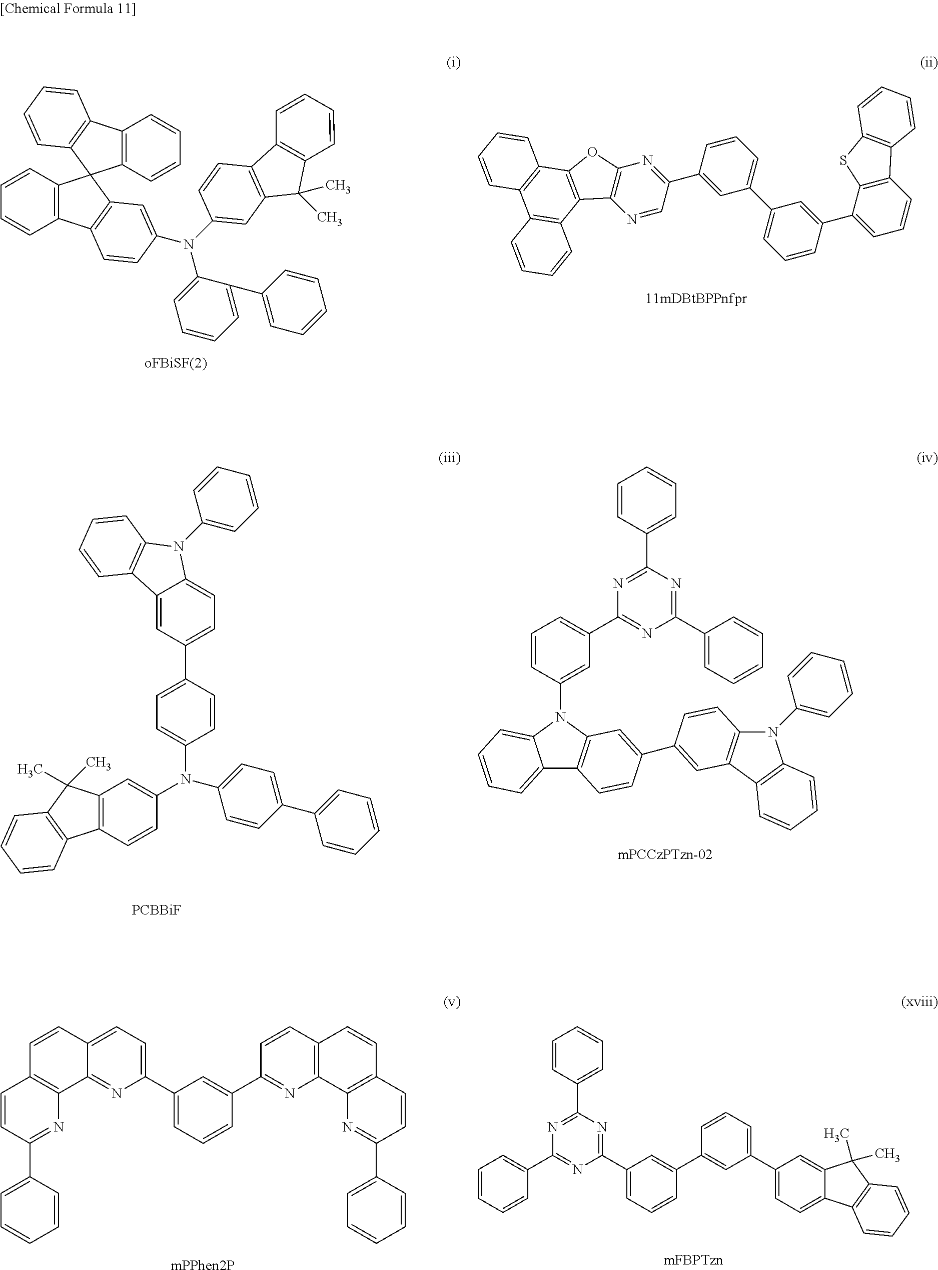

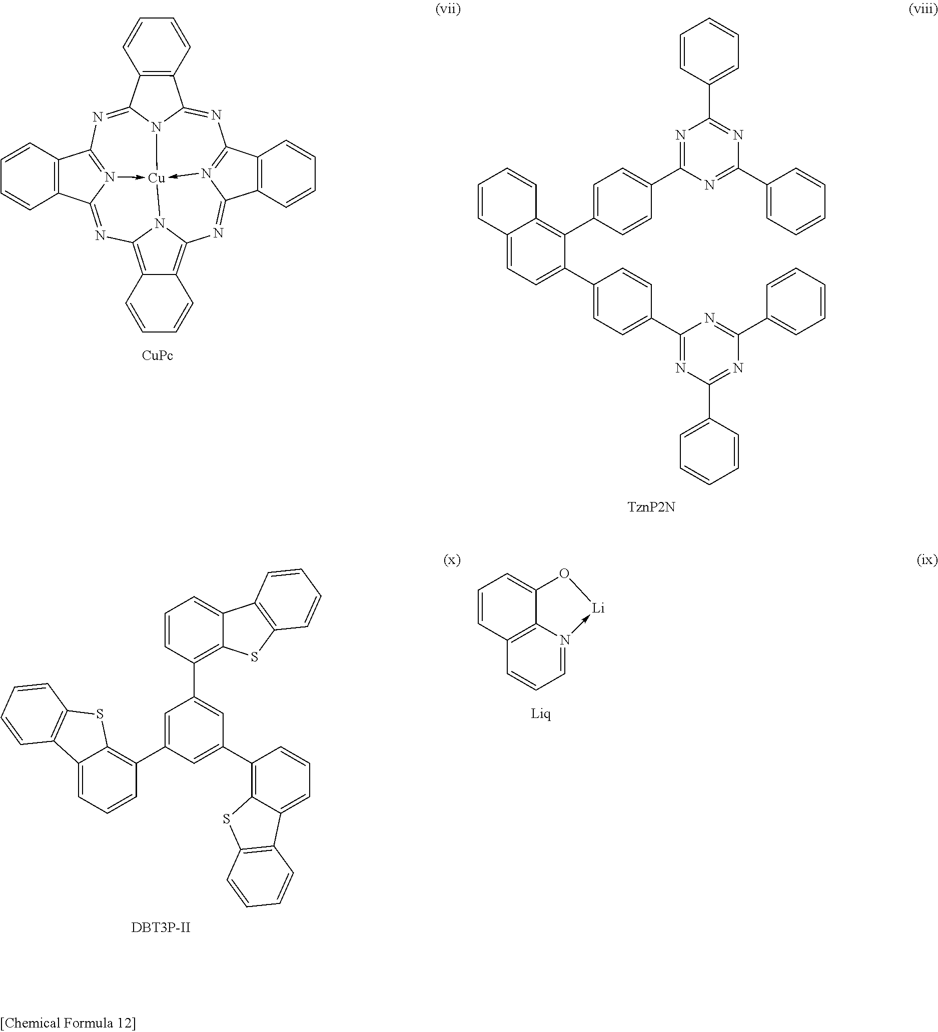

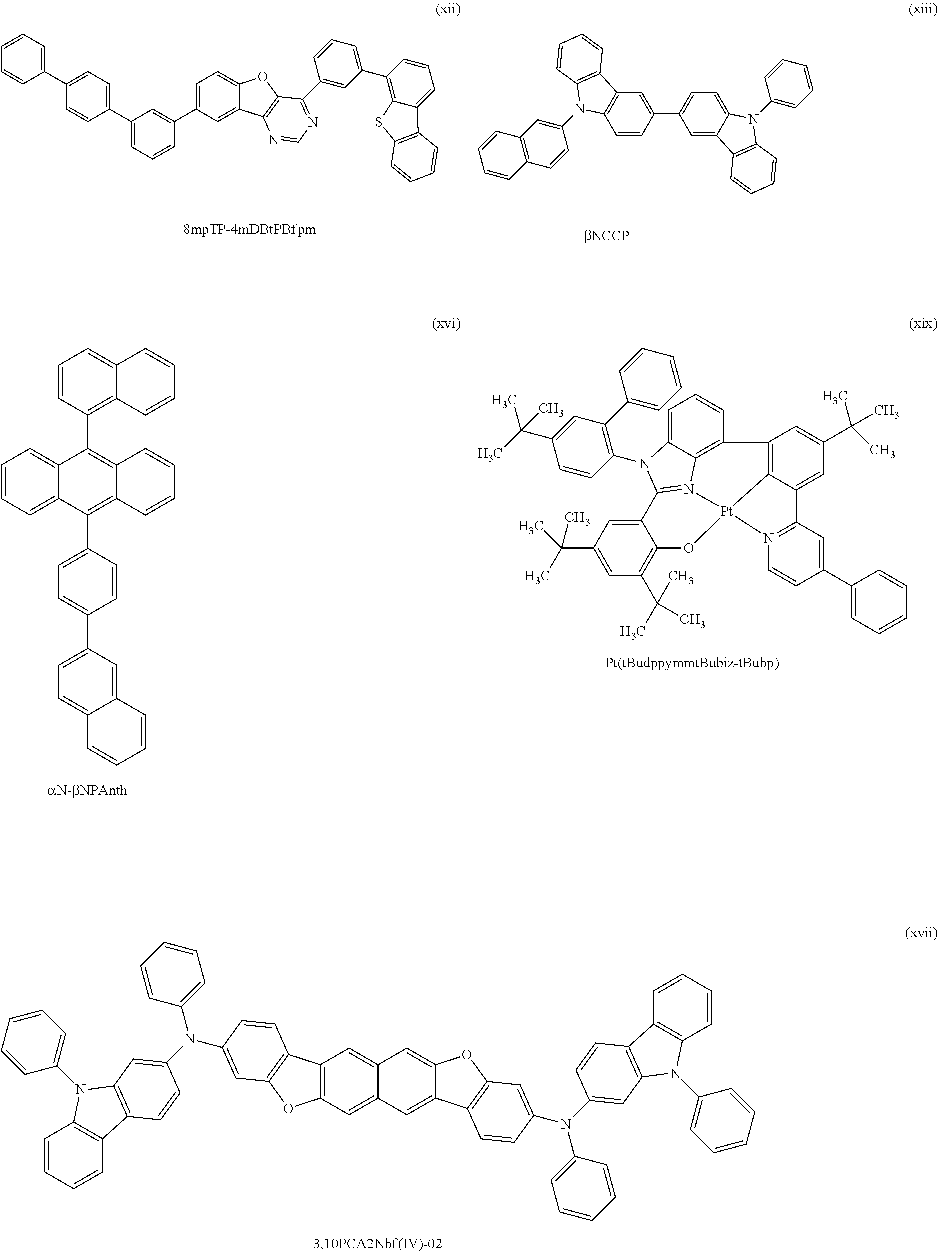

### (Fabrication Method of Light-Emitting Device R3)

First, 100-nm-thick silver (Ag) and 85-nm-thick indium tin oxide containing silicon oxide (ITSO) were stacked over a glass substrate sequentially from the substrate side by a sputtering method as a reflective electrode and a transparent electrode, respectively, so that the first electrode 101 with a size of 2 mm×2 mm was formed. Note that the transparent electrode functions as an anode, and the transparent electrode and the reflective electrode are collectively regarded as the first electrode 101.

Next, in pretreatment for fabricating the light-emitting device over the substrate, the surface of the substrate was washed with water, and baking was performed at 200° C. for one hour.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was allowed to cool down for approximately 30 minutes.

Next, the substrate was fixed to a holder provided in the vacuum evaporation apparatus such that the surface on which the first electrode 101 was formed faced downward. Then, N-(biphenyl-2-yl)-N-(9,9-dimethylfluoren-2-yl)-9,9′-spirobi[9H-fluoren]-2-amine (abbreviation: oFBiSF(2)) represented by Structural Formula (i) above and a fluorine-containing material having an electron-acceptor property with a molecular weight of 672(OCHD-003) were deposited by co-evaporation over the first electrode 101 to a thickness of 10 nm such that the weight ratio of oFBiSF(2) to OCHD-003 was 1:0.03, whereby the hole-injection layer 111 was formed.

Over the hole-injection layer 111, oFBiSF(2) was deposited by evaporation to a thickness of 160 nm, so that the first hole-transport layer was formed.

Next, 11-[3′-(dibenzothiophen-4-yl)biphenyl-3-yl]phenanthro[9′,10′:4,5]furo[2,3-b]pyrazine (abbreviation: 11mDBtBPPnfpr) represented by Structural Formula (ii) above, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (iii) above, and a red phosphorescent material OCPG-006 were deposited by co-evaporation over the first hole-transport layer to a thickness of 40 nm such that the weight ratio of 11mDBtBPPnfpr to PCBBiF to OCPG-006 was 0.7:0.3:0.05, whereby the first light-emitting layer was formed.

After that, 9-[3-(4,6-diphenyl-1,3,5-triazin-2-yl)phenyl]-9′-phenyl-2,3′-bi-9H-carbazole (abbreviation: mPCCzPTzn-02) represented by Structural Formula (iv) above was deposited by evaporation to a thickness of 10 nm, so that the first electron-transport layer was formed.

After the first electron-transport layer was formed, 2,2′-(1,3-phenylene)bis(9-phenyl-1,10-phenanthroline) (abbreviation: mPPhen2P) represented by Structural Formula (v) above as the second organic compound having a phenanthroline skeleton and ytterbium (Yb) were deposited by co-evaporation to a thickness of 5 nm such that the weight ratio of mPPhen2P to Yb was 1:0.02, whereby the first layer was formed. Then, copper phthalocyanine (abbreviation: CuPc) represented by Structural Formula (vii) above was deposited by evaporation to a thickness of 2 nm, whereby the third layer was formed. Furthermore, oFBiSF(2) and OCHD-003 were deposited by co-evaporation to a thickness of 10 nm such that the weight ratio of oFBiSF(2) to OCHD-003 was 1:0.15, whereby the second layer was formed. Thus, the intermediate layer was formed.

Over the intermediate layer, oFBiSF(2) was deposited by evaporation to a thickness of 75 nm, so that the second hole-transport layer was formed.

Over the second hole-transport layer, 11mDBtBPPnfpr, PCBBiF, and OCPG-006 were deposited by co-evaporation to a thickness of 40 nm such that the weight ratio of 11mDBtBPPnfpr to PCBBiF to OCPG-006 was 0.7:0.3:0.05, whereby the second light-emitting layer was formed.

Subsequently, 2-[3′-(9,9-dimethyl-9H-fluoren-2-yl)biphenyl-3-yl]-4,6-diphenyl-1,3,5-triazine (abbreviation: mFBPTzn) represented by Structural Formula (xviii) above was deposited by evaporation to a thickness of 10 nm and then, 2,2′-[1,2-naphthalendiyldi(4,1-phenylene)]bis(4,6-diphenyl-1,3,5-triazine) (abbreviation: TznP2N) represented by Structural Formula (viii) above and 8-hydroxyquinolinato-lithium (abbreviation: Liq) represented by Structural Formula (ix) above were deposited by co-evaporation to a thickness of 25 nm such that the weight ratio of TznP2N to Liq was 1:1, whereby the second electron-transport layer was formed.

After that, lithium fluoride (LiF) and ytterbium (Yb) were deposited by co-evaporation to a thickness of 1.5 nm such that the volume ratio of LiF to Yb was 2:1, and then silver (Ag) and magnesium (Mg) were deposited by co-evaporation to a thickness of 15 nm such that the volume ratio of Ag to Mg was 1:0.1, whereby the second electrode 102 was formed. Over the second electrode 102, a film of 4,4′,4″-(benzene-1,3,5-triyl)tri(dibenzothiophene) (abbreviation: DBT3P-II) represented by Structural Formula (x) above was formed to a thickness of 70 nm as a cap layer to improve light extraction efficiency.

Next, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device R3 was fabricated.

### (Fabrication Method of Light-Emitting Device G3)

The light-emitting device G3 was fabricated in a manner similar to that of the light-emitting device R3 except that the thickness of the first hole-transport layer was changed to 90 nm, the thickness of the second hole-transport layer was changed to 65 nm, and the first light-emitting layer and the second light-emitting layer were each formed by co-evaporation of 8-(p-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (xii) above, 9-(2-naphthyl)-9′-phenyl-3,3′-bi-9H-carbazole (abbreviation: βNCCP) represented by Structural Formula (xiii) above, and (2-{1-(5-tert-butylbiphenyl-2-yl)-4-[3-tert-butyl-5-(4-phenyl-2-pyridinyl-κN)phenyl-κC⁶]-2-benzimidazolyl-κN³}-4,6-di-tert-butylphenolato-κO) platinum(II) (abbreviation: Pt(tBudppymmtBubiz-tBubp)) represented by Structural Formula (xix) above such that the weight ratio of 8mpTP-4mDBtPBfpm to βNCCP to Pt(tBudppymmtBubiz-tBubp) was 0.5:0.5:0.1.

### (Fabrication Method of Light-Emitting Device B3)

The light-emitting device B3 was fabricated in a manner similar to that of the light-emitting device R3 except that the thickness of the first hole-transport layer was changed to 50 nm, the thickness of the second hole-transport layer was changed to 55 nm, and the first light-emitting layer and the second light-emitting layer were each formed to a thickness of 25 nm by co-evaporation of 9-(1-naphthyl)-10-[4-(2-naphthyl)phenyl]anthracene (abbreviation: αN-βNPAnth) represented by Structural Formula (xvi) above and N,N′-diphenyl-N,N′-bis(9-phenyl-9H-carbazol-2-yl) naphtho[2,3-b;6,7-b′]bisbenzofuran-3,10-diamine (abbreviation: 3,10PCA2Nbf(IV)-02) represented by Structural Formula (xvii) above such that the weight ratio of αN-βNPAnth to 3,10PCA2Nbf(IV)-02 was 1:0.015.

The structures of the light-emitting devices R3, G3, and B3 are shown below.

TABLE 21

| | | | |
|---|---|---|---|
| Thickness | Light-emitting | Light-emitting | Light-emitting |
| (nm) | device R3 | device G3 | device B3 |

| Cap layer | | 70 | DBT3P-II |
|---|---|---|---|
| Second electrode | 2 | 15 | Ag:Mg (1:0.1) |
| | 1 | 1.5 | LIF:Yb (2:1) |
| Second electron- | b | 25 | TznP2N:Liq (1:1) |
| transport layer | a | 10 | mFBPTzn |

| | | |
|---|---|---|
| Second light-emitting layer | *6 | *7 |

| Second hole-transport layer | | *5 | oFBiSF(2) |
|---|---|---|---|
| Intermediate | Second layer | 10 | oFBiSF(2):OCHD-003 (1:0.15) |
| layer | Third layer | 2 | CuPc |
| | First layer | 5 | mPPhen2P:Yb (1:0.02) |

| First electron-transport layer | 10 | mPCCzPTzn-02 | |
|---|---|---|---|
| First light-emitting layer | *4 | | *7 |

| First hole-transport layer | | *3 | oFBiSF(2) |
|---|---|---|---|
| Hole-injection layer | | 10 | oFBiSF(2):OCHD-003 (1:0.03) |
| First electrode | 2 | 85 | ITSO |
| | 1 | 100 | Ag |

TABLE 22

| | *3 | *4 | *5 | *6 |
|---|---|---|---|---|
| Light-emitting | 160 | 40 | 75 | 40 |
| device R3 | | | | |
| Light-emitting | 90 | | 65 | |
| device G3 | | | | |
| Light-emitting | 50 | 25 | 55 | 25 |
| device B3 | | | | |

TABLE 23

| | *7 |
|---|---|
| Light-emitting | 11mDBtBPPnfpr:PCBBiF:OCPG-006 |
| device R3 | (0.7:0.3:0.05) |
| Light-emitting | 8mpTP-4mDBtPBfpm:βNCCP: Pt(tBudppymmtBubiz-tBubp) |
| device G3 | (0.5:0.5:0.1) |
| Light-emitting | αN-βNP Anth:3,10PCA2Nbf(IV)-02 |
| device B3 | (1:0.015) |

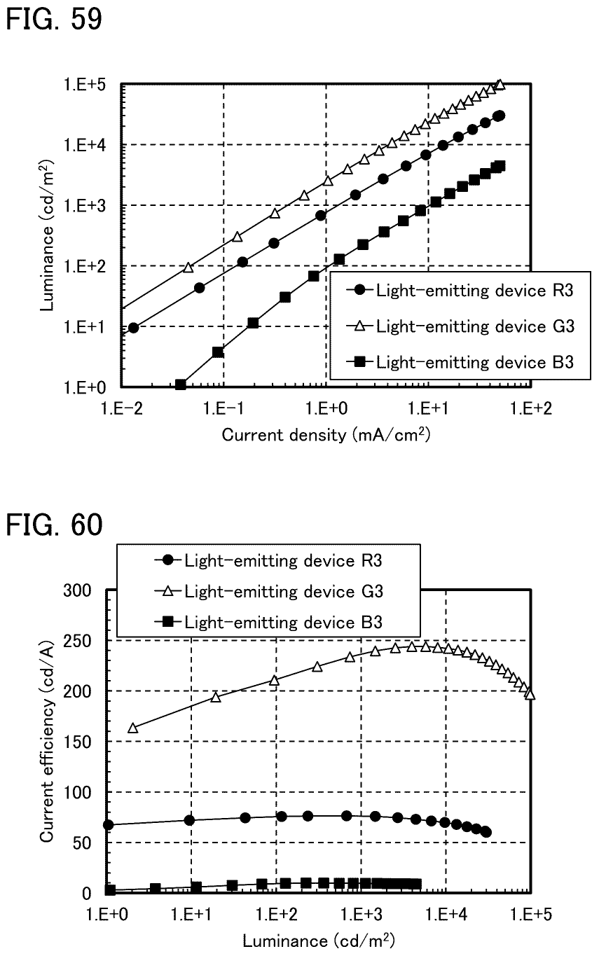

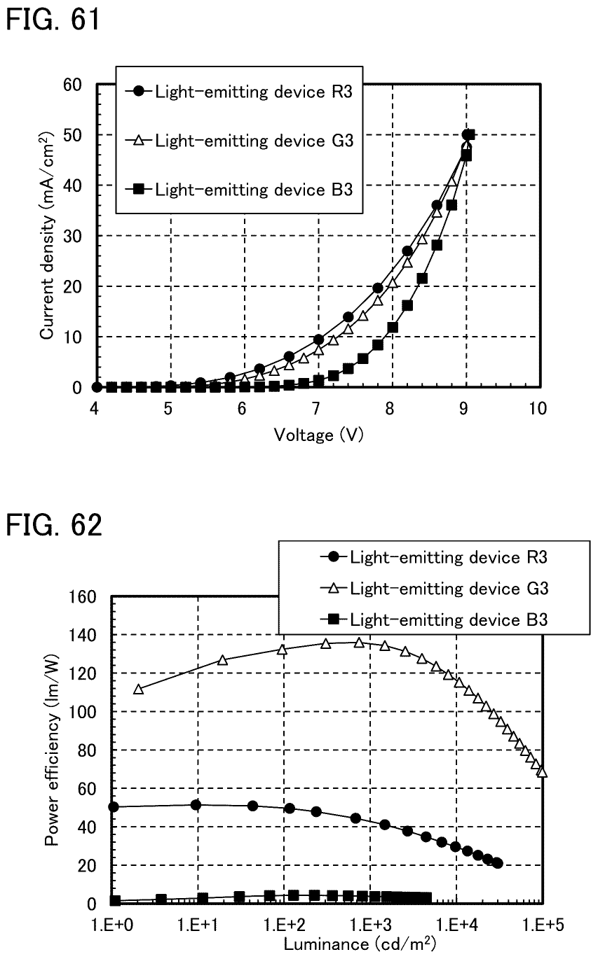

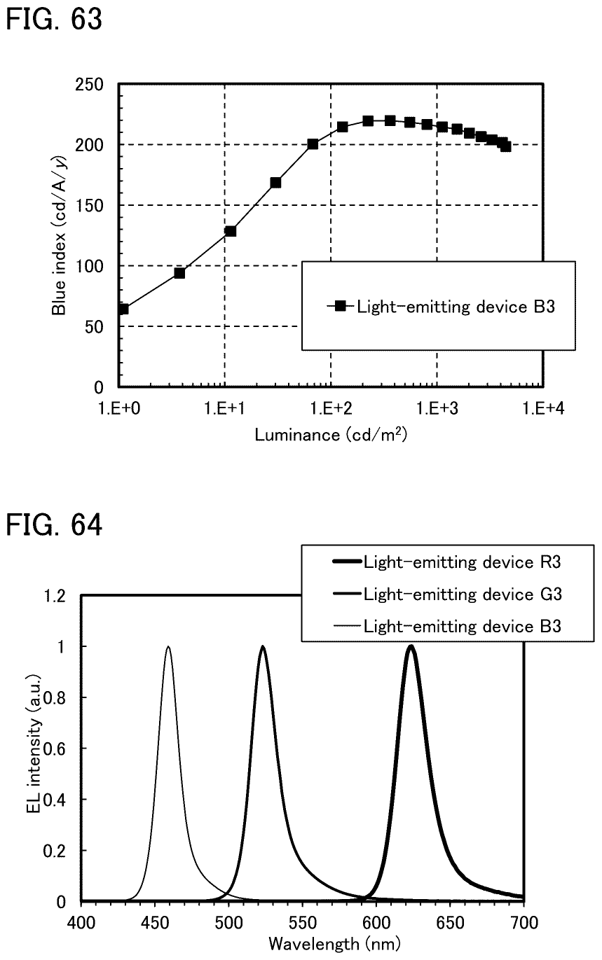

FIG. 59, FIG. 60, FIG. 61, FIG. 62, and FIG. 64 respectively show the luminance-current density characteristics, current efficiency-luminance characteristics, current density-voltage characteristics, power efficiency-luminance characteristics, and electroluminescence spectra of the light-emitting devices R3, G3, and B3. FIG. 63 shows the blue index-luminance characteristics of the light-emitting device B3.

Note that the blue index (BI) is a value obtained by dividing current efficiency (cd/A) by the y value of CIE chromaticity (x, y), and is one of the indicators of characteristics of blue light emission. As the y chromaticity value of blue light emission becomes smaller, the color purity thereof tends to be higher. Blue light emission having a small y chromaticity value and high color purity enables expression of blue colors with a wide range of chromaticity in a display. Using blue light emission with high color purity reduces the luminance of blue light emission necessary for a display to express white, leading to lower power consumption of the display. Thus, BI, which is current efficiency based on a y chromaticity value as one of the indicators of color purity of blue, is suitably used as a means for showing efficiency of blue light emission in some cases. The light-emitting device with higher BI can be regarded as a blue-light-emitting device having higher efficiency for a display.

Table 24 shows the main characteristics of the light-emitting devices R3, G3, and B3 at approximately 1000 cd/m². The luminance, CIE chromaticity, and electroluminescence spectra were measured at room temperature with a spectroradiometer (SR-ULIR, TOPCON TECHNOHOUSE CORPORATION).

TABLE 24

| | | | Current | | | Current | Power | |
|---|---|---|---|---|---|---|---|---|
| | Voltage | Current | density | Chromaticity | Chromaticity | efficiency | efficiency | BI |
| | (V) | (mA) | (mA/m²) | x | y | (cd/A) | (lm/W) | (cd/A/y) |
| Light-emitting | 5.40 | 0.04 | 0.9 | 0.69 | 0.31 | 76.3 | 44.4 | — |
| device R3 | | | | | | | | |
| Light-emitting | 5.40 | 0.01 | 0.3 | 0.18 | 0.75 | 233.7 | 135.9 | — |
| device G3 | | | | | | | | |
| Light-emitting | 7.80 | 0.33 | 8.4 | 0.14 | 0.04 | 9.6 | 3.9 | 214.4 |
| device B3 | | | | | | | | |

FIGS. 59 to 64 and Table 24 reveal that red light emission with an electroluminescence spectrum peak wavelength of 624 nm can be obtained from the light-emitting device R3, green light emission with an electroluminescence spectrum peak wavelength of 523 nm can be obtained from the light-emitting device G3, and blue light emission with an electroluminescence spectrum peak wavelength of 459 nm can be obtained from the light-emitting device B3. It was also found that the light-emitting devices R3, G3, and B3 have high current efficiency as light-emitting devices of the respective emission colors. The light-emitting devices R3, G3, and B3 were found to be tandem light-emitting devices having favorable characteristics.

Next, the materials used for the first and second light-emitting layers of the light-emitting device G3 will be described.

FIG. 33 shows measured PL spectra of a film formed by evaporation of 8mpTP-4mDBtPBfpm, a film formed by evaporation of βNCCP, and a film (mixed film) formed by co-evaporation of 8mpTP-4mDBtPBfpm and βNCCP such that the weight ratio of 8mpTP-4mDBtPBfpm to βNCCP was 1:1. As shown in the graph, the emission spectrum of the co-evaporation film is on a longer wavelength side than the emission spectrum of each organic compound, which indicates that 8mpTP-4mDBtPBfpm and βNCCP form an exciplex in combination.

FIG. 65 shows a PL spectrum of a film (mixed film) formed by co-evaporation of 8mpTP-4mDBtPBfpm and βNCCP such that the weight ratio of 8mpTP-4mDBtPBfpm to βNCCP was 1:1 (an emission spectrum of an exciplex) and an absorption spectrum and a PL spectrum of Pt(tBudppymmtBubiz-tBubp), which is the emission center substance. As can be seen from FIG. 65, the emission edge (442 nm) on a shorter wavelength side of the PL spectrum of the exciplex of 8mpTP-4mDBtPBfpm and βNCCP is positioned at a shorter wavelength than the absorption edge (461 nm) on a longer wavelength side of the absorption spectrum of Pt(tBudppymmtBubiz-tBubp). Since the PL spectrum of the exciplex of 8mpTP-4mDBtPBfpm and βNCCP and the absorption edge of Pt(tBudppymmtBubiz-tBubp) have such a positional relation, excitation energy can be efficiently transferred to Pt(tBudppymmtBubiz-tBubp) in the light-emitting device G3.

Alternatively, the peak wavelength (500 nm) of the PL spectrum of the exciplex formed by 8mpTP-4mDBtPBfpm and βNCCP is shorter than the peak wavelength (552 nm) of the PL spectrum of Pt(tBudppymmtBubiz-tBubp). Such a relationship between the peak wavelength of the PL spectrum of the exciplex and the peak wavelength of the PL spectrum of Pt(tBudppymmtBubiz-tBubp) enables efficient energy transfer.

Note that the PL spectrum of the exciplex was measured using a film formed by co-evaporation of 8mpTP-4mDBtPBfpm and βNCCP. The PL spectrum or the absorption spectrum of Pt(tBudppymmtBubiz-tBubp) was measured using a solution thereof in which chloroform was used as a solvent.

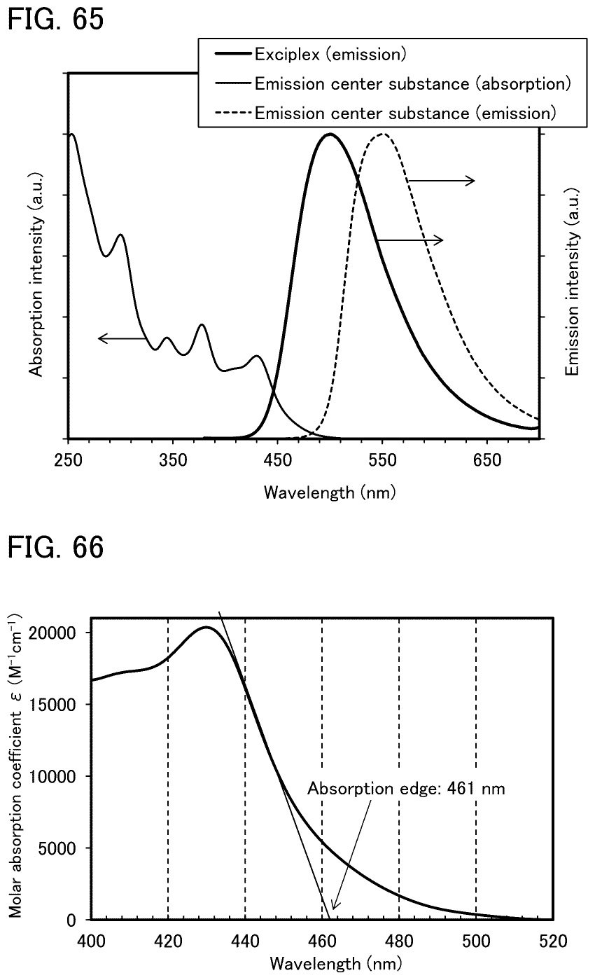

The absorption edge of the absorption spectrum was determined as the intersection between a tangent and the horizontal axis or the baseline. The tangent was drawn at a point at which the slope on a longer wavelength side of the longest-wavelength peak (or the longest-wavelength shoulder peak) of the absorption spectrum has the maximum absolute value. The emission edge on a shorter wavelength side of the PL spectrum was determined as the intersection between a tangent and the horizontal axis or the baseline. The tangent was drawn at a point at which the slope on a shorter wavelength side of the shortest-wavelength peak (or the shortest-wavelength shoulder peak) of the PL spectrum has the maximum absolute value. FIG. 66 shows an example of determining the absorption edge of the absorption spectrum of Pt(tBudppymmtBubiz-tBubp). In this manner, the absorption edge of Pt(tBudppymmtBubiz-tBubp) can be determined to be at 461 nm.

The HOMO level of βNCCP as the organic compound having a hole-transport property was −5.62 eV; the HOMO level of 8mpTP-4mDBtPBfpm as the organic compound having an electron-transport property was −6.2 eV (reference value); the LUMO level of βNCCP as the organic compound having a hole-transport property was −2.21 eV; and the LUMO level of 8mpTP-4mDBtPBfpm as the organic compound having an electron-transport property was −3.01 eV. Since the HOMO level of the organic compound having a hole-transport property is higher than or equal to the HOMO level of the organic compound having an electron-transport property and the LUMO level of the organic compound having a hole-transport property is higher than or equal to the LUMO level of the organic compound having an electron-transport property, the light-emitting device G3 was found to have a structure in which an exciplex can be formed more efficiently.

The HOMO level and the LUMO level of Pt(tBudppymmtBubiz-tBubp) were −5.4 eV and −2.78 eV, respectively. The energy difference between the HOMO level and the LUMO level of the exciplex was 2.61 eV, which corresponds to the energy difference between the HOMO level (−5.62 eV) of βNCCP as the organic compound having a hole-transport property and the LUMO level (−3.01 eV) of 8mpTP-4mDBtPBfpm as the organic compound having an electron-transport property. The energy difference (2.62 eV) between the HOMO level (−5.4 eV) and the LUMO level (−2.78 eV) of Pt(tBudppymmtBubiz-tBubp), which corresponds to the band gap thereof, was found to be larger than the energy difference between the HOMO level and the LUMO level of the exciplex.

Next, the materials used for the first and second light-emitting layers of the light-emitting device R3 will be described. Note that the first and second light-emitting layers of the light-emitting devices R1 and R2 each have a similar structure.

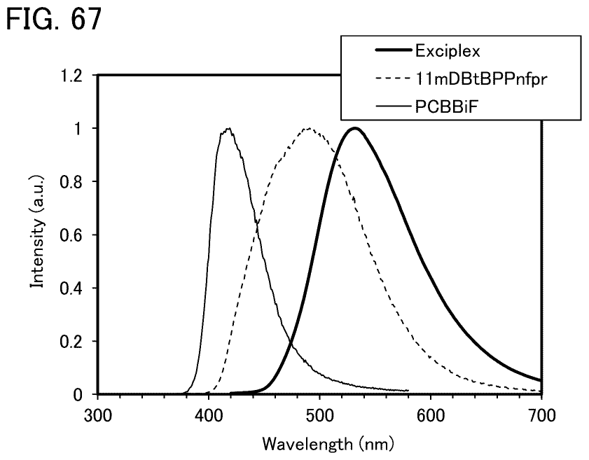

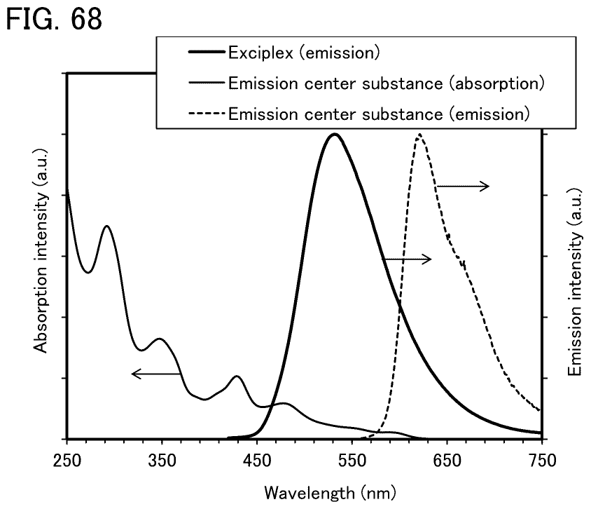

FIG. 67 shows measured PL spectra of a film formed by evaporation of 11mDBtBPPnfpr, a film formed by evaporation of PCBBIF, and a film (mixed film) formed by co-evaporation of 11mDBtBPPnfpr and PCBBiF such that the weight ratio of 11mDBtBPPnfpr to PCBBiF was 0.7:0.3. As shown in the graph, the emission spectrum of the co-evaporation film is on a longer wavelength side than the emission spectrum of each organic compound, which indicates that 11mDBtBPPnfpr and PCBBiF form an exciplex in combination.

FIG. 68 shows a PL spectrum of a film (mixed film) formed by co-evaporation of 11mDBtBPPnfpr and PCBBiF such that the weight ratio of 11mDBtBPPnfpr to PCBBIF was 0.7:0.3 (an emission spectrum of an exciplex) and an absorption spectrum and a PL spectrum of OCPG-006, which is the emission center substance. As can be seen from FIG. 68, the emission edge (468 nm) on a shorter wavelength side of the PL spectrum of the exciplex of 11mDBtBPPnfpr and PCBBiF is positioned at a shorter wavelength than the absorption edge (622 nm) on a longer wavelength side of the absorption spectrum of OCPG-006. Since the PL spectrum of the exciplex of 11mDBtBPPnfpr and PCBBiF and the absorption edge of OCPG-006 have such a positional relation, excitation energy can be efficiently transferred to OCPG-006 in the light-emitting device R3.

Alternatively, the peak wavelength (532 nm) of the PL spectrum of the exciplex formed by 11mDBtBPPnfpr and PCBBiF is shorter than the peak wavelength (621 nm) of the PL spectrum of OCPG-006. Such a relationship between the peak wavelength of the PL spectrum of the exciplex and the peak wavelength of the PL spectrum of OCPG-006 enables efficient energy transfer.

Alternatively, the peak wavelength (532 nm) of the PL spectrum of the exciplex formed by 11mDBtBPPnfpr and PCBBiF is shorter than the wavelength (622 nm) of the absorption edge on a longer wavelength side of the absorption spectrum of OCPG-006. Such a relationship between the peak wavelength of the PL spectrum of the exciplex and the wavelength of the absorption edge on a longer wavelength side of the absorption spectrum of OCPG-006 enables efficient energy transfer.

Note that the PL spectrum of the exciplex was measured using a film formed by co-evaporation of 11mDBtBPPnfpr and PCBBiF. The PL spectrum or the absorption spectrum of OCPG-006 was measured using a solution thereof in which dichloromethane was used as a solvent.

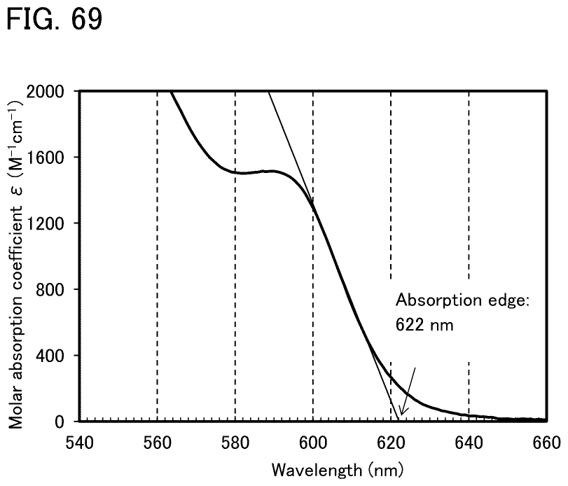

The absorption edge of the absorption spectrum was determined as the intersection between a tangent and the horizontal axis or the baseline. The tangent was drawn at a point at which the slope on a longer wavelength side of the longest-wavelength peak (or the longest-wavelength shoulder peak) of the absorption spectrum has the maximum absolute value. The emission edge on a shorter wavelength side of the PL spectrum was determined as the intersection between a tangent and the horizontal axis or the baseline. The tangent is drawn at a point at which the slope on a shorter wavelength side of the shortest-wavelength peak (or the shortest-wavelength shoulder peak) of the PL spectrum has the maximum absolute value. FIG. 69 shows an example of determining the absorption edge of the absorption spectrum of OCPG-006. In this manner, the absorption edge of OCPG-006 can be determined to be at 622 nm.

The HOMO level of PCBBiF as the organic compound having a hole-transport property was −5.36 eV; the HOMO level of 11mDBtBPPnfpr as the organic compound having an electron-transport property was −6.16 eV; the LUMO level of PCBBiF as the organic compound having a hole-transport property was −2.00 eV; and the LUMO level of 11mDBtBPPnfpr as the organic compound having an electron-transport property was −3.02 eV. Since the HOMO level of the organic compound having a hole-transport property is higher than or equal to the HOMO level of the organic compound having an electron-transport property and the LUMO level of the organic compound having a hole-transport property is higher than or equal to the LUMO level of the organic compound having an electron-transport property, the light-emitting device R3 was found to have a structure in which an exciplex can be formed more efficiently.

The HOMO level and the LUMO level of OCPG-006 were −5.26 eV and −2.69 eV, respectively. The energy difference between the HOMO level and the LUMO level of the exciplex was 2.33 eV, which corresponds to the energy difference between the HOMO level (−5.36 eV) of PCBBiF as the organic compound having a hole-transport property and the LUMO level (−3.02 eV) of 11mDBtBPPnfpr as the organic compound having an electron-transport property. The energy difference (2.57 eV) between the HOMO level (−5.26 eV) and the LUMO level (−2.69 eV) of OCPG-006, which corresponds to the band gap thereof, was found to be larger than the energy difference between the HOMO level and the LUMO level of the exciplex.

The values of the HOMO level and the LUMO level were calculated in a manner similar to that in Example 1.

Here, the second electron-transport layers of the light-emitting device R3, the light-emitting device G3, and the light-emitting device B3 include the same material (the first organic compound having a triazine skeleton). Thus, the light-emitting devices of different emission colors of embodiments of the present invention can each have favorable characteristics even when the second electron-transport layers of the light-emitting devices are made of the same material.

Next, a display device of this example including the light-emitting device R3, the light-emitting device G3, and the light-emitting device B3 respectively in red, green, and blue subpixels was assumed, and the power consumption of the display portion (except for the power consumption of a driving transistor, a driving circuit, and the like) was tentatively calculated. Note that each of the light-emitting devices assumed to be used in the display device is a tandem light-emitting device, and the same emission center substance is used in a plurality of light-emitting layers in each of the light-emitting devices. Thus, the display device that includes the light-emitting devices is a display device that employs a side-by-side patterning method.

The conditions of the display device assumed for the tentative calculation are as follows.

TABLE 25

| | | |
|---|---|---|
| Panel size | 5 | inches (16:9) |
| Panel area | 68.9 | cm² |

| | | | |
|---|---|---|---|
| Aperture ratio | 30% | Red | 10% |
| | | Green | 10% |
| | | Blue | 10% |

| | | |
|---|---|---|
| Effective luminance | 1000 | cd/m² in displaying white on the entire screen |

| | |
|---|---|
| Circularly polarizing plate | Not used |

First, in the display device under the above-described conditions, the luminance (effective luminance) of the light-emitting devices of RGB to obtain 1000 cd/m² emission of white light with CIE 1931 chromaticity coordinates (x, y)=(0.31, 0.33) when the display device is made to emit white light from the entire screen was calculated.

Next, the luminance (intrinsic luminance) required to obtain the calculated effective luminance of the light-emitting devices of RGB was calculated in consideration of the aperture ratios. The intrinsic luminance is the luminance at which each light-emitting device actually emits light in order to obtain the effective luminance of 1000 cd/m² when the display device is made to emit white light with CIE 1931 chromaticity coordinates (x, y)=(0.31, 0.33) from the entire screen. Since the aperture ratio of the whole display device subjected to the tentative calculation is 30% and the aperture ratio per emission color is 10%, the intrinsic luminance is approximately ten times the effective luminance.

From the measurement results of the light-emitting devices described above and the intrinsic luminance, the current density and voltage for making each light-emitting device emit light at the intrinsic luminance can be obtained. In other words, in the display device under the above-described conditions, the current density and voltage of each light-emitting device to obtain 1000 cd/m² luminance emission of white light with CIE 1931 chromaticity coordinates (x, y)=(0.31, 0.33) when the display device is made to emit white light from the entire screen can be obtained.

The power consumption is calculated by multiplying the amount of current by the voltage. The amount of current is calculated by multiplying the current density, the panel area, and the aperture ratio. The display device subjected to the tentative calculation has a diagonal size of 5 inches, an aspect ratio of 16:9, a panel area of 68.9 cm², and an aperture ratio of the light-emitting device of each color of 10%, and the amount of current can be calculated by multiplying the current density calculated in the previous paragraph by these values. Furthermore, power consumption of the light-emitting device of each emission color can be calculated by multiplying the amount of current by the voltage obtained in the previous paragraph. By calculating and summing up the power consumptions of the light-emitting devices of RGB, the total power consumption of the display portion of the display device (except for the power consumption of the driving transistor, the driving circuit, and the like) can be obtained.

Table 26 shows the calculated power consumption of the display device of this example assumed to use the light-emitting device R3, the light-emitting device G3, and the light-emitting device B3.

TABLE 26

| | | | Effective | Intrinsic | Current | Current | Current | | Power |
|---|---|---|---|---|---|---|---|---|---|
| | Chromaticity | Chromaticity | luminance | luminance | efficiency | density | amount | Voltage | consumption |
| | x | y | (cd/m²) | (cd/m²) | (cd/A) | (mA/m²) | (mA) | (V) | (mW) |
| Red | 0.69 | 0.31 | 272 | 2719 | 74.5 | 3.6 | 25.2 | 6.21 | 156.1 |
| Green | 0.18 | 0.75 | 672 | 6716 | 243.4 | 2.8 | 19.0 | 6.28 | 119.5 |
| Blue | 0.14 | 0.04 | 56 | 564 | 9.7 | 5.8 | 40.0 | 7.61 | 304.7 |
| White on the | 0.31 | 0.33 | 1000 | — | 81.8 | — | 84.2 | — | 580.2 |
| entire screen | | | | | | | | | |

Table 26 shows that the display device of this example has high current efficiency in white light emission and a low driving voltage. Moreover, the power consumption of the display device of this example is low.

Thus, the display device including the light-emitting devices of embodiments of the present invention, in each of which at least one of the light-emitting layers includes the emission center substance, the first host material, and the second host material and the first host material and the second host material are organic compounds and form an exciplex in combination, can have low power consumption because the light-emitting devices have high efficiency, high reliability, and a low driving voltage. It was found that the display device including the tandem light-emitting devices in each of which the second electron-transport layer includes the first organic compound having a triazine skeleton, the intermediate layer includes the mixed layer of the second organic compound having a phenanthroline skeleton and lithium or a lithium compound, and the difference in maximum peak wavelength between the emission spectra of light emitted from the light-emitting layers is less than or equal to 30 nm can have favorable characteristics with lower power consumption. In addition, since the tandem light-emitting devices are fabricated by a side-by-side patterning method (i.e., the light-emitting layer included in the tandem light-emitting device is separated from a light-emitting layer included in at least one adjacent light-emitting device or is different from a light-emitting layer included in at least one adjacent light-emitting device, the emission color of the tandem light-emitting device is different from the emission color of at least one adjacent light-emitting device, or the emission center substance included in the light-emitting layer of the tandem light-emitting device has a structure different from that of an emission center substance included in a light-emitting layer of at least one adjacent light-emitting device), the tandem light-emitting devices can have extremely high current efficiency and can thus have higher power efficiency and higher energy efficiency.

The structure in which the second electron-transport layer includes the first organic compound having a triazine skeleton and the intermediate layer includes the mixed layer of the second organic compound having a phenanthroline skeleton and a Group 3 element (Yb in this example) is common between the red-, green-, and blue-light-emitting devices. When the materials of the functional layers are common between the light-emitting devices of different colors, the raw material procurement cost can be reduced and the convenience in manufacturing can be improved. In the display device of one embodiment of the present invention, owing to the above structures of the second electron-transport layer and the intermediate layer, the light-emitting devices of all emission colors can have favorable characteristics even when the materials of the functional layers other than the light-emitting layer are common between the light-emitting devices.

This application is based on Japanese Patent Application Serial No. 2024-036313 filed with Japan Patent Office on Mar. 8, 2024, the entire contents of which are hereby incorporated by reference.

What is claimed is:

1. A light-emitting device comprising:
a first electrode;
a second electrode;
an intermediate layer;
a first light-emitting layer;
a second light-emitting layer;
a first electron-transport layer; and
a second electron-transport layer,
wherein the intermediate layer is between the first electrode and the second electrode,
wherein the first light-emitting layer is between the first electrode and the intermediate layer,
wherein the second light-emitting layer is between the intermediate layer and the second electrode,
wherein the first electron-transport layer is between the first light-emitting layer and the intermediate layer,
wherein the second electron-transport layer is between the second light-emitting layer and the second electrode,
wherein the first light-emitting layer comprises a first emission center substance, a third organic compound, and a fourth organic compound,
wherein the second light-emitting layer comprises a second emission center substance, a fifth organic compound, and a sixth organic compound,
wherein the third organic compound and the fourth organic compound form a first exciplex,
wherein the fifth organic compound and the sixth organic compound form a second exciplex,
wherein a difference between a maximum peak wavelength of an emission spectrum of the first emission center substance and a maximum peak wavelength of an emission spectrum of the second emission center substance is less than or equal to 30 nm,
wherein the first light-emitting layer emits light of a hue different from a hue of light emitted by a first light-emitting layer of at least one of a plurality of light-emitting devices adjacent to the light-emitting device, and
wherein the second light-emitting layer emits light of a hue different from a hue of light emitted by a second light-emitting layer of the at least one of the plurality of light-emitting devices adjacent to the light-emitting device.

2. The light-emitting device according to claim 1,
wherein the second electron-transport layer comprises a first organic compound comprising a triazine skeleton, and
wherein the intermediate layer comprises a mixed layer of lithium or a lithium compound and a second organic compound comprising a phenanthroline skeleton.

3. The light-emitting device according to claim 2,
wherein the first electron-transport layer comprises a seventh organic compound comprising a triazine skeleton.

4. The light-emitting device according to claim 3,
wherein the first organic compound and the seventh organic compound are the same organic compound.

5. A light-emitting device comprising:
a first electrode;
a second electrode;
an intermediate layer;
a first light-emitting layer;
a second light-emitting layer;
a first electron-transport layer; and
a second electron-transport layer,
wherein the intermediate layer is between the first electrode and the second electrode,
wherein the first light-emitting layer is between the first electrode and the intermediate layer,
wherein the second light-emitting layer is between the intermediate layer and the second electrode,
wherein the first electron-transport layer is between the first light-emitting layer and the intermediate layer,
wherein the second electron-transport layer is between the second light-emitting layer and the second electrode,
wherein the second electron-transport layer comprises a first organic compound comprising a triazine skeleton,
wherein the intermediate layer comprises a second organic compound comprising a phenanthroline skeleton,
wherein the first electron-transport layer comprises a seventh organic compound comprising a triazine skeleton,
wherein the first light-emitting layer comprises a first emission center substance, a third organic compound, and a fourth organic compound,
wherein the second light-emitting layer comprises a second emission center substance, a fifth organic compound, and a sixth organic compound,
wherein the third organic compound and the fourth organic compound form a first exciplex,
wherein the fifth organic compound and the sixth organic compound form a second exciplex,
wherein a difference between a maximum peak wavelength of an emission spectrum of the first emission center substance and a maximum peak wavelength of an emission spectrum of the second emission center substance is less than or equal to 30 nm,
wherein the first light-emitting layer emits light of a hue different from a hue of light emitted by a first light-emitting layer of at least one of a plurality of light-emitting devices adjacent to the light-emitting device, and
wherein the second light-emitting layer emits light of a hue different from a hue of light emitted by a second light-emitting layer of the at least one of the plurality of light-emitting devices adjacent to the light-emitting device.

6. The light-emitting device according to claim 5,
wherein the first organic compound and the seventh organic compound are the same organic compound.

7. The light-emitting device according to claim 5,
wherein the intermediate layer comprises a mixed layer of lithium or a lithium compound and the second organic compound.

8. The light-emitting device according to claim 1,
wherein an emission edge on a shorter wavelength side of a PL spectrum of the first exciplex is at a shorter wavelength than an absorption edge on a longer wavelength side of an absorption spectrum of the first emission center substance, and
wherein an emission edge on a shorter wavelength side of a PL spectrum of the second exciplex is at a shorter wavelength than an absorption edge on a longer wavelength side of an absorption spectrum of the second emission center substance.

9. The light-emitting device according to claim 1,
wherein a peak wavelength of an emission spectrum of the first exciplex is on a shorter wavelength side than a peak wavelength of the emission spectrum of the first emission center substance,
wherein a difference between the peak wavelength of the emission spectrum of the first exciplex and the peak wavelength of the emission spectrum of the first emission center substance is less than or equal to 30 nm,
wherein a peak wavelength of an emission spectrum of the second exciplex is on a shorter wavelength side than a peak wavelength of the emission spectrum of the second emission center substance, and
wherein a difference between the peak wavelength of the emission spectrum of the second exciplex and the peak wavelength of the emission spectrum of the second emission center substance is less than or equal to 30 nm.

10. The light-emitting device according to claim 1,
wherein an energy difference between a HOMO level and a LUMO level of the first emission center substance is larger than an energy difference between a HOMO level and a LUMO level of the first exciplex, and
wherein an energy difference between a HOMO level and a LUMO level of the second emission center substance is larger than an energy difference between a HOMO level and a LUMO level of the second exciplex.

11. The light-emitting device according to claim 5,
wherein an emission edge on a shorter wavelength side of a PL spectrum of the first exciplex is at a shorter wavelength than an absorption edge on a longer wavelength side of an absorption spectrum of the first emission center substance, and
wherein an emission edge on a shorter wavelength side of a PL spectrum of the second exciplex is at a shorter wavelength than an absorption edge on a longer wavelength side of an absorption spectrum of the second emission center substance.

12. The light-emitting device according to claim 5,
wherein a peak wavelength of an emission spectrum of the first exciplex is on a shorter wavelength side than a peak wavelength of the emission spectrum of the first emission center substance,
wherein a difference between the peak wavelength of the emission spectrum of the first exciplex and the peak wavelength of the emission spectrum of the first emission center substance is less than or equal to 30 nm,
wherein a peak wavelength of an emission spectrum of the second exciplex is on a shorter wavelength side than a peak wavelength of the emission spectrum of the second emission center substance, and
wherein a difference between the peak wavelength of the emission spectrum of the second exciplex and the peak wavelength of the emission spectrum of the second emission center substance is less than or equal to 30 nm.

13. The light-emitting device according to claim 5,
wherein an energy difference between a HOMO level and a LUMO level of the first emission center substance is larger than an energy difference between a HOMO level and a LUMO level of the first exciplex, and
wherein an energy difference between a HOMO level and a LUMO level of the second emission center substance is larger than an energy difference between a HOMO level and a LUMO level of the second exciplex.

14. A display device comprising:
a first light-emitting device; and
a second light-emitting device,
wherein the first light-emitting device and the second light-emitting device are adjacent to each other,
wherein the first light-emitting device comprises:
a first electrode;
a second electrode;
a first intermediate layer;
a first light-emitting layer;
a second light-emitting layer;
a first electron-transport layer; and
a second electron-transport layer,
wherein the first intermediate layer is between the first electrode and the second electrode,
wherein the first light-emitting layer is between the first electrode and the first intermediate layer,
wherein the second light-emitting layer is between the first intermediate layer and the second electrode,
wherein the first electron-transport layer is between the first light-emitting layer and the first intermediate layer,
wherein the second electron-transport layer is between the second light-emitting layer and the second electrode,
wherein the second light-emitting device comprises:
a third electrode;
a fourth electrode;
a second intermediate layer;
a third light-emitting layer;
a fourth light-emitting layer;
a third electron-transport layer; and
a fourth electron-transport layer,
wherein the second intermediate layer is between the third electrode and the fourth electrode,
wherein the third light-emitting layer is between the third electrode and the second intermediate layer,
wherein the fourth light-emitting layer is between the second intermediate layer and the fourth electrode,
wherein the third electron-transport layer is between the third light-emitting layer and the second intermediate layer,
wherein the fourth electron-transport layer is between the fourth light-emitting layer and the fourth electrode,
wherein the second electron-transport layer and the fourth electron-transport layer each comprise a first organic compound comprising a triazine skeleton,
wherein the second electron-transport layer and the fourth electron-transport layer are made of the same material,
wherein the first intermediate layer and the second intermediate layer each comprise lithium or a lithium compound and a second organic compound comprising a phenanthroline skeleton,
wherein the first light-emitting layer comprises a first emission center substance, a third organic compound, and a fourth organic compound,
wherein the second light-emitting layer comprises a second emission center substance, a fifth organic compound, and a sixth organic compound,
wherein the third organic compound and the fourth organic compound form a first exciplex,
wherein the fifth organic compound and the sixth organic compound form a second exciplex,
wherein the third light-emitting layer comprises a third emission center substance,
wherein the fourth light-emitting layer comprises a fourth emission center substance,
wherein a difference between a maximum peak wavelength of an emission spectrum of the first emission center substance and a maximum peak wavelength of an emission spectrum of the second emission center substance is less than or equal to 30 nm,
wherein a difference between a maximum peak wavelength of an emission spectrum of the third emission center substance and a maximum peak wavelength of an emission spectrum of the fourth emission center substance is less than or equal to 30 nm,
wherein the first light-emitting layer emits light of a hue different from a hue of light emitted by the third light-emitting layer, and
wherein the second light-emitting layer emits light of a hue different from a hue of light emitted by the fourth light-emitting layer.

15. The display device according to claim 14,
wherein an emission edge on a shorter wavelength side of a PL spectrum of the first exciplex is at a shorter wavelength than an absorption edge on a longer wavelength side of an absorption spectrum of the first emission center substance, and
wherein an emission edge on a shorter wavelength side of a PL spectrum of the second exciplex is at a shorter wavelength than an absorption edge on a longer wavelength side of an absorption spectrum of the second emission center substance.

16. The display device according to claim 14,
wherein a peak wavelength of an emission spectrum of the first exciplex is on a shorter wavelength side than a peak wavelength of the emission spectrum of the first emission center substance,
wherein a difference between the peak wavelength of the emission spectrum of the first exciplex and the peak wavelength of the emission spectrum of the first emission center substance is less than or equal to 30 nm,
wherein a peak wavelength of an emission spectrum of the second exciplex is on a shorter wavelength side than a peak wavelength of the emission spectrum of the second emission center substance, and
wherein a difference between the peak wavelength of the emission spectrum of the second exciplex and the peak wavelength of the emission spectrum of the second emission center substance is less than or equal to 30 nm.

17. The display device according to claim 14,
wherein an energy difference between a HOMO level and a LUMO level of the first emission center substance is larger than an energy difference between a HOMO level and a LUMO level of the first exciplex, and
wherein an energy difference between a HOMO level and a LUMO level of the second emission center substance is larger than an energy difference between a HOMO level and a LUMO level of the second exciplex.
